(19) United States
(12) Patent Application Publication
(10) Pub. No.: US 2014/0003134 A1
(43) Pub. Date: Jan. 2, 2014

(54) SEMICONDUCTOR MEMORY DEVICE AND A METHOD OF CONTROLLING THE SAME

(71) Applicant: FUJITSU LIMITED, Kawasaki (JP)

(72) Inventor: Atsushi MORI, Kawasaki (JP)

(73) Assignee: FUJITSU LIMITED, Kawasaki (JP)

(21) Appl. No.: 14/013,480

(22) Filed: Aug. 29, 2013

Related U.S. Application Data
(63) Continuation of application No. PCT/JP2011/056109, filed on Mar. 15, 2011.

(51) Int. Cl. G11C 11/419

(52) U.S. Cl. CPC G11C 11/419
USPC 365/154

(57) ABSTRACT

A semiconductor memory device includes a plurality of memory blocks, each including a plurality of memory cells for retaining data, a decoder which identifies, when the memory cells having a same address are identified out of the plurality of memory cells, the memory cells having the same address in adjacent bits from the different memory blocks, and a read-write controlling unit which reads the data retained by the memory cells identified by the decoder and writes the data into the memory cell identified by the decoder.

### CROSS-REFERENCE TO RELATED APPLICATION

This application is a continuation application of International Application PCT/JP2011/056109 filed on Mar. 15, 2011 and designated the U.S., the entire contents of which are incorporated herein by reference.

### FIELD

The embodiments discussed herein are related to semiconductor memory device and a method of controlling the semiconductor memory device.

### BACKGROUND

A semiconductor memory device that includes a plurality of memory cells arranged like a matrix, and includes bit lines connected to the same bit line selection circuit and arranged so as not to be adjacent each other is disclosed in Japanese Laid-open Patent Publication No. 2003-208795. This structure is provided to prevent a parity of a memory cell array from being nullified when a cosmic ray containing an alpha ray or the like impinges on the memory cells of the memory cell array to thereby cause a soft error.

### SUMMARY

According to an aspect of the embodiment, a semiconductor memory device includes a plurality of memory blocks, each including a plurality of memory cells for retaining data, a decoder which identifies, when the memory cells having a same address are identified out of the plurality of memory cells, the memory cells having the same address in adjacent bits from the different memory blocks, and a read-write controlling unit which reads the data retained by the memory cells identified by the decoder and writes the data into the memory cell identified by the decoder.

The object and advantages of the invention will be realized and attained by means of the elements and combinations particularly pointed out in the appended claims.

It is to be understood that both the foregoing general description and the following detailed description are exemplary and explanatory and are not restrictive of the invention, as claimed.

### BRIEF DESCRIPTION OF THE DRAWINGS

FIG. 1 schematically illustrates a structure of a bit cell of a single port type used in an SRAM;

FIG. 2 illustrates the structure of the bit cell illustrated in FIG. 1 in detail;

FIG. 3 illustrates a multiport bit cell of 8-transistors type;

FIG. 4 illustrates a part of an SRAM as an example of a semiconductor memory device of a comparative example;

FIG. 5 illustrates a part of an SRAM as an example of a semiconductor memory device of another comparative example;

FIG. 6 illustrates an information processing apparatus including a semiconductor memory device of a first embodiment;

FIG. 7 is an enlarged view of a semiconductor memory device of FIG. 6;

FIG. 8 illustrates a part of an SRAM of the first embodiment;

FIG. 9A illustrates data structure of an input address of the SRAM 200 of the first embodiment;

FIG. 9B illustrates a circuit of a row decoder of the SRAM of the first embodiment;

FIG. 9C illustrates a circuit of a sub block decoder of the SRAM of the first embodiment;

FIG. 9D illustrates a circuit of a top and bottom select decoder of the SRAM of the first embodiment;

FIG. 9E illustrates a circuit of a pattern select decoder of the SRAM of the first embodiment;

FIG. 9F illustrates a circuit for decoding the column address included in the column decoder of the SRAM of the first embodiment;

FIG. 9G illustrates a circuit for decoding the column address included in the column decoder of the SRAM of the first embodiment;

FIG. 9H illustrates a circuit for decoding the column address included in the column decoder of the SRAM of the first embodiment;

FIG. 9I illustrates a circuit for decoding the column address included in the column decoder of the SRAM of the first embodiment;

FIG. 10 illustrates a column selection and read-write circuit and a signal line for transmitting column selection data connected with the column selection and read-write circuit;

FIG. 11 illustrates the column selection and read-write circuit of the SRAM of the first embodiment;

FIG. 12 illustrates how to select bits under a first or second pattern in the SRAM of the first embodiment;

FIG. 13 is a timing chart illustrating an operation example of the SRAM of the first embodiment;

FIG. 14 is a timing chart illustrating an operation example of the SRAM of the first embodiment;

FIG. 15 is a timing chart illustrating an operation example of the SRAM of the first embodiment;

FIG. 16 illustrates an SRAM of a second embodiment;

FIG. 17 illustrates a switch circuit of the SRAM of the second embodiment;

FIG. 18 illustrates a part of the SRAM of the second embodiment;

FIG. 19A illustrates data structure of an input address of the SRAM of the second embodiment;

FIG. 19B illustrates a circuit of a row decoder of the SRAM of the second embodiment;

FIG. 19C illustrates a circuit of a sub block decoder of the SRAM of the first embodiment;

FIG. 19D illustrates a circuit of a pattern select decoder of the SRAM of the second embodiment;

FIG. 19E illustrates a circuit of a column decoder of the SRAM of the second embodiment;

FIG. 20 illustrates sub blocks including bit cells having the same address indicated by a shade in the SRAM of the second embodiment;

FIG. 21 illustrates sub blocks including bit cells having the same address indicated by a shade in the SRAM of the second embodiment;

FIG. 22 illustrates an SRAM of a third embodiment;

FIG. 23 illustrates a part of the SRAM of the third embodiment;

FIG. 24A illustrates data structure of an input address of the SRAM of the third embodiment;

FIG. 24B illustrates a circuit of a row decoder of the SRAM of the third embodiment;

FIG. 24C illustrates a circuit of a sub block decoder of the SRAM of the third embodiment;

FIG. 24D illustrates a circuit of a pattern select decoder of the SRAM of the third embodiment;

FIG. 24E illustrates a circuit of an region select decoder of the SRAM of the third embodiment;

FIG. 24F illustrates a circuit for decoding a column address included in the column decoder of the SRAM of the third embodiment;

FIG. 24G illustrates a circuit for decoding a column address included in the column decoder of the SRAM of the third embodiment;

FIG. 24H illustrates a circuit for decoding the column address included in the column decoder of the SRAM of the third embodiment; and

FIG. 24I illustrates a circuit for decoding the column address included in the column decoder of the SRAM of the third embodiment.

### DESCRIPTION OF EMBODIMENTS

A soft error is caused by an alpha ray having an electric charge or the like and a neuron ray having no electric charge among the cosmic ray impinging onto the semiconductor memory device.

In a case where an inversion of a retained bit value occurs because of a size reduction along with microminiaturization or a low voltage in an operating voltage along with power saving, or the like, an area where data are destructed increases to thereby tend to easily cause data destruction through a plurality of bits forming a unit data having, for example, one byte, which is designed to be protected by parity.

However, in a semiconductor memory device, in which bit lines connected with the same bit line selection circuit are arranged so as not to be mutually adjacent, the wiring lengths of the bit lines are elongated. Therefore, the layout and the working speed are restricted.

The semiconductor memory device, in which the bit lines are connected with the same bit line selection circuit so as not to be mutually adjacent, is not suitable as a static random access memory (SRAM) operated at a high frequency.

In order to decrease probability of data destruction caused by inversions of a plurality of bits, the number of columns is increased, for example.

However, there is a problem that the increased number of columns may lead to a drop of working speed caused by a change in an aspect ratio (a laterally elongated feature) of the semiconductor memory device and/or a laterally extended feature of the word line.

Preferred embodiments of the present invention will be explained with reference to accompanying drawings. Where the same reference symbols are attached to the same parts, repeated description of the parts is omitted.

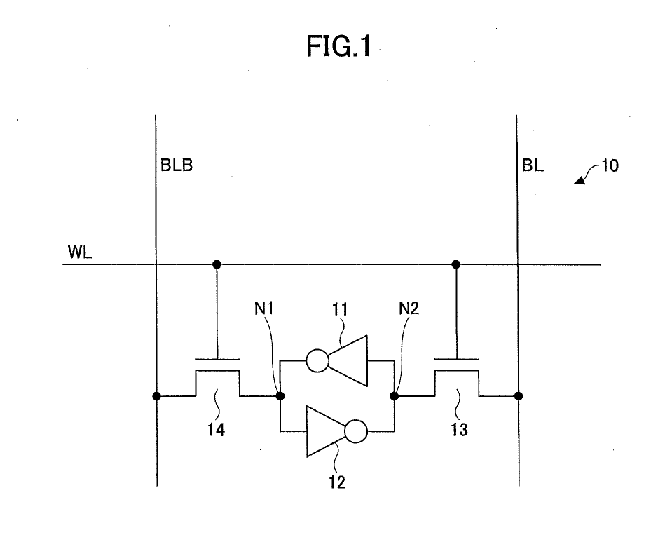

Before explaining semiconductor memory devices and methods of controlling the semiconductor memory devices of first to third embodiments, a semiconductor memory device of a comparative example is described together with its problems with reference to FIGS. 1 to 5.

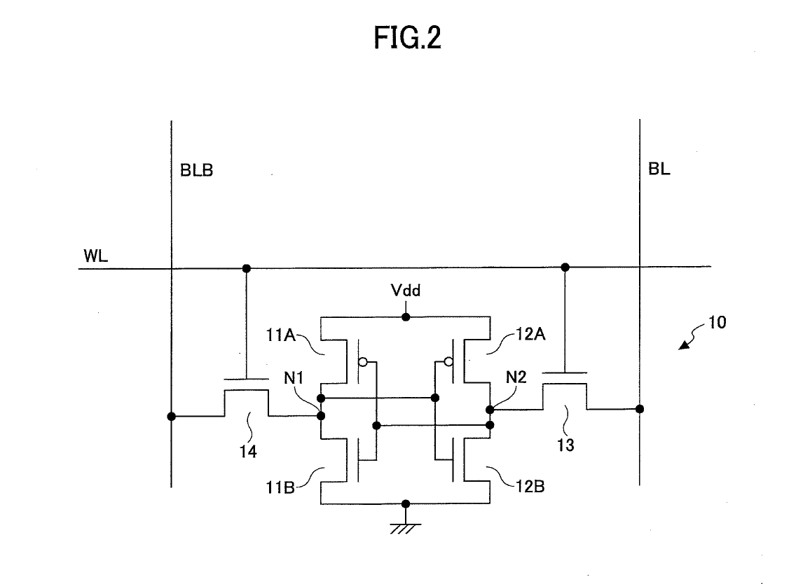

FIG. 1 schematically illustrates the structure of a bit cell 10 of a single port type used for a static random access memory (SRAM). FIG. 2 illustrates the structure of the bit cell 10 illustrated in FIG. 1 in more detail.

As illustrated in FIG. 1, the bit cell 10 includes inverters 11 and 12 as a pair of NOT circuits and a pair of n-type metal oxide semiconductor (NMOS) transistors 13 and 14.

The inverters 11 and 12 are connected to form a loop. The gates of the NMOS transistors 13 and 14 are connected to the word line (WL), the drain of the NMOS transistors 13 is connected to a bit line BL having a positive polarity, and the drain of the NMOS transistors 14 is connected to a bit line bar (BLB) having a negative polarity.

Further, the sources of the NMOS transistors 13 and 14 are connected with connecting portions N1 and N2 of the inverters 11 and 12 connected each other and formed like the loop.

Referring to FIG. 2, the inverter 11 includes a p-type metal oxide semiconductor (PMOS) transistor 11A and an NMOS transistor 11B. The inverter 11 is of a complementary metal oxide semiconductor (CMOS) type. In a manner similar to the above, the inverter 12 includes a PMOS transistor 12A and an NMOS transistor 12B. The inverter 12 is of a CMOS type. The bit cell illustrated in FIGS. 1 and 2 includes 6 MOS transistors.

Input-output terminals of the MOS transistors 11A and 11B are connected with input-output terminals of the MOS transistors 12A and 12B so that the input terminals of the MOS transistors 11A and 11B are connected with the output terminals of the MOS transistors 12A and 12B and the output terminals of the MOS transistors 11A and 11B are connected with the input terminals of the MOS transistors 12A and 12B. Thus, the bit cell 10 is substantialized as a latch circuit including the inverters 11 and 12.

The connecting portion N1 for connecting the drains of the MOS transistors 11A and 11B corresponds to the connecting portion N1 illustrated in FIG. 1. The connecting portion N1 functions as the memory node N1. The connecting portion N2 for connecting the drains of the MOS transistors 12A and 12B corresponds to the connecting portion N2 illustrated in FIG. 1. The connecting portion N2 functions as the memory node N2.

The data in the memory nodes N1 and N2 can be read or written by causing the memory nodes N1 and N2 to retain complementary data of “1” and “0” or “0” and “1” and selecting the bit cell 10 using the word line WL and a pair of bit lines BL and BLB.

When the data is read out, the pair of bit lines BL and BLB is set in an H level and the word line WL is driven, one of the bit lines BL and BLB is set in a L level by the memory node N1 or N2. Thus, the read data are output.

On the other hand, when the data is written in, one of the pair of bit lines BL and BLB is set in the H level and the other one of the pair of bit lines BL and BLB is set in the L level. Under this state, the word line WL is driven to write in the memory nodes N1 and N2.

In the bit cell 10 of the 6-transistor type illustrated in FIGS. 1 and 2, data are not simultaneously written in and read out. Reading and writing are performed in different cycles.

Next, a multiport bit cell is described. In the multiport bit cell, data are simultaneously read out and written in.

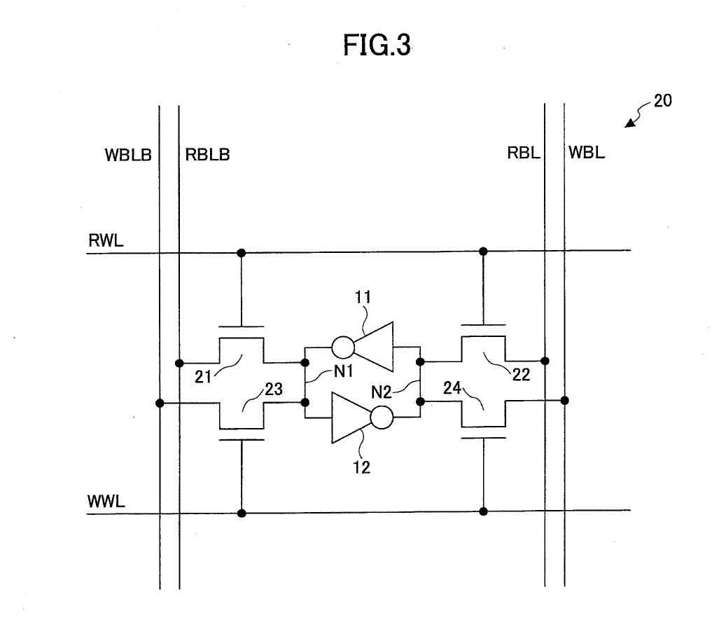

FIG. 3 illustrates a multiport bit cell of an 8-transistors type. The bit cell 20 of the multiport type illustrated in FIG. 3 includes two inverters. The two inverters are the same as the inverters 11 and 12 included in the bit cell of the single port type illustrated in FIG. 1. Each of the inverters 11 and 12 includes two transistors (see FIG. 2). Therefore, the same reference symbols are used and explanation of the reference symbols is omitted.

In the bit cell 20 of the multiport type illustrated in FIG. 3, there are two word lines, i.e., a write word line (WWL) and a read word line (RWL). Further, there are two pairs of bit lines, i.e., a pair of a write bit line (WBL) having a positive polarity and a write bit line bar (WBLB) having a negative polarity, and a pair of a read bit line (RBL) having a positive polarity and a read bit line bar (RBLB) having a negative polarity.

The gates of the NMOS transistors 21 and 22 are connected with the read word line RWL. The drain of the NMOS transistor 21 is connected with the read bit line bar RBLB, and the source of the NMOS transistor 21 is connected with the memory node N1. The drain of the NMOS transistor 22 is connected with the read bit line RBL, and the source of the NMOS transistor 22 is connected with the memory node N2.

The gates of the NMOS transistors 23 and 24 are connected with the write word line WWL. The drain of the NMOS transistor 23 is connected with the write bit line bar WBLB, and the source of the NMOS transistor 23 is connected with the memory node N1. The drain of the NMOS transistor 24 is connected with the write bit line WBL, and the source of the NMOS transistor 23 is connected with the memory node N2.

When the data is read out, the read word line RWL, read bit line RBL, and the read bit line bar RBLB are used to select the bit cell 20.

When the data is written in, the write word line WWL, the write bit line WBL, and the write bit line bar WBLB are used to select the bit cell 20.

As described, two pairs of transistors 21, 22, 23, and 24 used to read out and write in are included in the bit cell 20. Because the different word lines and the different bit lines are used for reading and writing the data, reading and writing can be simultaneously performed.

Referring to FIG. 3, the write word line WWL, the read word line RWL, the write bit line WBL, the write bit line bar WBLB, the read bit line RBL, and the read bit line bar RBLB are described by separating the word lines and the bit lines into those for reading and those for writing. However, when the word lines, the bit lines, and the bit line bars are not separated into those for reading and those for writing, the word line, the bit line, and the bit line bar are used for reading in and writing out the data.

Next, a semiconductor memory device including the bit cells 10 of the comparative example illustrated in FIGS. 1 and 2 is described.

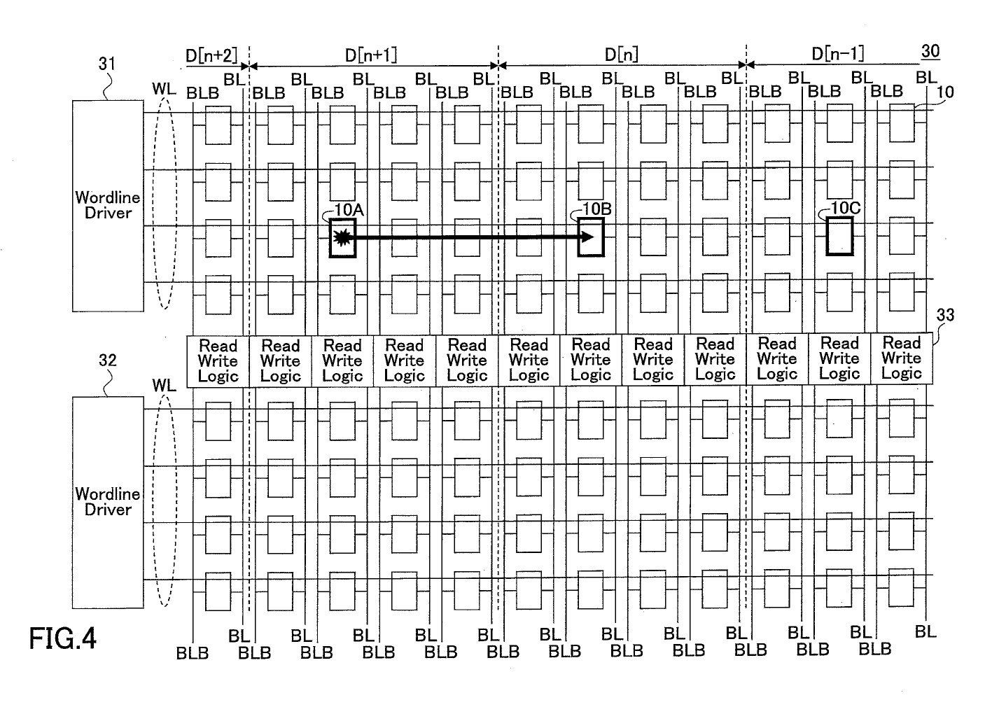

FIG. 4 illustrates a part of an SRAM 30 as an example of the semiconductor memory device of the comparative example.

The SRAM 30 includes a plurality of bit cells 10 arranged like an array, word line drivers 31 and 32, a column selection and read-write circuit 33, word lines WL, bit lines BL, and bit line bars (BLB).

The bit lines BL and the corresponding bit line bars BLB are paired. Each bit cell 10 is connected between the corresponding pair of the bit line BL and the bit line bar BLB.

Four word lines WL are connected with each of the word line drivers 31 and 32. The four word line drivers 31 and 32 select a row (the word line) based on row selection data (a row selection signal) output after decoding a row address.

The bit lines BL and the bit line bars BLB are connected with the column selection and read-write circuit 33. The column (the bit line and the bit line bar) is selected based on column selection data (a column selection signal) output after decoding the column address.

FIG. 4 illustrates 96 bit cells 10. The 48 bit cells positioned above the column selection and read-write circuit 33 are included in one sub array. The 48 bit cells positioned below the column selection and read-write circuit 33 are included in the other sub array. Said differently, 2 sub arrays are illustrated in FIG. 4. The sub array is, for example, a minimum unit in a memory hierarchy where a sub array, a sub block, and a bank are hierarchized from a lower layer to an upper layer.

Here, each bit included in the SRAM 30 is indicated by D[n], where n is an arbitrary natural number and is equal to the bit sequence number of the SRAM 30.

In the SRAM 30 illustrated in FIG. 4, each bit includes 4 columns. Said differently, each bit of D[n−1], D[n], D[n+1], and D[n+2] includes 4 columns. FIG. 4 illustrates 3 columns of D[n−1], 4 columns of D[n] and D[n+1], and 1 column of D[n+2] for convenience of explanation.

As described, 4 word lines WL are connected with the word line drivers 31 and 32.

Therefore, 16 bit cells (4 rows×4 columns) are allocated to one bit inside one sub array of the SRAM 30 illustrated in FIG. 4.

In the SRAM 30 of the comparative example, memory cells 10A, 10B, and 10C indicated by heavy lines reads in or writes out data by, for example, a unit of 1 byte. Therefore, if the bits D[n+1], D[n], and D[n−1] are included in the same byte, these 3 bit cells of the different cells D[n+1], D[n], and D[n−1] have the same address. Here, in order to distinguish the three bit cells 10 indicated by the heavy lines, the bit cell in the bit D[n+1] is designated by the reference symbol 10A, the bit cell in the bit D[n] is designated by the reference symbol 10B, and the bit cell in the bit D[n−1] is designated by the reference symbol 10C.

In the SRAM 30 of the comparative example, if an alpha ray or a neutron ray impinging on the SRAM 30 collides against the bit cell 10, data retained by the five bit cells, i.e., the bit cells 10A to 10B, may be destructed. In this case, 5 consecutive data of adjacent bit cells 10 are destructed by the alpha ray or the neutron ray.

If the bit cells 10A and 10B are in the same address, the data destruction effects on 2 bits included in the data of 1 byte designated by the same address.

As described, in the SRAM 30 of the comparative example, the data destruction of a plurality of bits, 2 bits or greater, may possibly occur.

The data destruction caused by the alpha ray or the like tends to increase by size reductions by microminiaturization of semiconductor memory devices, lower voltages of operating voltages for power saving, or the like.

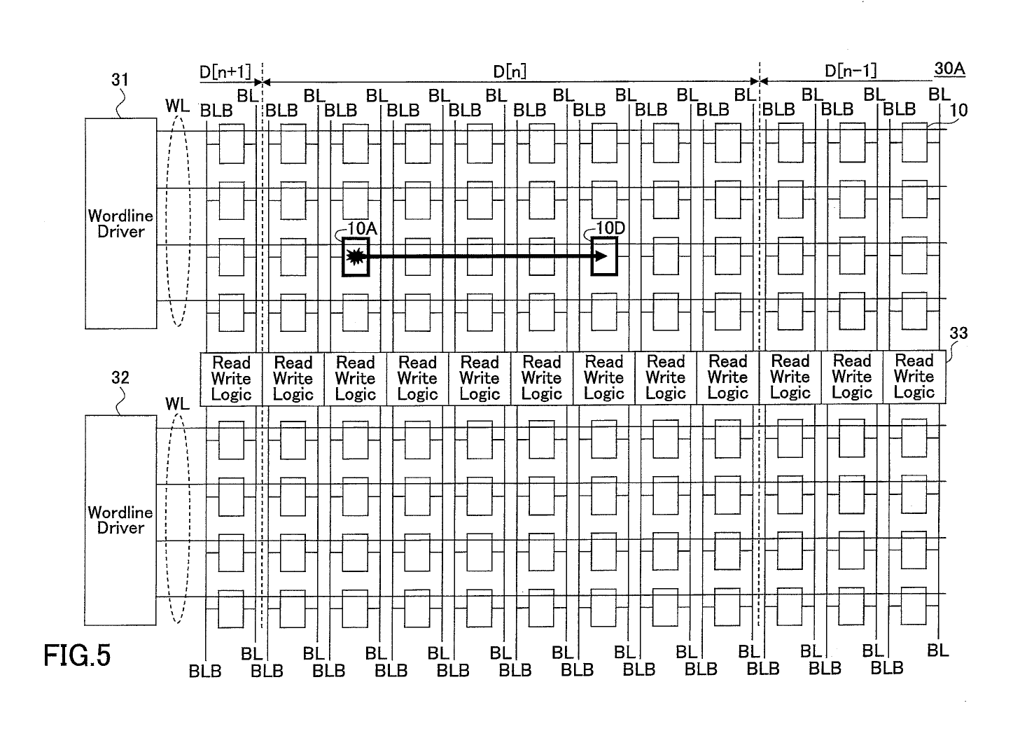

Next, referring to FIG. 5, data destruction in a semiconductor memory device of another comparative example is described.

FIG. 5 illustrates a part of an SRAM 30A as an example of a semiconductor memory device of the other comparative example.

The SRAM 30A of the other comparative example illustrated in FIG. 5 differs from the SRAM 30 of the comparative example illustrated in FIG. 4 at the point that one bit includes 8 columns. The other structure is similar to the SRAM 30 of the comparative example illustrated in FIG. 4. Therefore, the same reference symbols are attached to the same or similar parts, and repeated description of the parts is omitted.

If an alpha ray or a neutron ray having the same kinetic energy as that of the alpha ray or the neutron ray impinging on the SRAM. 30 illustrated in FIG. 4 impinges on the SDRAM 30A and collides against the bit cell 10A inside the bit D[n], five consecutively adjacent bit cells 10 may be destructed by the alpha ray or the neutron ray.

In this case, in the SRAM 30A illustrated in FIG. 5, data of the bit cells 10A to 10D are destructed. Because 5 bit cells, i.e., the bit cells 10A to 10D are included in the same bit D[n], the data destruction is limited to one bit.

As described, it is possible to restrict the data destruction through a plurality of bits by increasing the number of columns inside each bit D[k] where k is a natural number between n−1 to n+1.

However, there is a problem that the increased number of columns may lead to a drop of working speed caused by a change in an aspect ratio (a laterally elongated feature) of the semiconductor memory device and/or a laterally extended feature of the word line.

As described, the semiconductor device of the comparative example has a problem that data destruction is apt to occur in a plurality of bits. Further, in the semiconductor memory device of the other comparative example (see FIG. 5), there is the problem that the increased number of columns may lead the drop of working speed caused by the change in the aspect ratio (the laterally elongated feature) of the semiconductor memory device and/or the laterally extended feature of the word line.

Therefore, within first to third embodiments described below, a semiconductor memory device and a method of controlling the semiconductor memory device are provided solving the above problems. Hereinafter, the semiconductor memory devices of the first and second embodiments are described.

### [a] First Embodiment

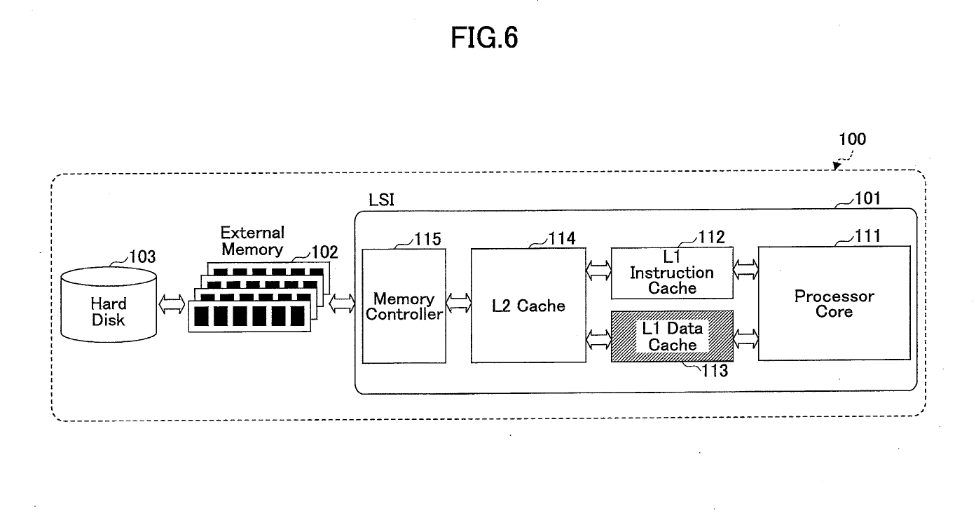

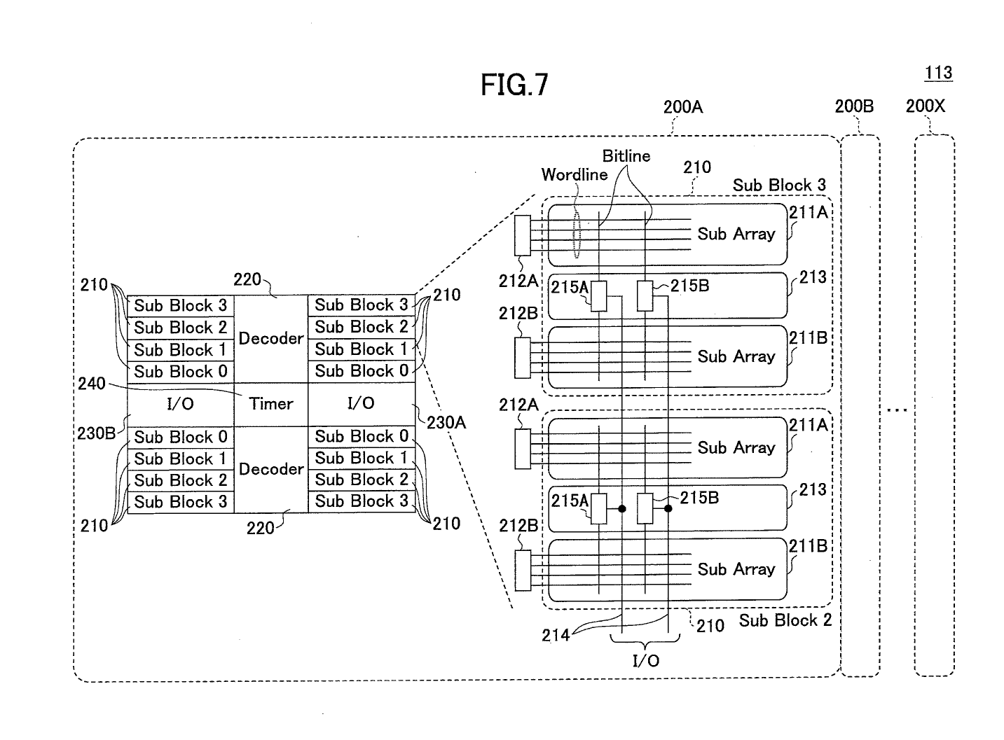

FIG. 6 illustrates an information processing apparatus including the semiconductor memory device of the first embodiment. FIG. 7 is an enlarged view of the semiconductor memory device illustrated in FIG. 6.

Within the first embodiment, a mode in which the information processing apparatus is a server 100 is described as an example.

Referring to FIG. 6, the server 100 includes a large scale integrated (LSI) circuit 101, a main memory unit 102, and an auxiliary memory unit 103. A dedicated bus is used to connect the LSI 101 with the main memory unit 102, for example. Another dedicated bus is used to connect the main memory unit 102 with an auxiliary memory unit 103, for example.

The LSI 101 includes a processor core 111, a level-1 (L1: primary) instruction cache 112, a L1 data cache 113, a level-2 (L2: secondary) cache 114, and a memory controller 115.

The processor core 111 is, for example, a central processing unit (CPU) core. The processor core 111 is a processing unit of the server as the information processing apparatus for performing arithmetic processing. The processor core 111, the L1 instruction cache 112, and the L1 data cache 113 may be integrally formed with the CPU. The number of the processor cores 111 may be plural. In this case, the single L1 instruction cache 112 and the single L1 data cache 113 may be connected with each of the processor cores 111.

The L1 instruction cache 112 is a primary instruction cache for temporarily storing a program for arithmetic processing by the processor core 111. For example, an SRAM is used to substantialize the function of the L1 instruction cache 112.

The L1 data cache 113 is a primary data cache for retaining data for the arithmetic processing in the processor core 111 or data generated by the arithmetic processing in the processor core 111. Within the first embodiment, the SRAM as the semiconductor memory device of the first embodiment is used for the L1 data cache 113. A detailed structure is described later.

The L2 cache 114 is closer to the main memory unit 102 in a memory hierarchy structure. Therefore, the L2 cache 114 is a lower cache than the L1 instruction cache 112 and the L1 data cache 113. Typically, the L2 cache 114 has a processing speed lower than those of the L1 instruction cache 112 and the L1 data cache 113, and has a capacity greater than those of the L1 instruction cache 112 and the L1 data cache 113. The function of the L2 cache 114 is substantialized by, for example, the SRAM.

The memory controller 115 is a control device for controlling write in and read out data between the LSI 101 and the main memory unit 102. The memory controller 115 is substantialized by, for example, a LSI.

The main memory unit 102 is substantialized by, for example, a dynamic random access memory (DRAM). The auxiliary memory unit 103 is substantialized by, for example, a hard disc.

The server 100 may include data input-output interface or the like for communicating with an external apparatus.

As illustrated in FIG. 7, the L1 data cache 113 includes a plurality of SRAMs 200A, 200B, . . . , and 200X. The SRAMs 200A, 200B, . . . , 200X are connected in parallel with the processor core 111 so as to be selected by the processor core 111.

Because the structures of all the SRAMs 200A, 200B, . . . , 200X are similar, the structure of the SRAM 200A is described. In order to explain the existence of the plurality of SRAMs, the SRAMs are referred to as 200A, 200B, . . . , 200X. However, the number of the SRAM may be single. For example, the SRAMs equal to 2 or greater may be arranged.

As illustrated on the left side of FIG. 7, the memory region of the SRAM 200A is divided into a plurality of sub blocks 210 and hierarchized. The SRAM 200A includes a decoder 220, input-output ports (I/O) 230A and 230B, and a timer 240.

As illustrated on the left side of FIG. 7, four sub blocks 210 arranged in four stages are provided above and below the input-output port (I/O) 230A, and four sub blocks 210 arranged in four stages are provided above and below the input-output port (I/O) 230B. Here, the four sub blocks 210 provided above and below the input-output port I/O 230A and 230B (16 sub blocks) are sequentially numbered by sub block numbers 0 to 3 from sides closer to the input-output port I/O 230A and 230B.

Hereinafter, when the input-output ports I/O 230A and 230B are not distinguished, the input-output port I/O 230 is used in the description.

As enlarged on the right side of FIG. 7, each of the sub blocks 210 includes 2 sub arrays 211A and 211B, word line drivers 212A and 211B, and column selection and read-write circuit (Column Select/Read/Write logic) 213. Referring to the right side of FIG. 7, the sub blocks 210 (Sub Block 2 and Sub Block 3) whose numbers are 2 and 3 are illustrated.

Each of the sub blocks 210 are separated by a plurality of bits. As an example, in a manner similar to the SRAM 30 (see FIG. 4), one bit includes 4 columns.

The structures of all sub arrays 211A and 211B included in the SRAM 200A are similar. Bit cells as memory cells are arranged like an array. A word line and bit lines (including a bit line bar) can be selected based on a result by the decoder 220 of decoding an input address input in the decoder 220.

The input address is input from the processor core 111 (see FIG. 6) to the decoder 220. The input address includes a column address for identifying the column, a row address for identifying a row, and a sub array address for identifying a sub array.

Further, the decoder 220 includes a column decoder for decoding the column address, a row decoder for decoding the row address, and a sub array decoder for decoding the sub array address.

The word line drivers 212A and 212B correspond to the sub arrays 211A and 211B, respectively. The word line drivers 212A and 212B are connected with the word lines included in the sub arrays 211A and 211B, respectively. Each of the word line drivers 212A and 212B selects the row (the word line) based on row selection data (a row selection signal) output by the decoder 220 after decoding the row address.

The column selection and read-write circuit 213 corresponds to each of the sub blocks 210. The column selection and read-write circuit 213 is connected with bit lines of the sub arrays 211A and 211B inside each of the sub blocks 210. The column selection and read-write circuit 213 selects a column (a bit line) based on column selection data (a column selection signal) output by the decoder 220 after decoding the column address.

Each column selection and read-write circuit 213 in each sub block 210 includes switch circuits 215A and 215B.

The bit lines of the sub arrays 211A and 211B are connected with global bit lines 214 via switch circuits 215A and 215B inside the column selection and read-write circuit 213.

Referring to FIG. 7, each of the switch circuits 215A and 215B connects one bit line with one global bit line 214 for convenience of explanation. However, the switch circuit 215A may connect a plurality of bit lines with the one global bit line 214.

Hereinafter, a mode in which the switch circuit 215A connects four bit lines with the one global bit line 214 is described as an example.

The bit lines of the sub arrays 211A and 211B included in all the hierarchized sub blocks 210 are connected with global bit lines 214 via switch circuits 215A and 215B inside the column selection and read-write circuits 213. The global bit lines 214 are connected with the input-output ports I/O 230.

With the above structure, the sub blocks 210 in each hierarchy are hierarchized by the global bit lines 214.

The switch circuits 215A and 215B connect the bit lines connected with the memory cells for reading or writing data with the global bit lines 214 based on the column selection data.

The column selection and read-write circuit 213 including the switch circuits 215A and 215B is a read-write controlling unit.

Hereinafter, if the SRAMs 200A, 200B, . . . , 200X are not specifically distinguished, the SRAM 200 is used in the description instead of the SRAMs 200A, 200B, . . . , 200X.

Positional relationships of the sub blocks 210, the sub arrays 211A and 211B, and so on are schematically illustrated as a hierarchical structure of the sub blocks 210, the sub arrays 211A and 211B, and so on. The expressions such as “above” and “below” in the description do not represent physical and positional relationships.

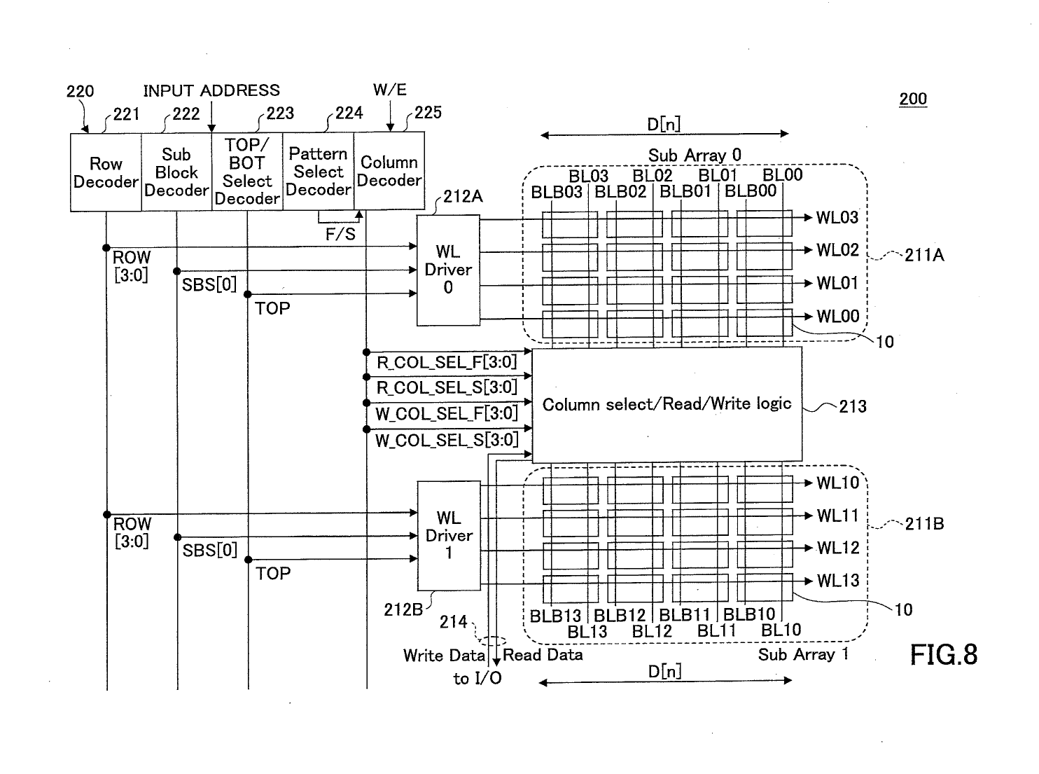

Next, referring to FIG. 8, a detailed structure of the SRAM 200 as the semiconductor memory device of the first embodiment is described.

FIG. 8 illustrates a part of the SRAM 200 of the first embodiment.

The part of the SRAM 200 illustrated in FIG. 8 corresponds to a portion of the bit D[n] of the sub block 210 (Sub Block 0) connected with the upper side of the input-output port I/O illustrated in FIG. 7, the word line drivers 212A and 212B, the column selection and read-write circuit 213, the global bit line 214, and the decoder 220.

The data are read out and written in the SRAM 200 in conformity with a read instruction and a write instruction, which are input from the processor core 111.

Each of the sub arrays 211A and 211B include the bit cells 10 as a plurality of memory cells arranged like the array.

The bit cells 10 used in the SRAM 200 of the first embodiment are similar to the bit cells 10 of the 6-transistor type of the comparative example. Therefore, the operation of the bit cells is omitted.

A connection between the source of and the drain of the MOS transistor 13 included in the bit cell may be reverse of the connection illustrated in FIGS. 1-2. In a manner similar to the above, a connection between the source of and the drain of the MOS transistor 14 may be reverse to the connection illustrated in FIGS. 1-2. Further, within the first embodiment, instead of the bit cell 10 of the 6-transistor type illustrated in FIGS. 1-2, the bit cell 20 of the 8-transistor type illustrated in FIG. 3 may be used.

In the SRAM 30 (see FIG. 4) of the comparative example, each of the plurality of bit cells having the same address is allocated to each bit included in one sub array. Therefore, as illustrated in FIG. 4, the bit cells having the same address are included in the adjacent bits D[n+1] and D[n].

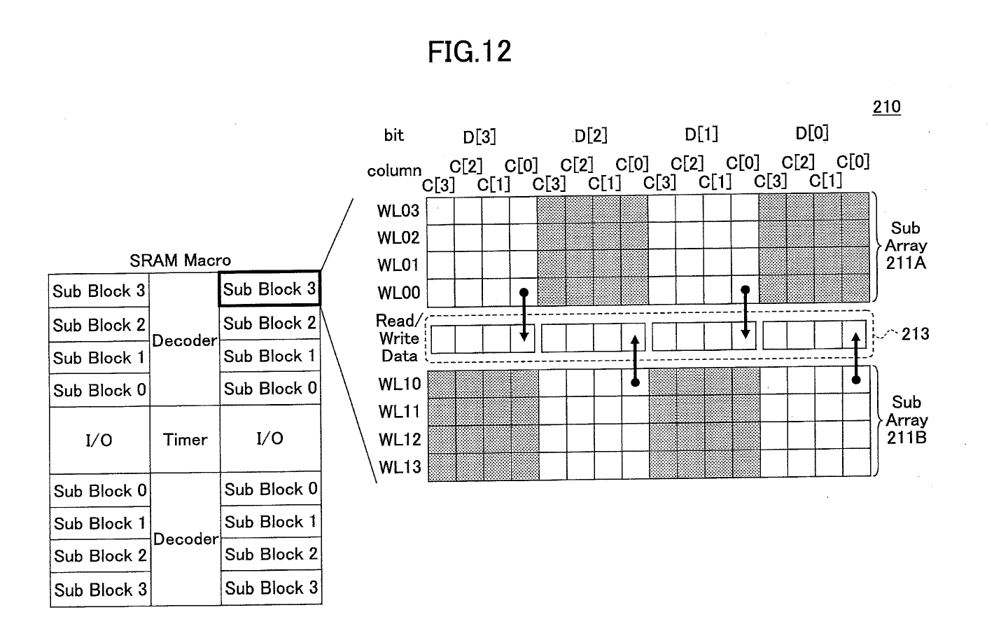

On the contrary to the above, in the SRAM 200 of the first embodiment, the bit cells having the same address are not allocated to the adjacent bits. In the SRAM 200 of the first embodiment, the bit cells having the same address are allocated to the 2 sub arrays 211A and 211B included in the one sub block 210, respectively (see FIG. 12). The bits including bit cells having the same address are arranged in a zigzag-like formation through the sub arrays 211A and 211B. Said differently, the bit cells having the same address are allocated into the bits asymmetrically positioned in the sub array 211A and the sub array 211B relative to the column selection and read-write circuit 213.

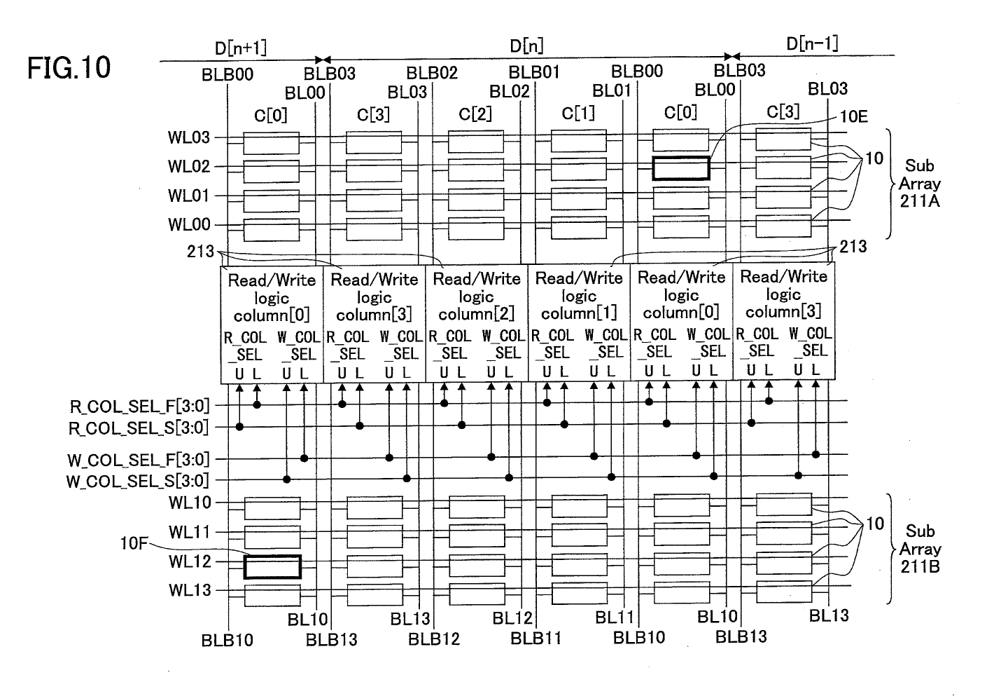

Hereinafter, “n” of the bit D[n] is called a “bit sequence number”. Said differently, in the sub block 210, the bit cells 10 having the same address are allocated to a bit inside the sub array 211A whose bit sequence number is odd and a bit inside the sub array 211B whose bit sequence number is even. Further, in the sub block 210, the bit cells 10 having the same address are allocated to a bit inside the sub array 211A whose bit sequence number is even and a bit inside the sub array 211B whose bit sequence number is odd. Such allocations of the addresses are described in detail with reference to FIGS. 10 to 12.

Therefore, in the SRAM 200 of the first embodiment, the read instruction includes an input address identifying the bit cells 10 in the sub arrays 211A and 211B inside any one of the sub block 210 and a write enable signal W/E (having the L level). A write instruction includes an input address identifying the bit cells 10 in the sub arrays 211A and 211B inside any one of the sub block 210 and a write enable signal W/E (having the H level).

The read instruction and the write instruction are instructions requested by the processor core 111 (see FIG. 6).

In the SRAM 200 of the first embodiment, the bits including the bit cells having the same address are arranged in the zigzag-like formation through the sub arrays 211A and 211B of the sub array 210. Therefore, the data are read and write for each sub block 210.

The data are simultaneously read out of the sub arrays 211A and 211B included in any one of the great number of sub blocks 210 included in the SRAM 200.

The data are simultaneously written in the sub arrays 211A and 211B included in any one of the great number of sub blocks 210 included in the SRAM 200.

As described, the data are read out and written in for each sub block 210. Therefore, the SRAM 200 of the first embodiment selects the sub block 210. The selection of the sub block 210 is substantialized by identifying the sub block number.

As illustrated in FIG. 7, the same sub block numbers are allocated to the sub blocks above and below the input-output port I/O 230. Therefore, in order to select one sub block 210 out of the great number of sub blocks 210 inside the SRAM 200, not only the sub block number but also the upper or lower side of the column selection and read-write circuit 213 is desired.

In writing or reading of the data, there are selectable two patterns, namely writing or reading of the data for a bit whose bit sequence number is odd or for a bit whose bit sequence number is even.

The first pattern is reading or write-in of the data for a bit inside the sub array 211A whose bit sequence number is odd and for a bit inside the sub array 211B whose bit sequence number is even.

The first pattern is substantialized by allocating bit cells having the same address to the bit inside the sub array 211A whose bit sequence number is odd and to the bit inside the sub array 211B whose bit sequence number is even.

The second pattern is reading or write-in of the data for a bit inside the sub array 211A whose bit sequence number is even and for a bit inside the sub array 211B whose bit sequence number is odd.

The second pattern is substantialized by allocating bit cells having the same address to the bit inside the sub array 211A whose bit sequence number is even and to the bit inside the sub array 211B whose bit sequence number is odd.

Therefore, in the SRAM 200 of the first embodiment, the first or second pattern is selected for reading or writing of the data.

Therefore, in the SRAM 200 of the first embodiment, in comparison with the comparative example, not only the row selection (the selection of the word line) and the column selection (the selections of the bit line and of the bit line bar) but also the selection of the sub block 210, the selection of the upper or lower side of the column selection and read-write circuit 213, and the selection of the first or second pattern.

The row selection, the column selection, the selection of the sub block 210, the selection of the upper or lower side of the column selection and read-write circuit 213, and the selection of the first or second pattern is performed based on the input address included in the read instruction or the write instruction.

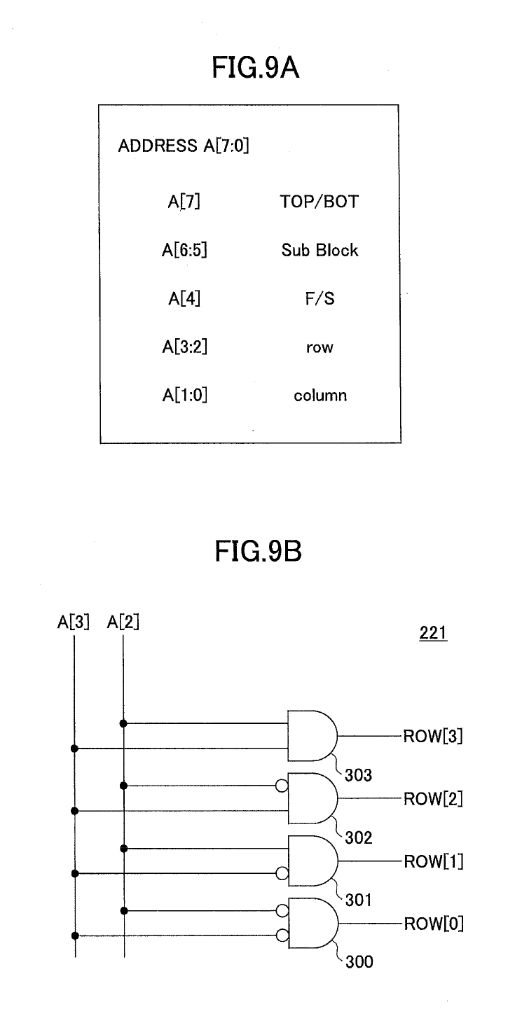

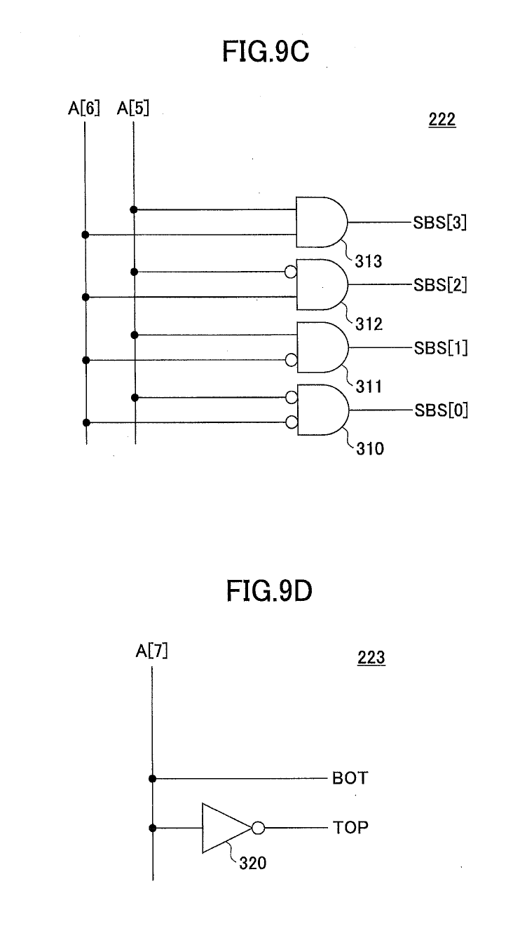

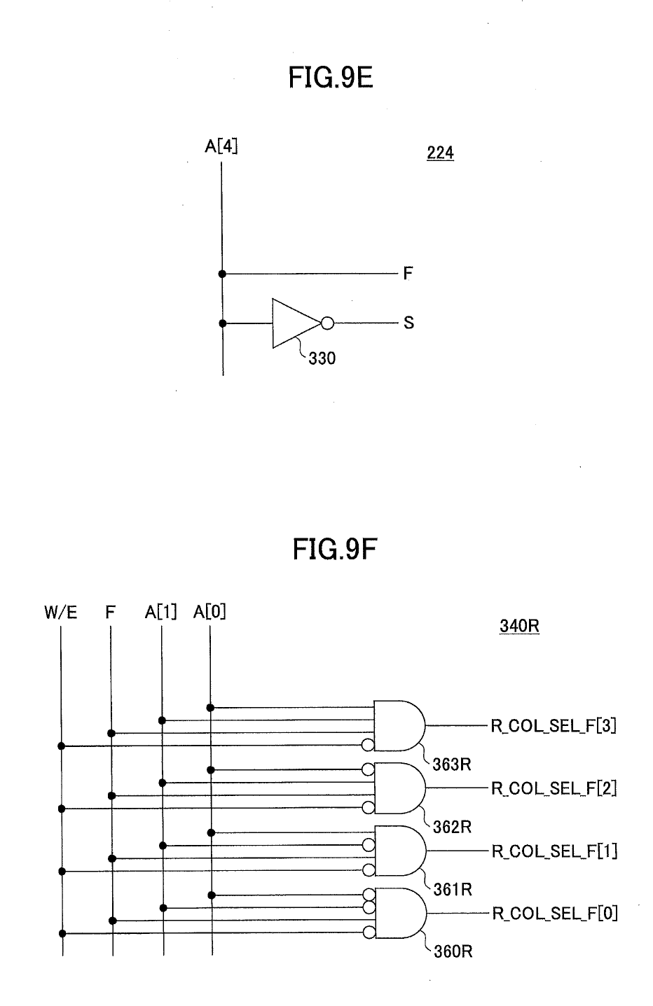

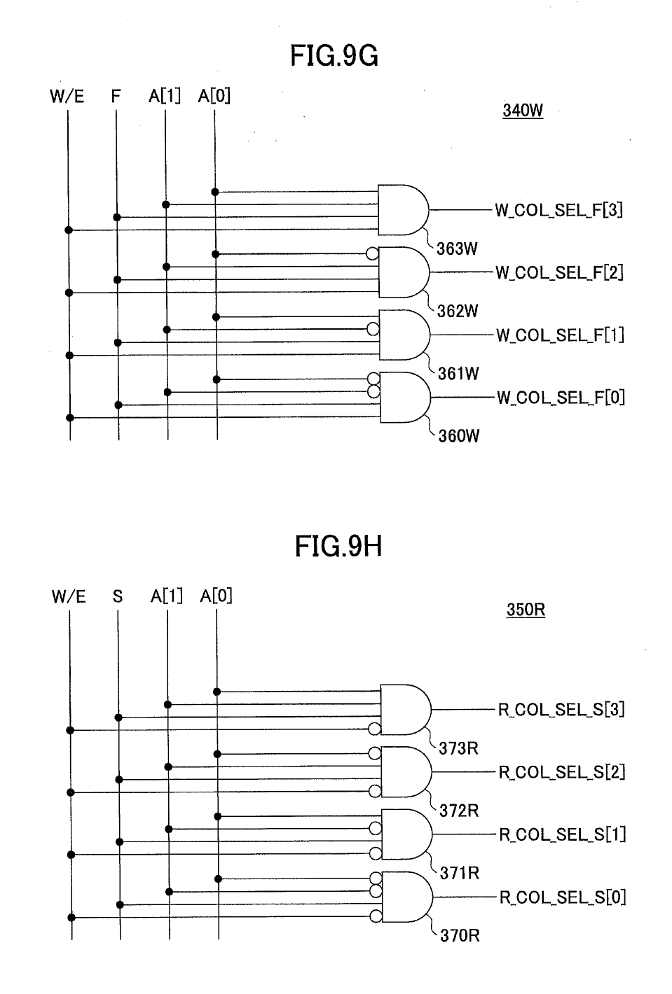

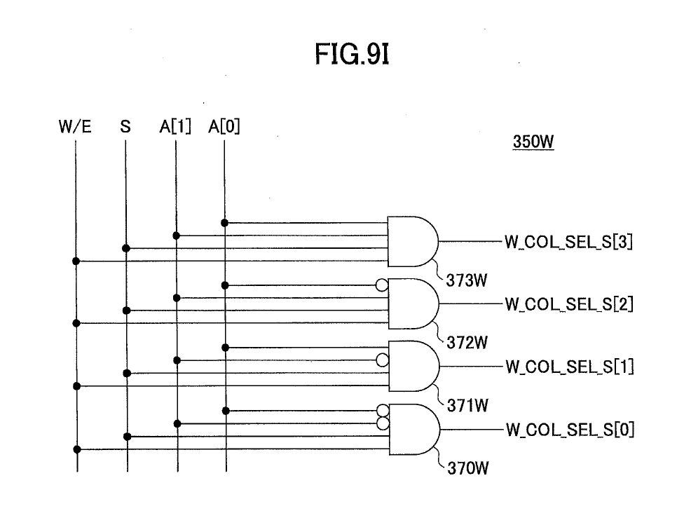

For example, through the lower to upper stages of the input address, a column address for the column selection, a row address for the row selection, a pattern selection address for the selection of the first or second pattern, a sub block address for the selection of the sub block 210, and a top or bottom selection address for the selection of the upper or lower side of the column selection and read-write circuit 213 are allocated. In this case, several bits are allocated to each of these addresses. As described later with reference to FIG. 9A, the addressees are specifically allocate.

Next, a connection relationship between the word lines and the bit lines and the decoder 220 are described.

The sub array 211A (Sub Array 0) includes 4 word lines WL00 to WL03 and 4 parts of bit lines, i.e., the BL00, BL bar (BLB) 00 to BL03, BLB03. The word lines WL00 to WL03 are connected with the word line driver 212A, and the bit lines BL00, BLB00 to BL03, BLB03 are connected with the column selection and read-write circuit 213.

Suffixes of the bit lines BL, BLB are called line numbers of the bit lines.

The sub array 211B (Sub Array 1) includes 4 word lines WL10 to WL13 and 4 parts of bit lines, i.e., the BL10, BLB 10 to BL13, BLB13. The word lines WL10 to WL13 are connected with the word line driver 212B, and the bit lines BL10, BLB10 to BL13, BLB13 are connected with the column selection and read-write circuit 213.

Each bit cell 10 is provided in crossing portions between corresponding word line and a corresponding pair of bit lines.

Further, FIG. 8 illustrates only a portion of one bit (D[n]) through the sub arrays 211A and 211B. However, the number of the bits is actually n bits. Therefore, each of the word lines extends from the word line drivers 212A and 212B to reach all the corresponding bits.

The decoder 220 includes a row decoder 221, a sub block decoder 222, atop and bottom select decoder 223, a pattern select decoder 224, and a column decoder 225. The input address is input into the decoder 220. The write enable signal W/E is input in the column decoder 225.

The numbers of the row decoder 221, the sub block decoder 222, the top and bottom select decoder 223, the pattern select decoder 224, and the column decoder 225 are one for each SRAM 200.

The row decoder 221, the sub block decoder 222, and the top and bottom select decoder 223 are connected with the word line drivers 212A and 212B through signal lines. Since the sub blocks 210 are hierarchized as illustrated in FIG. 7, the row decoder 221, the sub block decoder 222, and the top and bottom select decoder 223 are connected with all the word line drivers 212A and 212B.

Next, the row selection by the row decoder 221, the sub block selection by the sub block decoder 222, the selection of the upper or lower side of the column selection and read-write circuit 213 by the top and bottom select decoder 223, and the column selection by the column decoder 225.

The row decoder 221 is connected with the word line drivers 212A and 212B through the signal lines. The row decoder 221 decodes the row address included in the input address of the read instruction or the write instruction and outputs row selection data ROW[3:0]. The row selection data ROW[3:0] is input into the word line drivers 212A and 212B.

As a result, the word line drivers 212A and 212B select the row using the row selection data ROW[3:0], and select any one of the word lines WL00 to WL03 and any one of the word lines WL10 to WL13, respectively.

The row selection data ROW[3:0] is data which has 4 bits and input into the word line drivers 212A and 212B.

The row selection data ROW[3:0] is input from the row decoder 221 to the word line drivers 212A and 212B inside all the sub blocks arranged in 4 stages above and in 4 stages below the input-output port I/O 230 illustrated in FIG. 7. Therefore, the row selection based on the row selection data ROW[3:0] is performed in all the sub arrays 211.

The row selection data ROW[3:0] has 4 bits and includes row selection data ROW[3] of 1 bit, row selection data ROW[2] of 1 bit, row selection data ROW[1] of 1 bit, and row selection data ROW[0] of 1 bit.

The sub block decoder 222 is connected with the word line drivers 212A and 212B through the signal lines. The sub block decoder 222 decodes the sub block address included in the input address of the read instruction or the write instruction and outputs a sub block selection data SBS.

FIG. 8 illustrates only SBS[0] as the sub block selection data output through one signal line from the sub block decoder 222 because only a part inside the sub block whose sub block number is 0.

However, because there are sub blocks in 4 stages above and in 4 stages below the input-output port I/O 230 as illustrated in FIG. 7, 8 signal lines are connected with the sub block decoder 222. Further, the sub block decoder 222 outputs sub block selection data SBS[0] to SBS[3]. The suffixes of the sub block selection data SBS correspond to the sub block numbers 0 to 3.

The 8 signal lines are connected to the word line driver 212A of the sub blocks 210 in the 4 stages above and in the 4 stages below the input-output port I/O 230. The other 8 signal lines are connected to the word line driver 212B of the sub blocks 210 in the 4 stages above and in the 4 stages below the input-output port I/O 230.

The sub block selection data SBS[0] to SBS[3] are input into the word line drivers 212A and 212B of the sub blocks in the 4 stages through the 8 signal lines.

The top and bottom select decoder 223 is connected with the word line driver 212A and 212B inside the sub blocks in the 4 stages above and in the 4 stages below the input-output port I/O 230 through the signal lines as illustrated in FIG. 7. The top and bottom select decoder 223 decodes the top or bottom selection address included in the input address included in the read instruction or the write instruction, and outputs top data and bottom (hereinafter, “bot”) data.

The top data is allocated to the sub blocks 210 on the upper side of the input-output port I/O 230, and the bot data is allocated to the sub blocks 210 on the lower side of the input-output port I/O 230.

Because the sub arrays 211A and 211B illustrated in FIG. 8 are positioned on the upper side of the input-output port I/O 230, only the top data are illustrated in FIG. 8. The bottom data (bot data) are input in the sub blocks positioned on the lower side of the input-output port I/O 230 from the top and bottom select decoder 223.

In the SRAM 200 of the first embodiment, the selection of the sub block in one stage of the four stages above or below the input-output port I/O 230 is determined using the sub block selection data SBS output from the sub block decoder 222 and the top and bot data output from the top and bottom select decoder 223.

In this case, in the SRAM 200 illustrated in FIG. 7, the right and left sub blocks 210 in the same stage (having the same sub block number) positioned on right and left sides of the decoder 220 are simultaneously selected.

The sub blocks 210 selected based on the input address of the read instruction and the write instruction within one cycle for reading or writing the data are the two sub blocks 210 in the same stage positioned on the right and left sides of the decoder 220 in the SRAM illustrated in FIG. 7.

The pattern select decoder 224 is connected with the column decoder 225 through the signal line. The pattern select decoder 224 outputs first pattern selection data F or second pattern selection data S after decoding the pattern selection address included in the read or write instruction.

The first pattern selection data F and the second pattern selection data S are data for selecting the first pattern or the second pattern and input in the column decoder 225.

In a case where the first pattern selection data F is “1” and the second pattern selection data S is “0”, the first pattern is selected. On the contrary, in a case where the first pattern selection data F is “0” and the second pattern selection data is “1”, the second pattern is selected.

The first pattern indicates reading or write-in of the data for the plurality of bits cells having the same bit sequence number in a bit inside the sub array 211A whose bit sequence number is odd and in a bit inside the sub array 211B whose bit sequence number is even.

The second pattern indicates reading or write-in of the data for the plurality of bits cells having the same bit sequence number in a bit inside the sub array 211A whose bit sequence number is even and in a bit inside the sub array 211B whose bit sequence number is odd.

The column decoder 225 is connected with the column selection and read-write circuit 213 through the signal lines. The column decoder 225 is connected with the column selection and read-write circuit 213 inside all the sub blocks 210 illustrated in FIG. 7.

The first pattern selection data F, the second pattern selection data S, and the write enable signal W/E are input in addition to the column address included in the input address of the read instruction or the write instruction into the column decoder 225.

The column decoder 225 decodes the column address and outputs the data values of the first pattern selection data F and of the second pattern selection data S and the column selection data in response to the signal level of the write enable signal W/E.

The column selection data output from the column decoder 225 is provided for selecting the column inside the bits in the sub arrays 211A and 211B to substantialize reading or writing of the data in conformity with the first or second pattern.

The column selection data is input in the column selection and read-write circuit 213.

In a case where the signal level of the write enable signal W/E is the L level and the first pattern selection data F is “1”, and the second pattern selection data S is “0”, the column decoder 225 outputs the column selection data R_COL_SEL_F[3:0].

The column selection data R_COL_SEL_F[3:0] is provided to select a column in the bits inside the sub arrays 211A and 211B in order to substantialize reading of the data in conformity with the first pattern.

The column selection data R_COL_SEL_F[3:0] causes any pair of bit lines BL and BLB of the bits in the sub array 211A whose bit sequence numbers are odd and any pair of bit lines BL and BLB of the bits in the sub array 211B whose bit sequence numbers are even to be selected in conformity with the first pattern in order to read the data.

In a case where the signal level of the write enable signal W/E is the L level and the first pattern selection data F is “0”, and the second pattern selection data S is “1”, the column decoder 225 outputs the column selection data R_COL_SEL_S[3:0].

The column selection data R_COL_SEL_S[3:0] is provided for selecting the column in the bits inside the sub arrays 211A and 211B in order to substantialize reading of the data in conformity with the second pattern.

The column selection data R_COL_SEL_S[3:0] causes any pair of bit lines BL and BLB of the bits in the sub array 211A whose bit sequence numbers are even and any pair of bit lines BL and BLB of the bits in the sub array 211B whose bit sequence numbers are odd to be selected in conformity with the second pattern in order to read the data.

Although only one bit D[n] is illustrated in FIG. 8, a great number of bits are included in the sub arrays 211A and 211B. Based on the column selection data, any pair of the bit lines BL and BLB in the bits whose bit sequence numbers are odd and any pair of the bit lines BL and BLB in the bits whose bit sequence numbers are even are selected.

In a case where the signal level of the write enable signal W/E is the H level and the first pattern selection data F is “1”, and the second pattern selection data S is “0”, the column decoder 225 outputs the column selection data W_COL_SEL_F[3:0].

The column selection data W_COL_SEL_F[3:0] is provided to select a column in the bits inside the sub arrays 211A and 211B in order to substantialize writing of the data in conformity with the first pattern.

The column selection data W_COL_SEL_F[3:0] causes any pair of bit lines BL and BLB of the bits in the sub array 211A whose bit sequence numbers are odd and any pair of bit lines BL and BLB of the bits in the sub array 211B whose bit sequence numbers are even to be selected in conformity with the first pattern in order to write the data.

In a case where the signal level of the write enable signal W/E is the H level and the first pattern selection data F is “0”, and the second pattern selection data S is “1”, the column decoder 225 outputs the column selection data W_COL_SEL_S[3:0].

The column selection data W_COL_SEL_S[3:0] is provided to select a column in the bits inside the sub arrays 211A and 211B in order to substantialize writing of the data in conformity with the second pattern.

The column selection data W_COL_SEL_S[3:0] causes any pair of bit lines BL and BLB of the bits in the sub array 211A whose bit sequence numbers are even and any pair of bit lines BL and BLB of the bits in the sub array 211B whose bit sequence numbers are odd to be selected in conformity with the second pattern in order to write the data.

Each of the column selection data R_COL_SEL_F[3:0], R_COL_SEL_S[3:0], W_COL_SEL_F[3:0], and W_COL_SEL_S[3:0] indicate all column selection data of 4 bits.

For example, the column selection data R_COL_SEL_F[3:0] includes R_COL_SEL_F[3], R_COL_SEL_F[2], R_COL_SEL_F[1], and R_COL_SEL_F[0]. Such a feature is the same in the column selection data R_COL_SEL_S[3:0], W_COL_SEL_F[3:0], and W_COL_SEL_S[3:0].

Next, the column selection and read-write circuit 213 is described.

The bit lines BL00 to BL03, BLB00 to BLB03, BL10 to BL13, and BLB10 to BLB13 are connected with the column selection and read-write circuit 213.

The column selection and read-write circuit 213 selects the bit lines based on the column selection data input from the column decoder 225.

The column selection and read-write circuit 213 can select the bit lines BL and BLB, switch between reading and writing, send the write data, and receive the read data based on the column selection data input from the column decoder 225.

The column selection and read-write circuit 213 selects a pair of the bit lines BL and BLB having the same line number when the column selection data is input from the column decoder 225 in order to read or write the data.

Further, the global bit line 214 is connected with the column selection and read-write circuit 213. The global bit line 214 transmits the read data or the write data between the column selection and read-write circuit 213 and the input-output port I/O 230 (see FIG. 7).

The global bit line 214 transfers the data read through the bit lines BL, BLB to the input-output port I/O 230 (see FIG. 7), and also transfers the write data from the input-output port I/O 230 to the bit lines BL, BLB.

In the column selection and read-write circuit 213, a part of selecting the bit line may be of any type as far as the 4 pairs of bit lines included in each of the 2 sub arrays 211A and 211B, namely the bit lines BL00, BLB00 to BL03, BLB03 and BL10, BLB10 to BL13, BLB13, can be selected based on the column selection data transferred from the column decoder 225.

Further, in the column selection and read-write circuit 213, a part of reading and writing the data is of any type as far as a read process or a write process can be switched based on the column data corresponding to the signal level of the write enable signal W/E and can send and receive the data between the column selection and read-write circuit 213 and the global bit line 214.

Because there are a great number of sub blocks 210 as illustrated in FIG. 7, the column is selected out of all the sub blocks 210 by the column decoder 225.

Next, referring to FIGS. 9A to 9I, the data structure of the input address and the circuit structure of the decoder 220 are explained.

FIG. 9A illustrates an exemplary allocation of the input address for the SRAM 200 of the first embodiment. The input address A[7:0] is data having 8 bits and includes a column address (column), a row address (row), a pattern selection address (F/S), a sub block address (Sub Block), and a top or bottom selection address (Top/Bot).

A[1:0] of 2 bits is allocated to the column address (column). A[3:2] of 2 bits is allocated to the row address (row). A[4] of 1 bit is allocated to the pattern selection address (F/S). A[6:5] of 2 bits is allocated to the sub block address (Sub Block). A[7] of 1 bit is allocated to the top or bottom selection address (Top/Bot).

FIG. 9B illustrates a circuit of a row decoder of the SRAM 200 of the first embodiment.

The row decoder 221 includes a logical AND circuits 300, 301, 302, and 303 of the two-input type. Two signal lines are connected with each of the logical AND circuits 300 to 303. The row addresses A[3] and A[2] are input into the two signal lines, respectively.

The logical AND circuits 300, 301, 302, and 303 output row selection data ROW[0], ROW[1], ROW[2], and ROW[3], respectively.

The row selection data ROW[0] is provided to select the word lines WL00 and WL10 illustrated in FIG. 8. Similarly, the row selection data ROW[1], ROW[2], and ROW[3] are row selection data for selecting the word lines WL01 and WL11, WL02 and WL12, and WL03 and WL13, respectively.

The row addresses A[3] and A[2] undergo the NOT operation and are input into the logical AND circuit 300. The row address A[3] undergoes the NOT operation and is input into the logical AND circuit 301. The row address A[2] is input into the logical AND circuit 301 as-is. The row address A[3] is input into the logical AND circuit 302 as-is. The row address A[2] undergoes the NOT operation and is input into the logical AND circuit 302. The row addresses A[3] and A[2] are input into the logical AND circuit 303 as-is.

In the row decoder 221, in a case where the row addresses A[3] and A[2] are “0” and “0”, respectively, the row selection data ROW[0] is set to “1” and the row selection data ROW[1], ROW[2], and ROW[3] are set to “0”.

In the row decoder 221, in a case where the row addresses A[3] and A[2] are “0” and “1”, respectively, the row selection data ROW[1] is set to “1” and the row selection data ROW[1], ROW[2], and ROW[3] are set to “0”.

In the row decoder 221, in a case where the row addresses A[3] and A[2] are “1” and “0”, respectively, the row selection data ROW[2] is set to “1” and the row selection data ROW[0], ROW[1], and ROW[3] are set to “0”.

In the row decoder 221, in a case where the row addresses A[3] and A[2] are “1” and “1”, respectively, the row selection data ROW[3] is set to “1” and the row selection data ROW[0], ROW[1], and ROW[2] are set to “0”.

Next, referring to FIG. 9C, the circuit of the sub block decoder 222 is described.

FIG. 9C illustrates the circuit of the sub block decoder of the SRAM 200 of the first embodiment.

In a manner similar to the row decoder 221, the sub block decoder 222 includes logical AND circuits of the two-input type 310, 311, 312, and 313. Two signal lines are connected with each of the logical AND circuits 310 to 313. The sub block addresses A[6] and A[5] are input into the two signal lines, respectively.

The logical AND circuits 310, 311, 312, and 313 outputs the sub block selection data SBS [0], SBS[1], SBS[2], and SBS[3], respectively.

The sub block selection data SBS[0] is provided to select the sub block 210 (Sub Block 0) whose sub block number is 0 illustrated in FIG. 7. Similarly, the sub block selection data SBS[1], SBS[2], and SBS[3] are provided to select the sub blocks 210 (Sub Block 1, Sub Block 2, and Sub Block 3) whose sub block numbers are 1, 2, and 3 illustrated in FIG. 7.

The sub block selection addresses A[6] and A[5] undergo the NOT operation and are input into the logical AND circuit 310. The sub block selection address A[6] undergoes the NOT operation and is input into the logical AND circuit 311. The sub block selection address A[5] is input into the logical AND circuit 311 as-is. The sub block selection address A[6] is input into the logical AND circuit 312 as-is. The sub block selection address A[5] undergoes the NOT operation and is input into the logical AND circuit 312. The sub block selection addresses A[6] and A[5] undergo the NOT operation and are input into the logical AND circuit 313.

In the sub block decoder 222, in a case where the sub block selection addresses A[6] and A[5] are “0” and “0”, respectively, a sub block selection data SBS[0] is set to “1”, and sub block selection data SBS[1], SBS[2], and SBS[3] are set to “0”.

In the sub block decoder 222, in a case where the sub block selection addresses A[6] and A[5] are “0” and “1”, respectively, the sub block selection data SBS[1] is set to “1”, and the sub block selection data SBS[0], SBS[2], and SBS[3] are set to “0”.

In the sub block decoder 222, in a case where the sub block selection addresses A[6] and A[5] are “1” and “0”, respectively, the sub block selection data SBS [2] is set to “1”, and sub block selection data SBS [0], SBS[1], and SBS[3] are set to “0”.

In the sub block decoder 222, in a case where the sub block selection addresses A[6] and A[5] are “1” and “1”, respectively, the sub block selection data SBS[3] is set to “1”, and the sub block selection data SBS[0], SBS[1], and SBS[2] are set to “0”.

Next, referring to FIG. 9D, a circuit of the top and bottom select decoder 223 is described.

FIG. 9D illustrates the circuit of a top and bottom select decoder of the SRAM 200 of the first embodiment.

The top and bottom select decoder 223 includes the circuit of a one-input and two-output type. The top and bottom select decoder 223 decodes the top or bottom selection address A[7] and outputs a TOP data and a BOT data. The TOP data is changed by an inverter 320 to an inverted value of data value of the top or bottom selection address A[7]. The inverter 320 outputs the TOP data. The BOT data has the data value of the top or bottom selection address A[7].

As described above, the TOP data is input into the word line drivers 212A and 212B of the sub block 210 arranged on the upper side of the input-output port I/O 230 illustrated in FIG. 7.

As described above, the BOT data is input into the word line drivers 212A and 212B of the sub block 210 arranged on the lower side of the input-output port I/O 230 illustrated in FIG. 7.

In a case where the TOP data is “1” and the BOT data is “0”, the sub block 210 arranged on the upper side of the input-output port I/O 230 is selected. On the other hand, in a case where the TOP data is “0” and the BOT data is “1”, the sub block 210 arranged on the lower side of the input-output port I/O 230 is selected.

Next, referring to FIG. 9E, a circuit of the top and bottom select decoder 224 is described.

FIG. 9E illustrates the circuit of the pattern select decoder 224 of the SRAM 200 of the first embodiment.

The pattern select decoder 224 includes the circuit of a one-input and two-output type. The pattern select decoder 224 decodes the pattern selection address A[4] and outputs the first pattern selection data F and the second pattern selection data S. The first pattern selection data F has the data value of the pattern selection address A[4] and is output. The second pattern selection data S is inverted by the inverter 330 to have an inverted value of the data value of the pattern selection address A[4] and is output.

The first pattern selection data F and the second pattern selection data S are data for selecting the first pattern or the second pattern and input in the column decoder 225.

In a case where the first pattern selection data F is “1” and the second pattern selection data S is “0”, the first pattern is selected. On the contrary, in a case where the first pattern selection data F is “0” and the second pattern selection data is “1”, the second pattern is selected.

Referring to FIG. 9F to FIG. 9I, a circuit of the column decoder 225 is described.

The column decoder 225 decodes the column address and outputs the data values of the first pattern selection data F and of the second pattern selection data S and the column selection data in response to the signal level of the write enable signal W/E.

FIGS. 9F to 9I illustrate a circuit for decoding the column address included in the column decoder 225 of the SRAM 200 of the first embodiment.

The column decoder 225 includes a circuit 340R for decoding the column address to read the data under the first pattern and a circuit 340W for decoding the column address to write the data under the first pattern.

The column decoder 225 includes a circuit 350R for decoding the column address to read the data under the second pattern and a circuit 350W for decoding the column address to write the data under the second pattern.

As illustrated in FIG. 9F, the circuit 340R for decoding the column address to read the data under the first pattern includes logical AND circuits of the four-input type 360R, 361R, 362R, and 363R. 4 signal lines are connected with each of the logical AND circuits 360R to 363R. The first pattern selection data F, the column address A[1], the column address A[0], and the write enable signal W/E are input in the logical AND circuits 360R to 363R.

The logical AND circuits 3608, 361R, 362R, and 363R output the column selection data R_COL_SEL_F[0], R_COL_SEL_F[1], R_COL_SEL_F[2], and R_COL_SEL_F[3], respectively.

The column selection data R_COL_SEL_F[0] is provided to select the bit lines BL00 and BLB00 and the bit lines BL10 and BLB10 illustrated in FIG. 8 in order to read the data under the first pattern.

The column selection data R_COL_SEL_F[1] is provided to select the bit lines BL01 and BLB01 and the bit lines BL11 and BLB11 illustrated in FIG. 8 in order to read the data under the first pattern.

The column selection data R_COL_SEL_F[2] is provided to select the bit lines BL02 and BLB02 and the bit lines BL12 and BLB12 illustrated in FIG. 8 in order to read the data under the first pattern.

The column selection data R_COL_SEL_F[3] is provided to select the bit lines BL03 and BLB03 and the bit lines BL13 and BLB13 illustrated in FIG. 8 in order to read the data under the first pattern.

Into the logical AND circuit 360R, the first pattern selection data F, a value of the column address A[1] operated using the NOT operation, a value of the column address A[0] operated using the NOT operation, and a value of the write enable signal W/E operated using the NOT operation are input.

Into the logical AND circuit 361R, the first pattern selection data F, the value of the column address A[1] operated using the NOT operation, the column address A[0], and the value of the write enable signal W/E operated using the NOT operation are input.

Into the logical AND circuit 362R, the first pattern selection data F, the column address A[1], the value of the column address A[0] operated using the NOT operation, and the value of the write enable signal W/E operated using the NOT operation are input.

Into the logical AND circuit 363R, the first pattern selection data F, the column address A[1], the column address A[0], and the value of the write enable signal W/E operated using the NOT operation are input.

In a case where the first pattern selection data F is “1”, the column addresses A[1] and A[0] are “0” and “0”, respectively and the write enable signal W/E is in the L level, the column decoder 225 sets the column selection data R_COL_SEL_F[0] to “1” and the column selection data R_COL_SEL_F[1], R_COL_SEL_F[2], and R_COL_SEL_F[3] to “0”.

In a case where the first pattern selection data F is “1”, the column addresses A[1] and A[0] are “0” and “1”, respectively and the write enable signal W/E is in the L level, the column decoder 225 sets the column selection data R_COL_SEL_F[1] to “1” and the column selection data R_COL_SEL_F[0], R_COL_SEL_F[2], and R_COL_SEL_F[3] to “0”.

In a case where the first pattern selection data F is “1”, the column addresses A[1] and A[0] are “1” and “0”, and the write enable signal W/E is in the L level, the column decoder 225 sets the column selection data R_COL_SEL_F[2] to “1” and the column selection data R_COL_SEL_F[0], R_COL_SEL_F[1], and R_COL_SEL_F[3] to “0”.

In a case where the first pattern selection data F is “1”, the column addresses A[1] and A[0] are “1” and “1”, respectively and the write enable signal W/E is in the L level, the column decoder 225 sets the column selection data R_COL_SEL_F[3] to “1” and the column selection data R_COL_SEL_F[0], R_COL_SEL_F[1], and R_COL_SEL_F[2] to “0”.

In a case where the first pattern selection data F is “0”, the data is not read under the first pattern. Therefore, all the column selection data R_COL_SEL_F[0], R_COL_SEL_F[1], R_COL_SEL_F[2], and R_COL_SEL_F[3] are set to “0”.

As illustrated in FIG. 9G, the circuit 340W for decoding the column address to write the data under the first pattern includes logical AND circuits of the four-input type 360W, 361W, 362W, and 363W. 4 signal lines are connected with each of the logical AND circuits 360W to 363W. The first pattern selection data F, the column address A[1], the column address A[0], and the write enable signal W/E are input in the logical AND circuits 360W to 363W.

The logical AND circuits 360W, 361W, 362W, and 363W output the column selection data W_COL_SEL_F[0], W_COL_SEL_F[1], W_COL_SEL_F[2], and W_COL_SEL_F[3], respectively.

The column selection data W_COL_SEL_F[0] is provided to select the bit lines BL00 and BLB00 and the bit lines BL10 and BLB10 illustrated in FIG. 8 in order to write the data under the first pattern.

The column selection data W_COL_SEL_F[1] is provided to select the bit lines BL01 and BLB01 and the bit lines BL11 and BLB11 illustrated in FIG. 8 in order to write the data under the first pattern.

The column selection data W_COL_SEL_F[2] is provided to select the bit lines BL02 and BLB02 and the bit lines BL12 and BLB12 illustrated in FIG. 8 in order to write the data under the first pattern.

The column selection data W_COL_SEL_F[3] is provided to select the bit lines BL03 and BLB03 and the bit lines BL13 and BLB13 illustrated in FIG. 8 in order to write the data under the first pattern.

Into the logical AND circuit 361W, the first pattern selection data F, the value of the column address A[1] operated using the NOT operation, the column address A[0], and a value of the write enable signal W/E operated using the NOT operation are input.

Into the logical AND circuit 361W, the first pattern selection data F, the value of the column address A[1] operated using the NOT operation, the column address A[0], and the write enable signal W/E are input.

Into the logical AND circuit 362W, the first pattern selection data F, the column address A[1], the value of the column address A[0] operated using the NOT operation, and the write enable signal W/E are input.

Into the logical AND circuit 363W, the first pattern selection data F, the column address A[1], the value of the column address A[0] operated using the NOT operation, and the write enable signal W/E are input.

In a case where the first pattern selection data F is “1”, the column addresses A[1] and A[0] are “0” and “0”, respectively and the write enable signal W/E is in the H level, the column decoder 225 sets the column selection data W_COL_SEL_F[0] to “1” and the column selection data W_COL_SEL_F[1], W_COL_SEL_F[2], and W_COL_SEL_F[3] to “0”.

In a case where the first pattern selection data F is “1”, the column addresses A[1] and A[0] are “0” and “1”, respectively and the write enable signal W/E is in the H level, the column decoder 225 sets the column selection data W_COL_SEL_F[1] to “1” and the column selection data W_COL_SEL_F[0], W_COL_SEL_F[2], and W_COL_SEL_F[3] to “0”.

In a case where the first pattern selection data F is “1”, the column addresses A[1] and A[0] are “1” and “0”, respectively and the write enable signal W/E is in the H level, the column decoder 225 sets the column selection data W_COL_SEL_F[2] to “1” and the column selection data W_COL_SEL_F[0], W_COL_SEL_F[1], and W_COL_SEL_F[3] to “0”.

In a case where the first pattern selection data F is “1”, the column addresses A[1] and A[0] are “1” and “1”, respectively and the write enable signal W/E is in the H level, the column decoder 225 sets the column selection data W_COL_SEL_F[3] to “1” and the column selection data W_COL_SEL_F[0], W_COL_SEL_F[1], and W_COL_SEL_F[2] to “0”.

In a case where the first pattern selection data F is “0”, the data is not written under the first pattern. Therefore, all the column selection data W_COL_SEL_F[0], W_COL_SEL_F[1], W_COL_SEL_F[2], and W_COL_SEL_F[3] are set to “0”.

As illustrated in FIG. 9H, the circuit 350R for decoding the column address to read the data under the second pattern includes logical AND circuits of the four-input type 370R, 371R, 372R, and 373R. 4 signal lines are connected with each of the logical AND circuits 370R to 373R. The second pattern selection data S, the column address A[1], the column address A[0], and the write enable signal W/E are input in the logical AND circuits 370R to 373R.

The logical AND circuits 370R, 371R, 372R, and 373R output the column selection data R_COL_SEL_S[0], R_COL_SEL_S[1], R_COL_SEL_S[2], and R_COL_SEL_S[3], respectively.

The column selection data R_COL_SEL_S[0] is provided to select the bit lines BL00 and BLB00 and the bit lines BL10 and BLB10 illustrated in FIG. 8 in order to read the data under the second pattern.

The column selection data R_COL_SEL_S[1] is provided to select the bit lines BL01 and BLB01 and the bit lines BL11 and BLB11 illustrated in FIG. 8 in order to read the data under the second pattern.

The column selection data R_COL_SEL_S[2] is provided to select the bit lines BL02 and BLB02 and the bit lines BL12 and BLB12 illustrated in FIG. 8 in order to read the data under the second pattern.

The column selection data R_COL_SEL_S[3] is provided to select the bit lines BL03 and BLB03 and the bit lines BL13 and BLB13 illustrated in FIG. 8 in order to read the data under the second pattern.

Into the logical AND circuit 370R, the second pattern selection data S, a value of the column address A[1] operated using the NOT operation, a value of the column address A[0] operated using the NOT operation, and a value of the write enable signal W/E operated using the NOT operation are input.

Into the logical AND circuit 371R, the second pattern selection data S, the value of the column address A[1] operated using the NOT operation, the column address A[0], and the value of the write enable signal W/E operated using the NOT operation are input.

Into the logical AND circuit 372R, the second pattern selection data S, the column address A[1], the value of the column address A[0] operated using the NOT operation, and the value of the write enable signal W/E operated using the NOT operation are input.

Into the logical AND circuit 373R, the second pattern selection data S, the column address A[1], the column address A[0], and the value of the write enable signal W/E operated using the NOT operation are input.

In a case where the second pattern selection data S is “1”, the column addresses A[1] and A[0] are “0” and “0”, and the write enable signal W/E is in the L level, the column decoder 225 sets the column selection data R_COL_SEL_S[0] to “1” and the column selection data R_COL_SEL_S[1], R_COL_SEL_S[2], and R_COL_SEL_S[3] to “0”.

In a case where the second pattern selection data S is “1”, the column addresses A[1] and A[0] are “0” and “1”, and the write enable signal W/E is in the L level, the column decoder 225 sets the column selection data R_COL_SEL_S[1] to “1” and the column selection data R_COL_SEL_S[0], R_COL_SEL_S[2], and R_COL_SEL_S[3] to “0”.

In a case where the second pattern selection data S is “1”, the column addresses A[1] and A[0] are “1” and “0”, and the write enable signal W/E is in the L level, the column decoder 225 sets the column selection data R_COL_SEL_S[2] to “1” and the column selection data R_COL_SEL_S[0], R_COL_SEL_S[1], and R_COL_SEL_S[3] to “0”.

In a case where the second pattern selection data S is “1”, the column addresses A[1] and A[0] are “1” and “1”, and the write enable signal W/E is in the L level, the column decoder 225 sets the column selection data R_COL_SEL_S[3] to “1” and the column selection data R_COL_SEL_S[0], R_COL_SEL_S[1], and R_COL_SEL_S[2] to “0”.

In a case where the second pattern selection data S is “0”, the data is not read under the second pattern. Therefore, all the column selection data R_COL_SEL_S[0], R_COL_SEL_S[1], R_COL_SEL_S[2], and R_COL_SEL_S[3] are set to “0”.

As illustrated in FIG. 9I, a circuit 350W for decoding the column address to write the data under the second pattern includes logical AND circuits of the four-input type 370W, 371W, 372W, and 373W. 4 signal lines are connected with each of the logical AND circuits 370W to 373W. The second pattern selection data S, the column address A[1], the column address A[0], and the write enable signal W/E are input in the logical AND circuits 370W to 373W.

The logical AND circuits 370W, 371W, 372W, and 373W output the column selection data W_COL_SEL_S[0], W_COL_SEL_S[1], W_COL_SEL_S[2], and W_COL_SEL_S[3], respectively.

The column selection data W_COL_SEL_S[0] is provided to select the bit lines BL00 and BLB00 and the bit lines BL10 and BLB10 illustrated in FIG. 8 in order to write the data under the second pattern.

The column selection data W_COL_SEL_S[1] is provided to select the bit lines BL01 and BLB01 and the bit lines BL11 and BLB11 illustrated in FIG. 8 in order to write the data under the second pattern.

The column selection data W_COL_SEL_S[2] is provided to select the bit lines BL02 and BLB02 and the bit lines BL12 and BLB12 illustrated in FIG. 8 in order to write the data under the second pattern.

The column selection data W_COL_SEL_S[3] is provided to select the bit lines BL03 and BLB03 and the bit lines BL13 and BLB13 illustrated in FIG. 8 in order to write the data under the second pattern.

Into the logical AND circuit 370W, the second pattern selection data S, the value of the column address A[1] operated using the NOT operation, the column address A[0], and the write enable signal W/E operated using the NOT operation are input.

Into the logical AND circuit 371W, the second pattern selection data S, the value of the column address A[1] operated using the NOT operation, the column address A[0], and the write enable signal W/E are input.

Into the logical AND circuit 372W, the second pattern selection data S, the column address A[1], the value of the column address A[0] operated using the NOT operation, and the write enable signal W/E are input.

Into the logical AND circuit 373W, the second pattern selection data S, the column address A[1], the column address A[0], and the write enable signal W/E are input.

In a case where the second pattern selection data R is “1”, the column addresses A[1] and A[0] are “0” and “0”, respectively and the write enable signal W/E is in the H level, the column decoder 225 sets the column selection data W_COL_SEL_S[0] to “1” and the column selection data W_COL_SEL_S[1], W_COL_SEL_S[2], and W_COL_SEL_S[3] to “0”.

In a case where the second pattern selection data S is “1”, the column addresses A[1] and A[0] are “0” and “1”, respectively and the write enable signal W/E is in the H level, the column decoder 225 sets the column selection data W_COL_SEL_S[1] to “1” and the column selection data W_COL_SEL_S[0], W_COL_SEL_S[2], and W_COL_SEL_S[3] to “0”.

In a case where the second pattern selection data S is “1”, the column addresses A[1] and A[0] are “1” and “0”, respectively and the write enable signal W/E is in the H level, the column decoder 225 sets the column selection data W_COL_SEL_S[2] to “1” and the column selection data W_COL_SEL_S[0], W_COL_SEL_S[1], and W_COL_SEL_S[3] to “0”.

In a case where the second pattern selection data S is “1”, the column addresses A[1] and A[0] are “1” and “1”, respectively and the write enable signal W/E is in the H level, the column decoder 225 sets the column selection data W_COL_SEL_S[3] to “1” and the column selection data W_COL_SEL_S[0], W_COL_SEL_S[1], and W_COL_SEL_S[2] to “0”.

In a case where the second pattern selection data S is “0”, the data is not written under the second pattern. Therefore, all the column selection data W_COL_SEL_S[0], W_COL_SEL_S[1], W_COL_SEL_S[2], and W_COL_SEL_S[3] are set to “0”.

Referring to FIG. 10, the column selection data R_COL_SEL_F[3:0], R_COL_SEL_S[3:0], W_COL_SEL_F[3:0], and W_COL_SEL_S[3:0] and selections of the bits are described.

FIG. 10 illustrates a column selection and read-write circuit 213 of the SRAM 200 and signal lines for transmitting column selection data connected with the column selection and read-write circuit 213 to explain a connection between the column selection and read-write circuit 213 and the signal lines.

In FIG. 10, 4 columns inside bits D[n] in the sub arrays 211A and 211B are designated by C[0], C[1], C[2], and C[3]. Further, FIG. 10 illustrates columns C[3] inside the bits D[n−1] adjacent to the bits D[n] and columns C[0] inside the bits D[n+1] adjacent to the bits D[n].

The bit lines BL00, BLB00 to the bit lines BL03, BLB03 are included in the columns C[0] to C[3] inside the sub array 211A, respectively.

The bit lines BL10, BLB10 to the bit lines BL13, BLB13 are included in the columns C[0] to C[3] inside the sub array 211B, respectively.

Inside the sub array 211A, the four word lines WL00 to WL03 are arranged. Inside the sub array 211B, the four word lines WL10 to WL13 are arranged.

One bit cell 10 is arranged at each intersection point between the bit lines BL00, BLB00 to the bit lines BL03, BLB03 and the bit lines BL10, BLB10 to the bit lines BL13, BLB13 and the word lines WL00 to WL03 and the word lines WL10 to WL13. Total 48 bit cells are illustrated in FIG. 10.

The column selection and read-write circuit 213 is provided for each column.

Here, the bit sequence number of the bit D[n] is odd, and the bit sequence numbers of the bits D[n−1] and D[n+1] are even.

As described, the first pattern indicates reading or writing of the data for the plurality of bits cells having the same bit sequence number in a bit inside the sub array 211A whose bit sequence number is odd and in a bit inside the sub array 211B whose bit sequence number is even.

Further, the second pattern indicates reading or writing of the data for the plurality of bits cells having the same bit sequence number in a bit inside the sub array 211A whose bit sequence number is even and in a bit inside the sub array 211B whose bit sequence number is odd.

There are four types in the column selection data, i.e., R_COL_SEL_F[3:0], R_COL_SEL_S[3:0], W_COL_SEL_F[3:0], and W_COL_SEL_S[3:0].

The column selection and read-write circuit 213 allocates input destinations of the column selection data of the four types to any one of the bits on the upper or lower side of the column selection and read-write circuit 213 for each bit to substantialize reading and writing of the data under the first or second pattern.

Here, the column selection data for selecting the bit in the sub array 211A on the upper side of the column selection and read-write circuit 213 inside the sub block 210 to read the data is designated by is R_COL_SEL_U.

Further, the column selection data for selecting the bit in the sub array 211B on the lower side of the column selection and read-write circuit 213 inside the sub block 210 to read the data is designated by is R_COL_SEL_L.

Here, the column selection data for selecting the bit in the sub array 211A on the upper side of the column selection and read-write circuit 213 inside the sub block 210 to write the data is designated by is W_COL_SEL_U.

Further, the column selection data for selecting the bit in the sub array 211B on the lower side of the column selection and read-write circuit 213 inside the sub block 210 to write the data is designated by is W_COL_SEL_L.

The column selection R_COL_SEL_F[3:0] and W_COL_SEL_F[3:0] used in the first pattern are input into the bit D[n] whose bit sequence number is odd as R_COL_SEL_U and W_COL_SEL_U, respectively.

The column selection R_COL_SEL_F[3:0] and W_COL_SEL_F[3:0] used in the first pattern are input into the bit D[n−1] and D[n+1] whose bit sequence numbers are even as R_COL_SEL_L and W_COL_SEL_L, respectively.

On the contrary thereto, the column selection R_COL_SEL_S[3:0] and W_COL_SEL_S[3:0] used in the second pattern are input into the bit D[n−1] and D[n+1] whose bit sequence numbers are even as R_COL_SEL_U and W_COL_SEL_U, respectively.

The column selection R_COL_SEL_S[3:0] and W_COL_SEL_S[3:0] used in the second pattern are input into the bit D[n] whose bit sequence number is odd as R_COL_SEL_L and W_COL_SEL_L, respectively.

As described, the column selection data for reading or writing the data under the first or second pattern are allocated to the bits whose bit sequence numbers are odd or even. Thus, the bits having the same address are allocated as follows.

For example, an example of the readout of the data is performed when the row selection data ROW[2] is “1”, and the column selection data R_COL_SEL_F[0] is “1”. This corresponds to a case where reading is performed under the first pattern.

In this case, in the bit D[n] whose bit sequence number is odd, the bit cell 10E positioned at the intersection point between the word line WL02 and the column C[0] is selected. In the bit D[n+1] whose bit sequence number is even, the bit cell 10F positioned at the intersection point between the word line WL12 and the column C[0] is selected.

Said differently, the bit cells in the adjacent bits and in the different sub arrays 211A and 211B have the same address. This relationship is similar to the addresses identified by the word lines WL00 to WL03 and WL10 to WL13 and the columns C[0] to C[3] for all bits.

Within the SRAM 200 of the first embodiment, the column selection data for reading or writing under the first or second pattern are allocated to the bits whose bit sequence numbers are odd or even as described above. Therefore, the bits including the bit cells having the same address are arranged in a zigzag-like formation continuously in a direction of arranging the bits.

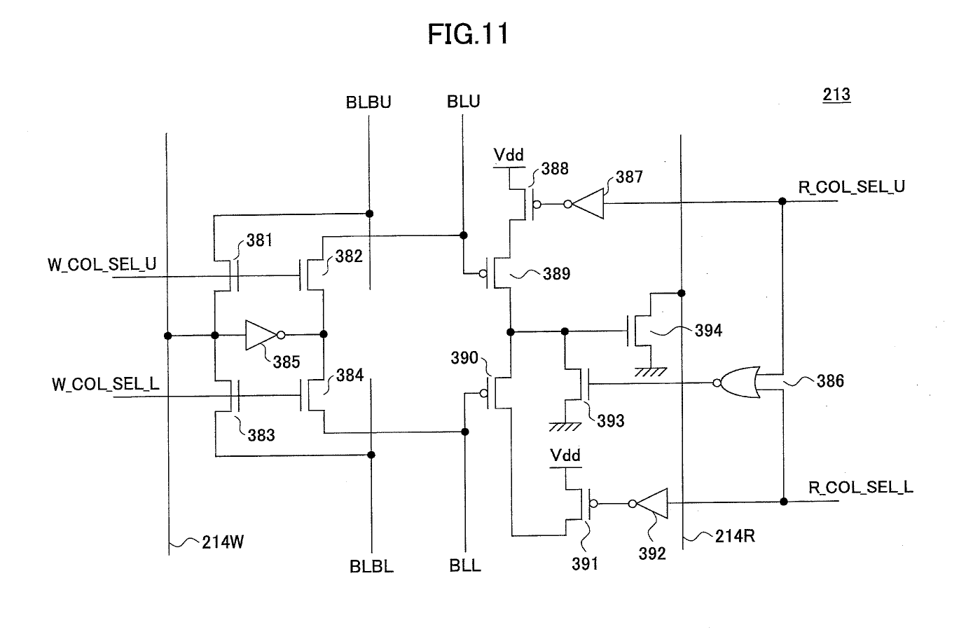

Next, referring to FIG. 11, the column selection and read-write circuit 213 is described.

FIG. 11 illustrates the column selection and read-write circuit 213 of the SRAM 100 of the first embodiment.

One column selection and read-write circuit 213 is provided in each of the sub blocks 210. The column selection and read-write circuit 213 is connected with bit lines BL and BLB of the sub arrays 211A and 211B inside each of the sub blocks 210.

Here, the bit lines connected with the sub array 211A on the upper side of the column selection and read-write circuit 213 inside the sub block 210 are referred to as BLU and BLBU (the suffix “U” stands for Upper). The bit lines connected with the sub array 211A on the lower side of the column selection and read-write circuit 213 inside the sub block 210 are referred to as BLL and BLBL (the suffix “L” stands for Lower).

The bit lines BLU and BLBU correspond to, for example, the bit lines BL00 and BLB00 to BL03 and BLB 03. The bit lines BLL and BLBL correspond to, for example, the bit lines BL10 and BLB10 to BL13 and BLB 13.

Further, as illustrated in FIG. 10, the column selection data R_COL_SEL_U, R_COL_SEL_L, W_COL_SEL_U, and W_COL_SEL_L are input into the column selection and read-write circuit 213.

Referring to FIG. 11, the column selection and read-write circuit 213 includes NMOS transistors 381, 382, 383, and 384 and an inverter 385.

The column selection data W_COL_SEL_U is input into the gates of the NMOS transistors 381 and 382. The column selection data W_COL_SEL_L is input into the gates of the NMOS transistors 383 and 384.

The drain of the NMOS transistor 381 is connected with the upper bit line BLBU, and the source of the NMOS transistor 381 is connected with the drain of the NMOS transistor 383.

The source of the NMOS transistor 383 is connected with the lower bit line BLBL, and the drain of the NMOS transistor 383 is connected with the source of the NMOS transistor 381.

Similarly, the drain of the NMOS transistor 382 is connected with the upper bit line BLU, and the source of the NMOS transistor 382 is connected with the drain of the NMOS transistor 384.

The source of the NMOS transistor 384 is connected with the lower bit line BLL, and the drain of the NMOS transistor 384 is connected with the source of the NMOS transistor 382.

A connecting point between the source of the NMOS transistor 381 and the drain of the NMOS transistor 383 is connected with a global bit line 214W for writing the data.

Further, a connecting point between the source of the NMOS transistor 381 and the drain of the NMOS transistor 383 is connected with an input terminal of the inverter 385. A connecting point between the source of the NMOS transistor 382 and the drain of the NMOS transistor 384 is connected with an output terminal of the inverter 385.

The column selection data R_COL_SEL_U and R_COL_SEL_L are input into a pair of input terminals of a negative OR (NOR) circuit 386, respectively.

The input terminal of the pair of input terminals of the NOR circuit 386, into which the column selection data R_COL_SEL_U is input, is connected with the input terminal of an inverter 387.

The output terminal of the inverter 387 is connected with the gate of a PMOS transistor 388.

The drain of the PMOS transistor 388 is connected with the power source having a predetermined voltage (Vdd). The source of the PMOS transistor 388 is connected with the drain of a PMOS transistor 389.

The gate of the PMOS transistor 389 is connected with the upper bit line BLU. The source of the PMOS transistor 389 is connected with the drain of a PMOS transistor 390.

The gate of the PMOS transistor 390 is connected with the lower bit line BLL. The source of the PMOS transistor 390 is connected with the source of a PMOS transistor 391.

The drain of the PMOS transistor 391 is connected with the power source having a predetermined voltage (Vdd). The gate of the PMOS transistor 391 is connected with the output terminal of an inverter 392.

The input terminal of the inverter 392 is connected with the other input terminal of the NOR circuit 386.

A connecting point between the source of the PMOS transistor 389 and the drain of the PMOS transistor 390 is connected with the drain of the NMOS transistor 393 and the gate of the NMOS transistor 394.

The source of the NMOS transistor 393 is grounded, and the gate is connected with the output terminal of the NOR circuit 386.

The drain of the NMOS transistor 394 is connected with the global bit line 214R for reading the data. The source of the NMOS transistor 394 is grounded.

In the above described column selection and read-write circuit 213, when the data is written in the bit on the upper side, the column selection data W_COL_SEL_U is “1”.

At this time, the NMOS transistors 381 and 382 are turned on and the global bit line 214W is connected with the upper bit lines BLU and BLBU. As a result, the data can be written in the bit on the upper side through the upper bit lines BLU and BLBU from the global bit line 214W for writing the data.

When the data is written in the bit on the lower side, the column selection data W_COL_SEL_L is “1”.

At this time, the NMOS transistors 383 and 384 are turned on, and the global bit line 214W is connected with the lower bit lines BLL and BLBL. As a result, the data can be written in the bit on the lower side through the lower bit lines BLL and BLBL from the global bit line 214W for writing the data.

Further, when the data in the bit on the upper side is read out, the column selection data is “1”.

At this time, the PMOS transistor 388 is turned on, and the output from the NOR circuit 386 is “0”. When the column selection data R_COL_SEL_U is “1”, the column selection data W_COL_SEL_U is “0”. Therefore, the NMOS transistor 382 is turned off, and the PMOS transistor is turned on.

Further, because the output from the NOR circuit 386 is “0”, the NMOS transistor 393 is turned off, and the NMOS transistor 394 is turned on.

As a result, the upper bit line BLU is connected with the global bit line 214R for reading the data. Then, the data in the bit on the upper side can be readout through the global bit line 214R for reading the data.

The operation of reading the data in the bit on the lower side is as follows depending on asymmetric property between upper and lower sides of the column selection and read-write circuit 213.

When the column selection data R_COL_SEL_L is “1” at a time of reading out the data in the bit on the lower side, the lower bit line BLL is connected with the global bit line 214R for reading the data. Therefore, the data in the bit on the lower side can be readout through the global bit line 214R for reading the data.

As described, the data can be freely read out of or written in the bits on the upper or lower side by the column selection and read-write circuit 213.

FIG. 11 illustrates a relationship among the column selection and read-write circuit 213, the global bit line 214R for reading the data, and the global bit line 214W for writing the data.

However, within the first embodiment, the column selection and read-write circuits 213 corresponding to four columns are connected for each pair of global bit lines 214R and 214W.

The column selection and read-write circuits 213 of the other three columns (not illustrated in FIG. 11) have the same circuit structure as that of the column selection and read-write circuit 213 illustrated in FIG. 11.

The column selection and read-write circuits 213 of the other three columns (not illustrated in FIG. 11) are connected with the global bit line 214W for writing the data through the NMOS transistors 381 to 384 and the inverters 385.

By turning on the NMOS transistors 381 to 384 in any one of the four column selection and read-write circuits 213, the any one of the four column selection and read-write circuits 213 is connected with the global bit line 214W for writing the data.

Similarly, the column selection and read-write circuits 213 of the other three columns (not illustrated in FIG. 11) are connected with the global bit line 214R for reading the data through the NMOS transistors 394.

By turning on the NMOS transistors 394 in any one of the four column selection and read-write circuits 213, the any one of the four column selection and read-write circuits 213 is connected with the global bit line 214R for reading the data.

As described, the NMOS transistors 381 to 384 and the NMOS transistor 394 functions as the switch circuits 215A and 215B connecting any one of the four column selection and read-write circuits 213 with the global bit line 214W for writing the data and the global bit line 214R for reading the data.

Next, referring to FIG. 12, a method of selecting bits in the zigzag-like formation under the first or second pattern is described.

FIG. 12 illustrates how to select the bits under the first or second pattern in the SRAM 200 of the first embodiment.

On the right side of FIG. 12, an enlarged view of the sub block 210 having the sub block number 3 positioned above the input-output port (I/O) 230A is illustrated.

Hereinafter, description is given below for an example that the sub array 211A and the sub array 211B include the 4 bits D[0], D[1], D[2], and D[3], and the column selection and read-write circuit 213 is provided between the sub arrays 211A and 211B.

Each of the 8 bits illustrated in FIG. 12 includes 16 bit cells having 4 rows and 4 columns. For convenience of explanation, the bit cells are illustrated as rectangles arranged like a grid in FIG. 12.

The 4 columns included in each bit D[0], D[1], D[2], or D[3] are designated by C[0], C[1], C[2], or C[3]. The bit lines BL00, BLB00 to the bit lines BL03, BLB03 are included in the columns C[0] to C[3] inside the sub array 211A, respectively.

Further, for convenience of explanation, the reference symbols WL00 to WL03 and WL10 to WL13 are illustrated without illustrating the word lines.

As described, the first pattern indicates reading or writing of the data for the plurality of bits cells having the same bit sequence number in a bit inside the sub array 211A whose bit sequence number is odd and in a bit inside the sub array 211B whose bit sequence number is even.

Therefore, under the first pattern, the bits are selected in the zigzag-like formation in the sub arrays 211A and 211b as in bits without shading. Said differently, every other bit is selected in the sub arrays 211A and 211b, and the selected bits alternately correspond between the upper and lower sides.

Further, the second pattern indicates reading or writing of the data for the plurality of bits cells having the same bit sequence number in a bit inside the sub array 211A whose bit sequence number is even and in a bit inside the sub array 211B whose bit sequence number is odd.

Therefore, under the second pattern, the bits are selected in the zigzag-like formation in the sub arrays 211A and 211b as in bits with shading. Said differently, every other bit is selected in the sub arrays 211A and 211b, and the selected bits alternately correspond between the upper and lower sides.

For example, data are read out under conditions (1) to (5).

(1) The row selection data ROW[0] output from the row decoder 221 is “1”, and the row selection data ROW[1], ROW[2], and ROW[3] output from the row decoder 221 are all “0”.

(2) The sub block selection data SBS [3] output from the sub block decoder 222 is “1”, and the sub block selection data SBS[1], SBS[2], and SBS[3] output from sub block decoder 222 are all “0”.

(3) The data SBS[3] output from the top and bottom select decoder 223 is the TOP data.

(4) The first pattern selection data F output from the pattern select decoder 224 is “1”, and the second pattern selection data S output from the pattern select decoder 224 is “0”.

(5) The column selection data R_COL_SEL_F[0] output from the column decoder 225 is “1”, and column selection data R_COL_SEL_F[1], R_COL_SEL_F[2], and R_COL_SEL_F[3] output from the column decoder 225 are all “0”. The column selection data R_COL_SEL_S[3:0], W_COL_SEL_F[3:0], and W_COL_SEL_S[3:0] are all “0”.

The conditions of the above (1) to (5) are for reading the data under the first pattern.

In this case, 2 bit cells are selected in the sub array 211A. As illustrated by arrows in FIG. 12, the 2 bit cells exist at intersection points between the column C[0] and the word line WL00 inside the bits D[1] and D[3], whose bit sequence numbers are odd.

In this case, 2 bit cells are selected in the sub array 211B. As illustrated by arrows in FIG. 12, the 2 bit cells exist at intersection points between the column C[0] and the word line WL10 inside the bits D[0] and D[2], whose bit sequence numbers are even.

These 4 bit cells identified by the first pattern have the same address. Each of the 4 bit cells is included in the 4 bits arranged in the zigzag-like formation as illustrated by blanks (the white color) in FIG. 12.

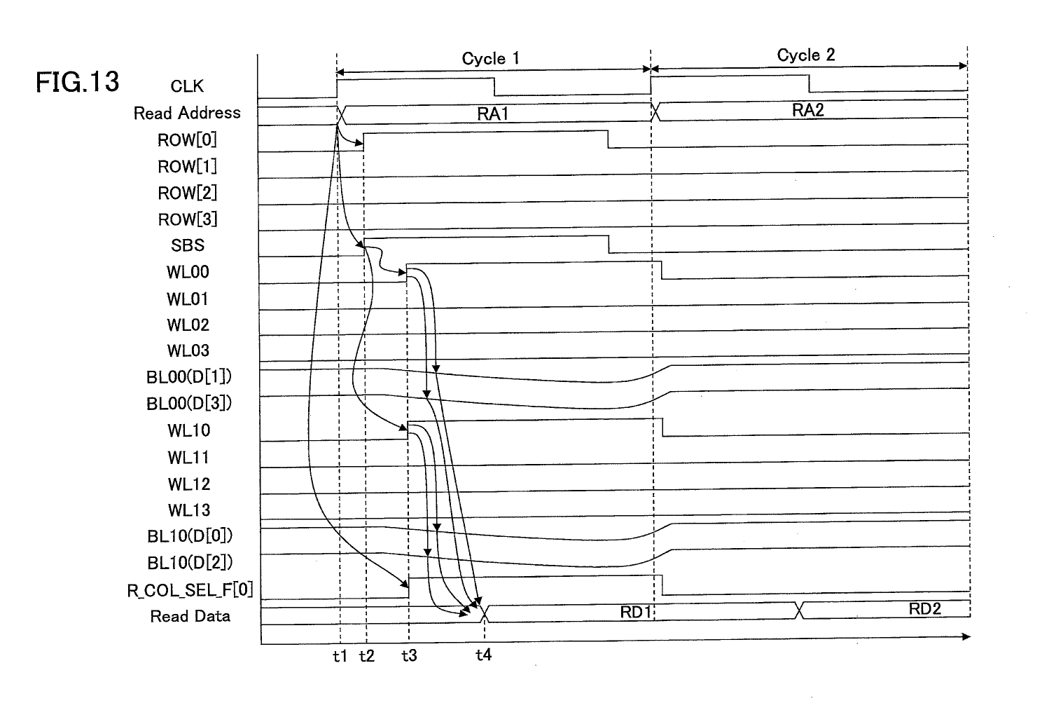

Next, a timing chart illustrated in FIG. 13 is used to explain an operation of reading out the data from the 4 bit cells illustrated in FIG. 12 under the first pattern in the SRAM 200 of the first embodiment.

FIG. 13 is the timing chart illustrating an operation example of the SRAM 200 of the first embodiment.

The 4 bit cells in the bits D[1] and D[3] illustrated in FIG. 12 are identified by the column C[0] and the word line WL00. The 4 bit cells in the bits D[0] and D[2] illustrated in FIG. 12 are identified by the column C[0] and the word line WL10. The word lines WL00 and WL10 are identified by the row selection data ROW[0].

Referring to FIG. 13, signal levels of a system clock CLK, of an input address for reading RA (Read Address), of the row selection data ROW[0] to ROW[3], of sub block selection data SBS, and of the word lines WL00 to WL03 and WL10 to WL 13 are illustrated.

Further, FIG. 13 illustrates the signal levels of the bit lines BL00 of the bits D[1] and D[3], the signal levels of the bit lines BL10 of the bits D[0] and D[2], the column selection data R_COL_SEL_F[0], and the read data RD (Read Data).

Further, the system clock CLK is output from the timer 240 (see FIG. 7).

If the input address for reading is switched to RA1, the selection data ROW[0] and the sub block selection data SBS are raised at a time t2.

When the row selection data ROW[0] and the sub block selection data SBS are raised, the word lines WL00 and WL10 are selected at a time t3.

Further, the input address RA1 for reading designates reading of data under the first pattern. Therefore, the column selection data R_COL_SEL_F[0] is raised to “1” at the time t3.

As a result, the data in the 4 bit cells, which are the 2 bit cells at the intersection points between the columns C[0] and the word line WL10 inside the bits D[1] and D[3], whose bit sequence numbers are odd, and the 2 bit cells at the intersection points between the columns C[0] inside the bits D[0] and D[2] and the word line WL10 inside the bits D[0] and D[2], whose bit sequence numbers are even, are read out after the time t3.

The data of the 2 bit cells at the intersection points between the columns C[0] and the word line WL10 inside the bits D[1] and D[3], whose bit sequence numbers are odd, are readout through the bit lines BL00 of the bits D[1] and D[3].

The data of the 2 bit cells at the intersection points between the columns C[0] and the word line WL10 inside the bits D[0] and D[2], whose bit sequence numbers are even, are read out through the bit lines BL10 of the bits D[0] and D[2].

As a result, the read data becomes RD1 at a time t4.

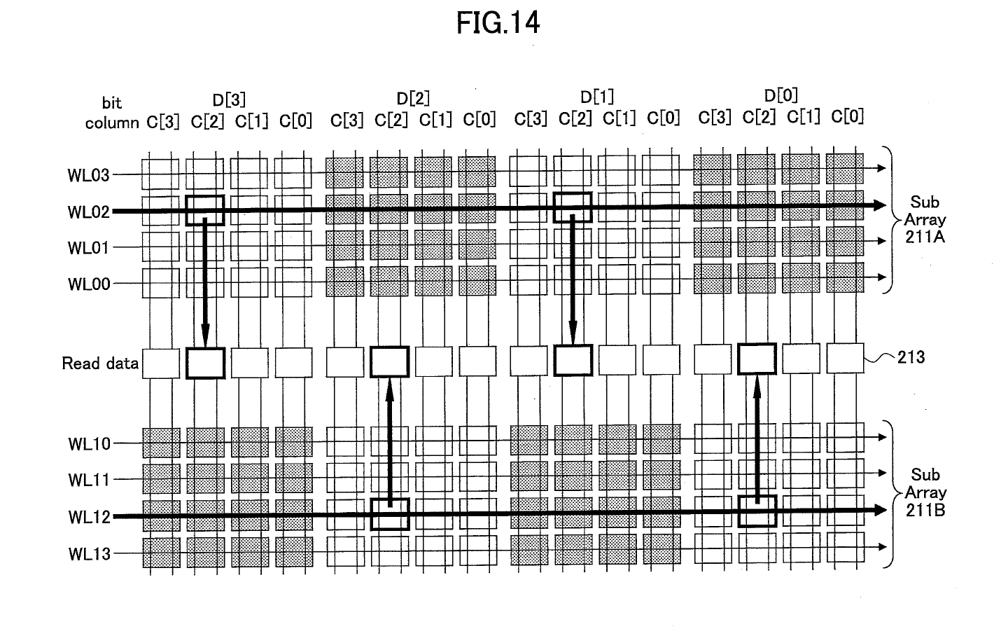

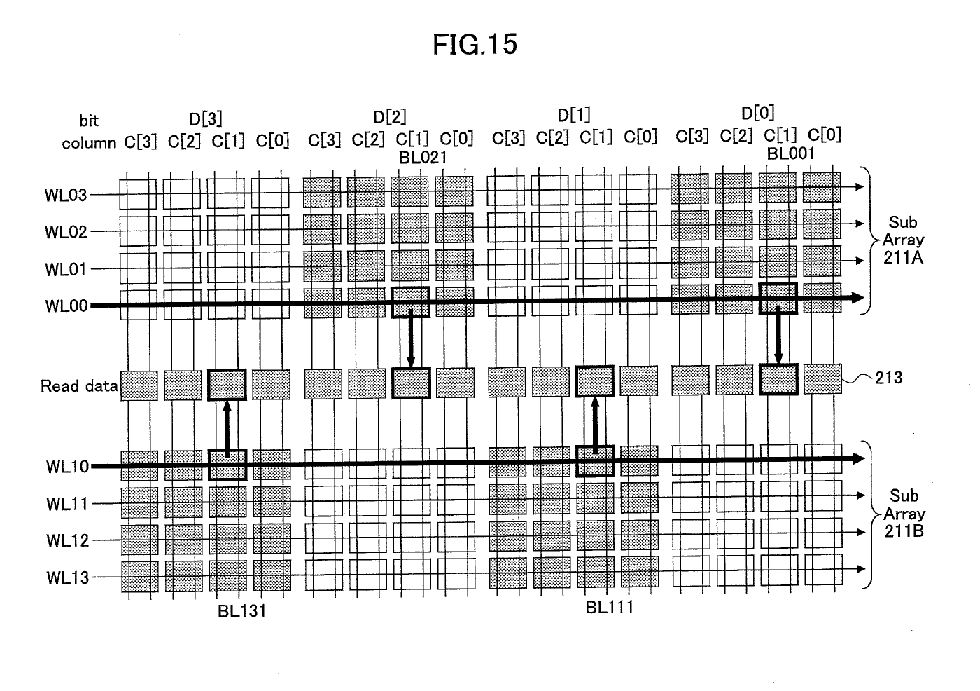

Next, referring to FIGS. 14 and 15, exemplary operations of selecting the bit cells under the first and second patterns are explained.

FIGS. 14 and 15 illustrate the exemplary operations of selecting the bit cells for reading the data under the first and second patterns in the SRAM 200 of the first embodiment.

Referring to FIGS. 14 and 15, the bits D[0], D[1], D[2], and D[3] included in the sub arrays 211A and 211B and the word lines WL00 to WL03 and WL10 to WL13 are illustrated. The columns C[0] to C[3] are illustrated in every bit.

Referring to FIGS. 14 and 15, the blank (white colored) bits, whose bit sequence numbers are odd, inside the sub array 211A and blank (white colored) bits, whose bit sequence numbers are even, inside the sub array 211B indicated by blank are selected by the first pattern at the time of reading out the data.

Similarly, the shaded (gray colored) bits, whose bit sequence numbers are even, inside the sub array 211A and the shaded (gray colored) bits, whose bit sequence numbers are odd, inside the sub array 211B are selected by the second pattern at the time of reading out the data.

Referring to FIG. 14, the row selection data ROW[2] is “1”, and the row selection data ROW[0], ROW[1], and ROW[3] are all “0”.

Further, the column selection data R_COL_SEL_F[2] is “1”, and the column selection data R_COL_SEL_F[0], R_COL_SEL_F[1], and R_COL_SEL_F[3] are all “0”.

In this case, the data are read out of the bit cells at the intersection points between the columns C[2] and the word line WL02 inside the bits D[1] and D[3], whose bit sequence numbers are odd, and the data are readout of the bit cells at the intersection points between the columns C[2] and the word line WL12 inside the bits D[0] and D[2], whose bit sequence numbers are even.

These 4 bit cells have the same address.

As described, in the SRAM 200 of the first embodiment, the adjacent bit cells having the same address are arranged (allocated) to different sub arrays 211A and 211B. Therefore, when the data are read under the first pattern, the data are read out of the sub array 211A for the bits, whose bit sequence numbers are odd, and data are read out of the sub array 211B for the bits, whose bit sequence numbers are even.

Referring to FIG. 15, the row selection data ROW[0] is “1”, and the row selection data ROW[1], ROW[2], and ROW[3] are all “0”.

Further, the column selection data R_COL_SEL_S[1] is “1”, and the column selection data R_COL_SEL_S[0], R_COL_SEL_S[2], and R_COL_SEL_S[3] are all “0”.

In this case, the data are read out of the bit cells at the intersection points between the columns C[1] and the word line WL10 inside the bits D[1] and D[3], whose bit sequence numbers are odd, and the data are readout of the bit cells at the intersection points between the columns C[1] and the word line WL00 inside the bits D[0] and D[2], whose bit sequence numbers are even.

These 4 bit cells have the same address.

As described, in the SRAM 200 of the first embodiment, the adjacent bit cells having the same address are arranged (allocated) to different sub arrays 211A and 211B. Therefore, when the data are read under the second pattern, the data are read out of the sub array 211B for the bits, whose bit sequence numbers are odd, and data are read out of the sub array 211A for the bits, whose bit sequence numbers are even.

As described, in the SRAM 200 of the first embodiment, a plurality of bit cells having the same address are arranged (allocated) in the different sub arrays. Said differently, the plurality of bit cells having the same address included in the adjacent bits adjacent in a lateral direction (a direction of arranging the bits or the columns) are alternately dispersed between the pair of sub arrays 211A and 211B inside one sub block 210.

The bit cells having the same address are alternately dispersed in the lateral direction between the different sub arrays 211A and 211B by arranging the bits, which include the bits having the same address and whose bit sequence numbers are odd, and the bits, which include the bits having the same address and whose bit sequence numbers are even, in the zigzag-like formation as described above.

Therefore, even when each bit includes 4 columns in a manner similar to the SRAM 30 (see FIG. 4) of the comparative example, durability similar to that of the SRAM 30A, in which each bit includes 8 columns (see FIG. 5), of the other comparative example can be performed even if data destruction occurs by incidence of an alpha ray or a neuron ray.

On the other hand, unlike the SRAM 30A (see FIG. 5) of the other comparative example, the number of columns may be limited to 4. Therefore, reduction of a working speed caused by a change in the aspect ratio of laterally elongating bits and a laterally extended word line can be restricted.

As described, within the first embodiment, the semiconductor memory device on which the data destruction along a plurality of bits is restricted while restricting the change in the aspect ratio and the reduction of the working speed and a method of controlling the semiconductor memory device can be provided.

Even if the data destruction of 2 bits or more in the comparative example occurs in the SRAM 200 of the first embodiment, the data destruction can be restricted by physically changing the arrangement of the bit cells as described above.

Referring to FIGS. 14 and 15, a case where the data are read is described. In a case where the data are written, the column selection data are changed from R_COL_SEL_F and R_COL_SEL_S to W_COL_SEL_F and W_COL_SEL_S. However, a way of selecting the bit cells is similar to the above.

### [b] Second Embodiment

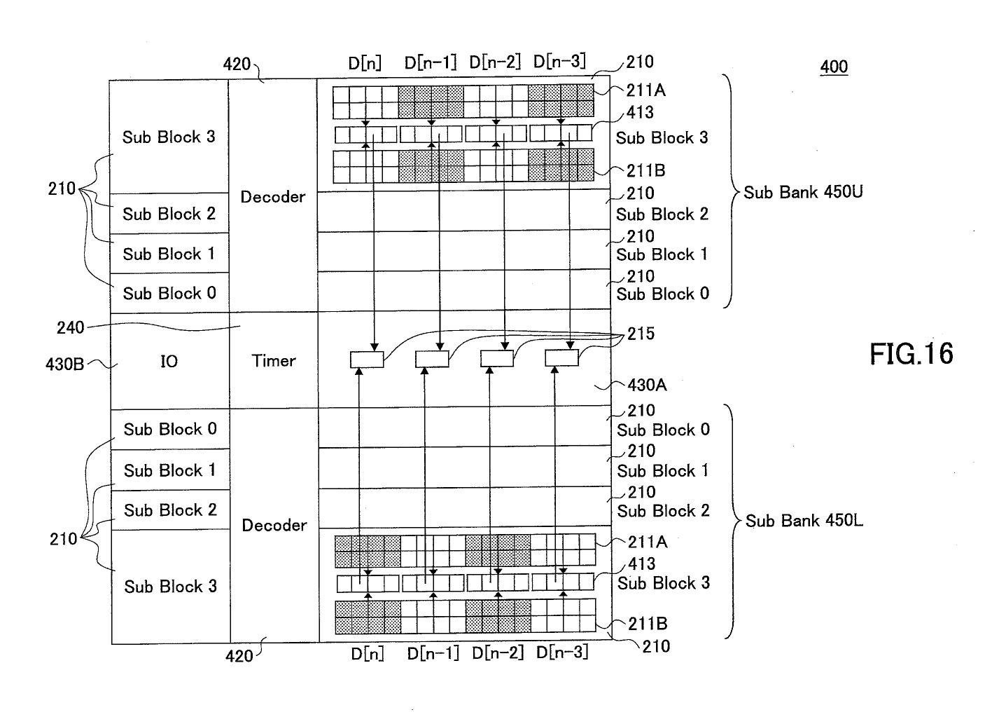

FIG. 16 illustrates an SRAM 400 of a second embodiment.

The SRAM 400 of the second embodiment differs from the SRAM 200 of the first embodiment at a point that a plurality of bit cells having the same address and included in adjacent bits adjacent in a lateral direction (a direction of arranging the bits or columns) are dispersed into (arranged in) a zigzag-like formation inside sub blocks whose sub block numbers are the same inside different sub banks 450U and 450L.

Hereinafter, the same reference symbols are attached to elements the same as those of the first embodiment, and explanation thereof is omitted.

The SRAM 400 illustrated in FIG. 16 includes the sub block 210, the decoder 420, the input-output ports 430A and 430B, and the timer 240.

Four stages of the sub blocks 210 are arranged above and below the input-output ports 430A and 430B in a manner similar to the first embodiment. Referring to FIG. 16, 16 sub blocks 210 are illustrated.

The sub block numbers 0, 1, 2, and 3 are allocated from the side close to the input-output ports 430A and 430B to the side far from the input-output ports 430A and 430B above and below the input-output ports 430A and 430B. The sub block numbers are allocated in a manner similar to the first embodiment.

Here, a group of the 8 sub blocks 210 including 4 stages above every input-output port 430A and 430B is referred to as a sub bank 450U (Upper). A group of the 8 sub blocks 210 including 4 stages below every input-output port 430A and 430B is referred to as a sub bank 450L (Lower).

Each sub block 210 includes sub arrays 211A and 211B and a column selection and read-write circuit 413 in a manner similar to the first embodiment. The sub array 211A is positioned on the upper side of the column selection and read-write circuit 413, and the sub array 211B is positioned on the lower side of the column selection and read-write circuit 413.

FIG. 16 illustrates bits D[n−3] to D[n] inside the sub arrays 211A and 211B. Each bit inside each sub array 211A or 211B includes 16 bit cells arranged in 4 rows×4 columns. For convenience of explanation, the bit cells including 2 rows×4 columns are illustrated by rectangles for the bits inside the sub arrays 211A and 211B.

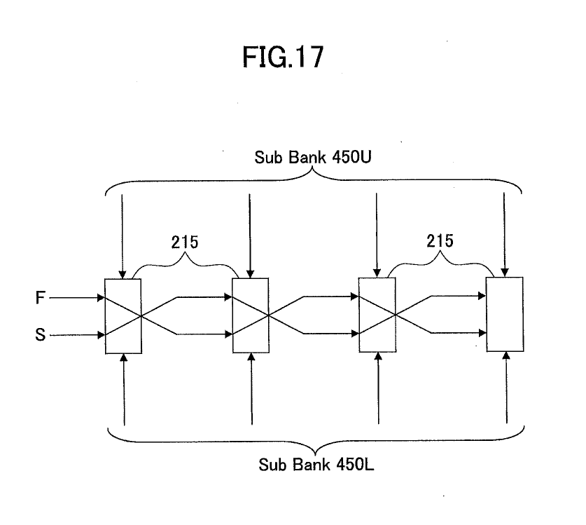

Inside the input-output port 430A illustrated in FIG. 16, a switch circuit 215 is illustrated in order to schematically illustrating reading of data. The switch circuit 215 is illustrated with reference to FIG. 17.

Positional relationships of the sub blocks 210, the sub arrays 211A and 211B, and so on are schematically illustrated as a hierarchical structure of the sub blocks 210, the sub arrays 211A and 211B, and so on. The expressions such as “above” and “below” in the description do not represent physical and positional relationships.

FIG. 17 illustrates a switch circuit 215 of the SRAM 400 of the second embodiment.

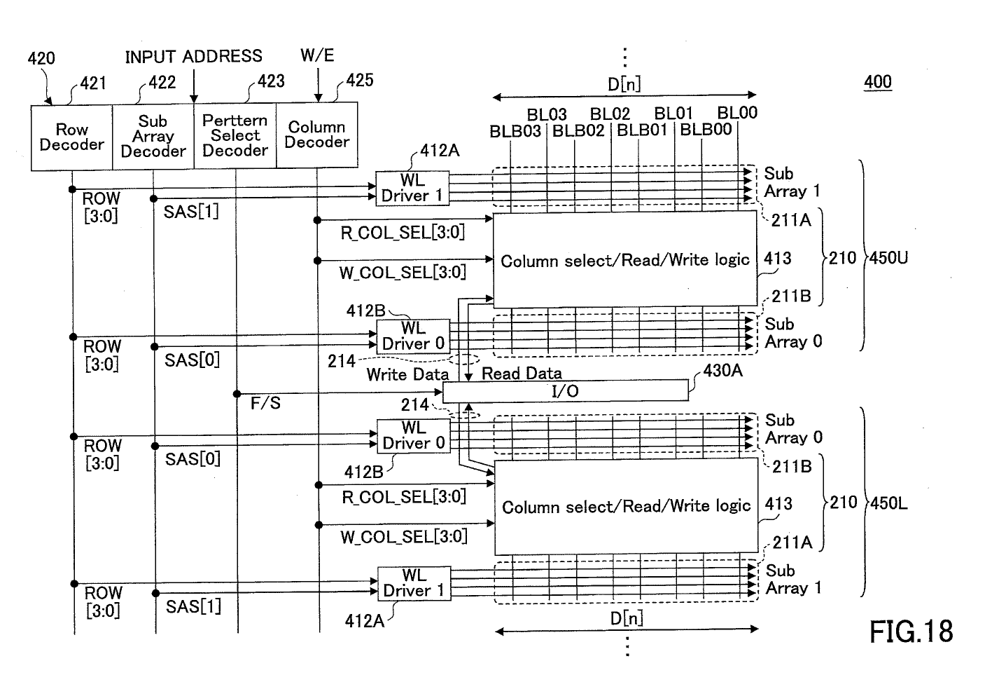

As illustrated in FIG. 17, the first pattern selection data F and the second pattern selection data S are input from a pattern select decoder 423 (see FIG. 18) to the switch circuits 215.

As illustrated in FIG. 17, the switch circuits 215 are connected so that the first and second pattern selection data F and S are input in the zigzag-like formation of the adjacent bits in the lateral direction.

The 4 switch circuits 215 illustrated in FIG. 17 read or write the data out of or in the bit cells in the adjacent bits in the lateral direction selected from the sub banks 450U or 450L in response to the first and second pattern selection data F and S.

Next, referring to FIG. 18, the circuit structure of the SRAM 400 of the second embodiment is described.

FIG. 18 illustrates a part of the SRAM 400 of the second embodiment.

Referring to FIG. 18, an input-output port (I/O) 430A, a part of the bit D[n] of the sub block 210 whose sub block number is 0 among the two sub blocks positioned above and below the input-output port (I/O) 430A, 2 column selection and read-write circuits 413, a global bit lines 214, a decoder 420, and two pairs of word line drivers 412A and 412B.

The data are read out and written in the SRAM 400 in conformity with a read instruction and a write instruction, which are input from the processor core 111.

For convenience of explanation, the bit cells 10 are not illustrated in FIG. 18. However, a plurality of bit cells 10 arranged like an array is included in every sub array 211A and 211B.

Within the second embodiment, the sub array numbers are attached to the sub arrays 211A and 211B included in each sub block 210. 8 stages of the sub arrays 211A are arranged above the input-output ports (I/O) 430A and 430B. 8 stages of the sub arrays 211B are arranged below the input-output ports (I/O) 430A and 430B.

The sub array numbers are 0 to 7 from a side close to the input-output port (I/O) 430A to a side far from the input-output port (I/O) 430A for the 8 stages of the sub arrays 211A and 211B above the input-output ports (I/O) 430A. The sub array numbers are 0 to 7 from a side close to the input-output port (I/O) 430B to a side far from the input-output port (I/O) 430B for the 8 stages of the sub arrays 211A and 211B above the input-output ports (I/O) 430B.

For convenience of explanation, only the sub arrays 211A and 211B, whose sub array numbers 0 and 1, inside the sub block 210, whose sub block number is 0, above the input-output port (I/O) 430A are illustrated in FIG. 18. For convenience of explanation, only the sub arrays 211A and 211B, whose sub array numbers 0 and 1, inside the sub block 210, whose sub block number is 0, below the input-output port (I/O) 430A are illustrated in FIG. 18.

The sub array numbers of the sub arrays inside the sub block 210 which are not illustrated in FIG. 18 are as follows.

The sub block 210 above the input-output port (I/O) 430A illustrated in FIG. 16, whose sub block number is 1, includes a sub array 211B whose sub array number is 2 and a sub array 211A whose sub array number is 3. Similarly, the sub block 210 above the input-output port (I/O) 430A, whose sub block number is 2, includes a sub array 211B, whose sub array number is 4, and a sub array 211A, whose sub array number is 5. The sub block 210 above the input-output port (I/O) 430A, whose sub block number is 3, includes a sub array 211B whose sub array number is 6 and a sub array 211A, whose sub array number is 7.

The sub block 210 below the input-output port (I/O) 430A illustrated in FIG. 16, whose sub block number is 1, includes a sub array 211A, whose sub array number is 2, and a sub array 211B, whose sub array number is 3. Similarly, the sub block 210 above the input-output port (I/O) 430A, whose sub block number is 2, includes a sub array 211A, whose sub array number is 4, and a sub array 211B, whose sub array number is 5. The sub block 210 below the input-output port (I/O) 430A, whose sub block number is 4, includes a sub array 211A, whose sub array number is 6 and a sub array 211B, whose sub array number is 7.

The positional relationships of the sub blocks 210 above and below the input-output port (I/O) 430B and the sub arrays 211A and 211B in the sub blocks 210 are similar.

The word line drivers 412A and 412B are connected with the word lines of the sub arrays 211A and 211B, respectively. For convenience of explanation, the numbers of the word lines are not illustrated in FIG. 18. The way of allocating the numbers to the word lines is similar to that in the SRAM 200 of the first embodiment.

The decoder 420 includes a row decoder 421, a sub array decoder 422, a pattern select decoder 423, and a column decoder 425. An input address is input into the decoder 420. A write enable signal W/E is input in the column decoder 425.

The numbers of the row decoder 421, the sub array decoder 422, the pattern select decoder 423, and the column decoder 425 are one for the entire SRAM 400.

The row decoder 421 and the sub array decoder 422 are connected with the word line drivers 412A and 412B through signal lines. Since the sub blocks 210 are hierarchized as illustrated in FIG. 7, the row decoder 421 and the sub array decoder 422 are connected with the word line drivers 412A and 412B of all the sub blocks 210.

Next, a row selection by the row decoder 421, a sub array selection by the sub array decoder 422, a first or second pattern selection by the pattern select decoder 423, and a column selection by the column decoder 425 are described.

The row decoder 421 is connected with the word line drivers 412A and 412B through the signal lines. The row decoder 421 decodes the row address included in the input address of the read instruction or the write instruction and outputs row selection data ROW[3:0]. The row selection data ROW[3:0] is input into the word line drivers 412A and 412B. The row decoder 421 is similar to the row decoder 221 of the first embodiment. The row selection data ROW[3:0] output by the row decoder 421 is similar to the row selection data ROW[3:0] output by the row decoder 221 of the first embodiment.

The sub block decoder 422 is connected with the word line drivers 412A and 412B through the signal lines. The sub array decoder 422 decodes a sub array address included in the input address of the read instruction or the write instruction and outputs a sub array selection data SAS.

A suffix of the sub array selection data SAS corresponds to the sub array numbers 0 to 7.

The pattern select decoder 423 is connected with the input-output port (I/O) 430A through the signal lines. First and second patterns are different from the first and second patterns of the first embodiment.

An input-output port (I/O) 430B is not illustrated in FIG. 18. The pattern select decoder 423 is connected with the input-output port (I/O) 430B is a manner similar to the input-output port (I/O) 430A.

The pattern select decoder 423 decodes the pattern selection address included in the input address of the read or write instruction, and outputs the first and second pattern selection data F and S.

In a case where the first pattern selection data F is “1” and the second pattern selection data S is “0”, the first pattern is selected. On the contrary, in a case where the first pattern selection data F is “0” and the second pattern selection data S is “1”, the second pattern is selected.

The first pattern of the second embodiment is for reading or writing the data out of or in bits inside the sub array 211A or 211b included in the sub bank 450U, whose bit sequence numbers are odd, and bits inside the sub array 211A or 211b included in the sub bank 450L, whose bit sequence numbers are even.

This means that the bits having the same address are included in the bits inside the sub array 211A or 211b included in the sub bank 450U, whose bit sequence numbers are odd, and bits having the same address are included in the bits inside the sub array 211A or 211b included in the sub bank 450L, whose bit sequence numbers are even.

The sub arrays 211A and 211B selected inside the sub banks 450U and 450L under the first pattern have the same sub array number.

The second pattern of the second embodiment is for reading or writing the data out of or in bits inside the sub array 211A or 211B included in the sub bank 450U, whose bit sequence numbers are even, and bits inside the sub array 211A or 211B included in the sub bank 450L, whose bit sequence numbers are odd.

This means that the bits having the same address are included in the bits inside the sub array 211A or 211b included in the sub bank 450U, whose bit sequence numbers are even, and bits having the same address are included in the bits inside the sub array 211A or 211b included in the sub bank 450L, whose bit sequence numbers are odd.

The sub arrays 211A and 211B selected inside the sub banks 450U and 450L under the second pattern have the same sub array number.

As described, in the SRAM 400 of the second embodiment, the bit cells having the same address and being included in the adjacent bits in the lateral direction are alternately allocated to the sub blocks 210 inside the mutually different sub banks 450U and 450L.

The column decoder 425 is connected with the column selection and read-write circuit 413 through the signal lines.

In addition to the column address included in the input address of the read instruction or the write instruction, the write enable signal W/E is input in the column address 425.

The column decoder 425 decodes the column address and outputs the column selection data corresponding to the signal level of the write enable signal W/E. The column selection data is input in the column selection and read-write circuit 413.

The column decoder 425 outputs the column selection data R_COL_SEL[3:0] in a case where the signal level of the write enable signal W/E is a L level.

The column selection data R_COL_SEL[3:0] is provided to select a column in the bits inside the sub arrays 211A and 211B in order to substantialize reading of the data.

Any pair of bit lines BL and BLB inside the sub arrays 211A and 211B is selected to read the data by the column selection data R_COL_SEL[3:0].

The column decoder 425 outputs the column selection data W_COL_SEL[3:0] in a case where the signal level of the write enable signal W/E is an H level.

The column selection data W_COL_SEL[3:0] is provided to select a column in the bits inside the sub arrays 211A and 211B in order to substantialize writing of the data.

Any pair of bit lines BL and BLB inside the sub arrays 211A and 211B is selected to write the data by the column selection data W_COL_SEL[3:0].

Next, the column selection and read-write circuit 413 is described.

The bit lines BL00 to BL03, BLB00 to BLB03, BL10 to BL13, and BLB10 to BLB13 are connected with the column selection and read-write circuit 413.

The column selection and read-write circuit 413 selects the bit lines based on the column selection data input from the column decoder 425.

The column selection and read-write circuit 413 can select the bit lines BL and BLB, switch between reading and writing, send the write data, and receive the read data based on the column selection data input from the column decoder 425.

The column selection and read-write circuit 413 selects a pair of the bit lines BL and BLB having the same line number when the column selection data is input from the column decoder 425 in order to read or write the data.

Further, the global bit line 214 is connected with the column selection and read-write circuit 413. The global bit line 214 transmits the read data or the write data between the column selection and read-write circuit 413 and the input-output port I/O 430A and 430B (see FIG. 16).

In the column selection and read-write circuit 413, a part of selecting the bit line may be any as far as the 4 pairs of bit lines included in each of the 2 sub arrays 211A and 211B, namely the bit lines BL00, BLB00 to BL03, BLB03 and BL10, BLB10 to BL13, BLB13, based on the column selection data transferred from the column decoder 425.

Further, in the column selection and read-write circuit 413, a part of reading and writing the data is of any type as far as a read process or a write process can be switched based on the column data corresponding to the signal level of the write enable signal W/E and can send and receive the data between the column selection and read-write circuit 413 and the global bit line 214.

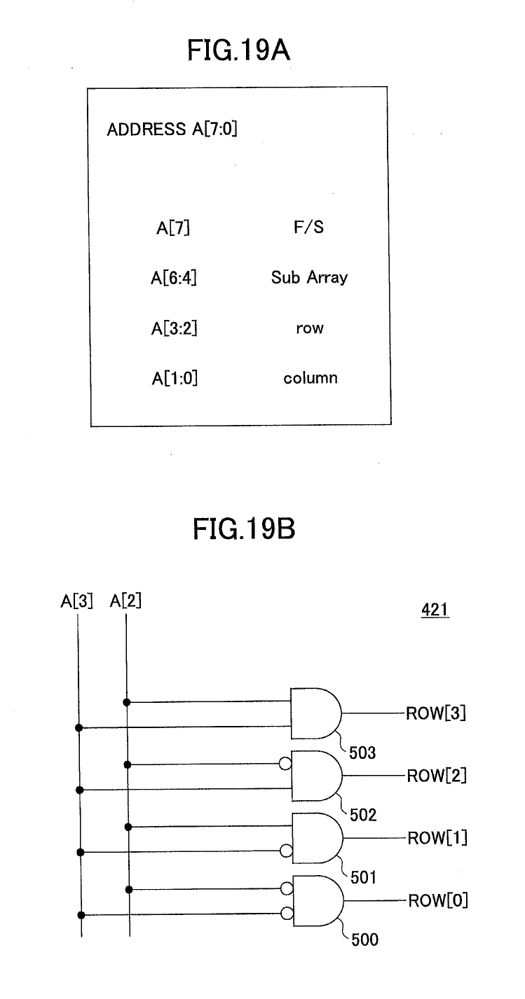

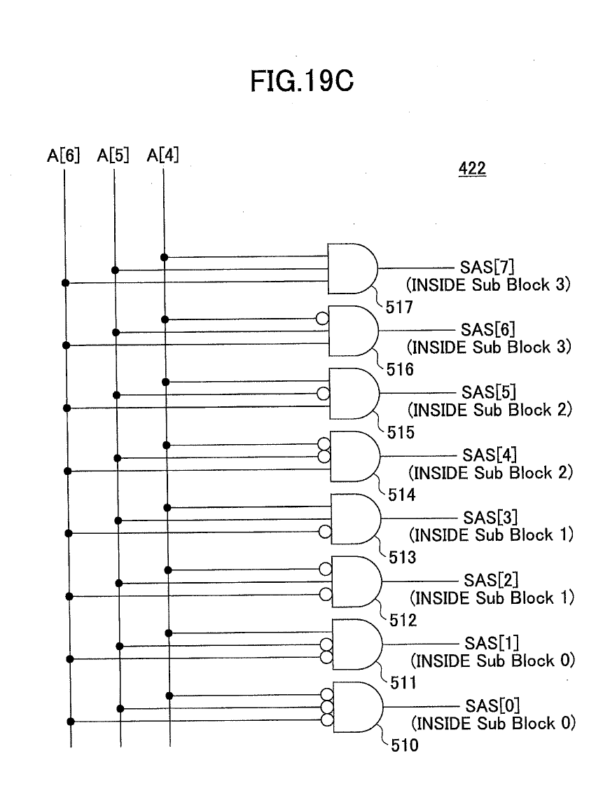

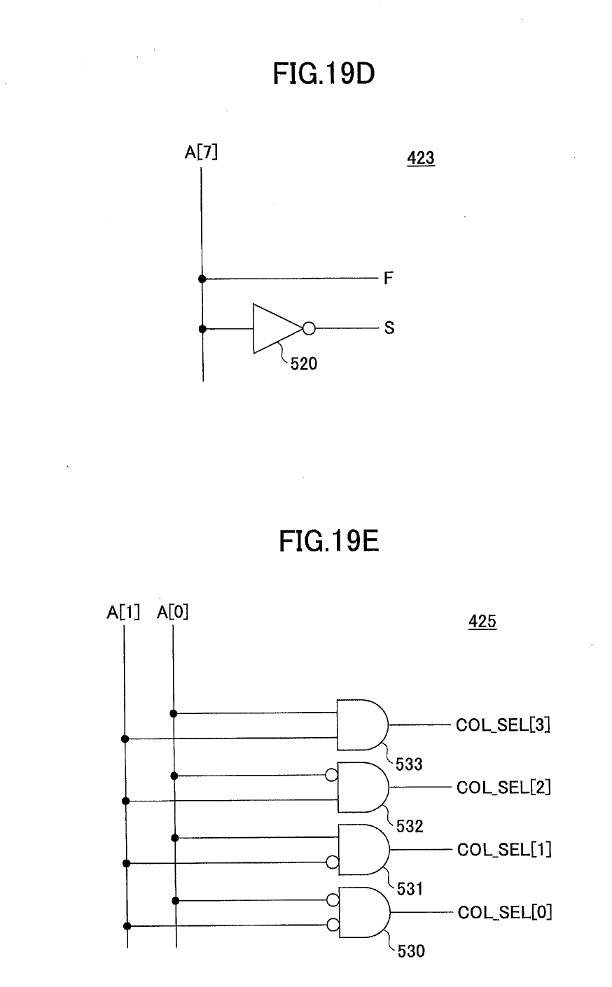

Next, referring to FIGS. 19A to 19E, the data structure of the input address and the circuit structure of the decoder 220 are explained.

FIG. 19A illustrates the data structure of the input address of the SRAM 400 of the second embodiment. The input address A[7:0] is data of 8 bits and includes a column address (column), a row address (row), a sub array address (Sub Array), and a pattern selection address (F/S) from a lower bit to an upper bit.

A[1:0] of 2 bits is allocated to the column address (column), A[3:2] of 2 bits is allocated to the row address, A[6:4] of 3 bits is allocated to the sub array address, and A[7] of 1 bit is allocated to the pattern selection address (F/S).

FIG. 19B illustrates a circuit of the row decoder 421 of the SRAM 400 of the second embodiment.

The row decoder 421 includes a logical AND circuits 500, 501, 502, and 503 of the two-input type. Two signal lines are connected with each of The logical AND circuits 500 to 503. The row addresses A[3] and A[2] are input into the two signal lines, respectively.

The logical AND circuits 500, 501, 502, and 503 output row selection data ROW[0], ROW[1], ROW[2], and ROW[3], respectively.

The row decoder 421 is similar to the decoder 221 of the first embodiment.

Next, referring to FIG. 19C, the circuit of the sub array decoder 422 is described.

FIG. 19C illustrates a circuit of a sub array decoder 422 of the SRAM 400 of the second embodiment.

The sub array decoder 422 includes logical AND circuits 510, 511, 512, 513, 514, 515, 516, and 517 of a three-input type. Three signal lines are connected with each of the logical AND circuits 510 to 517. The row addresses A[6], A[5], and A[4] are input into the three signal lines, respectively.

The logical AND circuits 510, 511, 512, 513, 514, 515, 516, and 517 respectively output sub array selection data SAS[0], SAS[1], SAS[2], SAS[3], SAS[4], SAS[5], SAS[6], and SAS[7].

The sub array selection data SAS[0] is provided for selecting the sub array 211A (Sub Array j), whose sub array number is 0. The sub array selection data SAS[0] is provided to simultaneously select the sub arrays 211A included in the sub banks 450U and 450L, whose sub array numbers are 0.

The sub array selection data SAS[1] to SAS[7] are provided to select the sub array 211A or 211B, whose sub array numbers are 1 to 7, respectively. The sub array selection data SAS[1] to SAS[7] are provided to simultaneously select the sub array 211A or 211B, one each of which is included in each of the sub banks 450U and 450L, whose sub array numbers are 0.

The sub block selection addresses A[6], A[5], and A[4] undergo a NOT operation and are input into the logical AND circuit 510.

The sub block selection addresses A[6] and A[5] undergo a NOT operation and are input into the logical AND circuit 511. The sub block selection address A[4] is input into the logical AND circuit 311 as-is.

The sub block selection addresses A[6] and A[4] undergo a NOT operation and are input into the logical AND circuit 512. The sub block selection address A[5] is input into the logical AND circuit 512 as-is.

The sub block selection address A[6] undergoes a NOT operation and is input into the logical AND circuit 513. The sub block selection addresses A[5] and A[4] are input into the logical AND circuit 513 as-is.

The sub block selection address A[6] is input into the logical AND circuit 514 as-is. The sub block selection addresses A[5] and A[4] undergo a NOT operation and are input into the logical AND circuit 514.

The sub block selection addresses A[6] and A[4] are input into the logical AND circuit 515 as-is. The sub block selection address A[5] undergoes a NOT operation and is input into the logical AND circuit 515.

The sub block selection addresses A[6] and A[5] are input into the logical AND circuit 516 as-is. The sub block selection address A[4] undergoes a NOT operation and is input into the logical AND circuit 516.

The sub block selection addresses A[6] and A[5] undergo the NOT operation and are input into the logical AND circuit 517.

In the sub array decoder 422, in a case where the sub block selection addresses A[6], A[5], and A[4] are “0”, “0”, and “0”, respectively, a sub array selection data SAS[0] is set to “1”, and sub array selection data SAS[1] to SAS[7] are set to “0”.

In the sub array decoder 422, in a case where the sub array selection addresses A[6], A[5], and A[4] are “0”, “0”, and “1”, respectively, the sub array selection data SAS[1] is set to “1”, and the sub array selection data SAS[1] and SAS[2] to SAS[7] are set to “0”.

In the sub array decoder 422, in a case where the sub array selection addresses A[6], A[5], and A[4] are “0”, “1”, and “0”, respectively, the sub array selection data SAS[2] is set to “1”, and the sub array selection data SAS[0], SAS[1] and SAS[3] to SAS[7] are set to “0”.

In the sub array decoder 422, in a case where the sub array selection addresses A[6], A[5], and A[4] are “0”, “1”, and “1”, respectively, the sub array selection data SAS[3] is set to “1”, and the sub array selection data SAS[0] to SAS[2] and SAS[4] to SAS[7] are set to “0”.

In the sub array decoder 422, in a case where the sub array selection addresses A[6], A[5], and A[4] are “1”, “0”, and “0”, respectively, the sub array selection data SAS[4] is set to “1”, and the sub array selection data SAS[0] to SAS[3] and SAS[5] to SAS[7] are set to “0”.

In the sub array decoder 422, in a case where the sub array selection addresses A[6], A[5], and A[4] are “1”, “0”, and “1”, respectively, the sub array selection data SAS[5] is set to “1”, and the sub array selection data SAS[0] to SAS[4], SAS[6], and SAS[7] are set to “0”.

In the sub array decoder 422, in a case where the sub array selection addresses A[6], A[5], and A[4] are “1”, “1”, and “0”, respectively, the sub array selection data SAS[6] is set to “1”, and the sub array selection data SAS[0] to SAS[5], and SAS[7] are set to “0”.

In the sub array decoder 422, in a case where the sub block selection addresses A[6], A[5], and A[4] are “1”, “1”, and “1”, respectively, the sub array selection data SAS[7] is set to “1”, and the sub array selection data SAS[0] to SAS[6] are set to “0”.

Next, referring to FIG. 19D, a circuit of the pattern select decoder 423 is described.

FIG. 19D illustrates the circuit of the pattern select decoder 423 of the SRAM 400 of the second embodiment.

The pattern select decoder 423 includes the circuit of a one-input and two-output type. The pattern select decoder 424 decodes the pattern selection address A[7] and outputs the first pattern selection data F and the second pattern selection data S. The first pattern selection data F is output as an inverted value of data value of the pattern selection address A[7], and the second pattern selection data S is output as the data value of the pattern selection address A[7].

The first pattern selection data F and the second pattern selection data S are data for selecting the first or second pattern and input in the input-output ports (I/O) 430A and 430B.

In a case where the first pattern selection data F is “1” and the second pattern selection data S is “0”, the first pattern is selected. On the contrary, in a case where the first pattern selection data F is “0” and the second pattern selection data S is “1”, the second pattern is selected.

FIG. 19E illustrates a circuit of the column decoder 425 of the SRAM 400 of the second embodiment.

The column decoder 425 includes logical AND circuits 530, 531, 532, and 533 of the two-input type. Two signal lines are connected with each of the AND circuits 530 to 533. The column addresses A[1] and A[0] are input into the two signal lines, respectively.

The logical AND circuits 530, 531, 532, and 533 output the column selection data R_COL_SEL[0], R_COL_SEL[1], R_COL_SEL[2], R_COL_SEL[3], W_COL_SEL[0], W_COL_SEL[1], W_COL_SEL[2], and W_COL_SEL[3], respectively.

The SRAM 400 of the second embodiment selects data readout of the bits or written in the bits through the global bit line 214 by the input-output ports (I/O) 430A and 430B under the first or second pattern based on the first pattern selection data F or the second pattern selection data S.

This is because, in the SRAM 400 of the second embodiment, the bit cells having the same address and being included in the adjacent bits in the lateral direction are alternately allocated to the sub blocks 210 inside the mutually different sub banks 450U and 450L.

The adjacent bits adjacent in the lateral direction including bit cells having the same address in the SRAM 400 of the second embodiment are dispersed into (allocated to) the sub blocks 210 in the mutually different sub banks 450U and 450L so as to be in the zigzag-like formation.

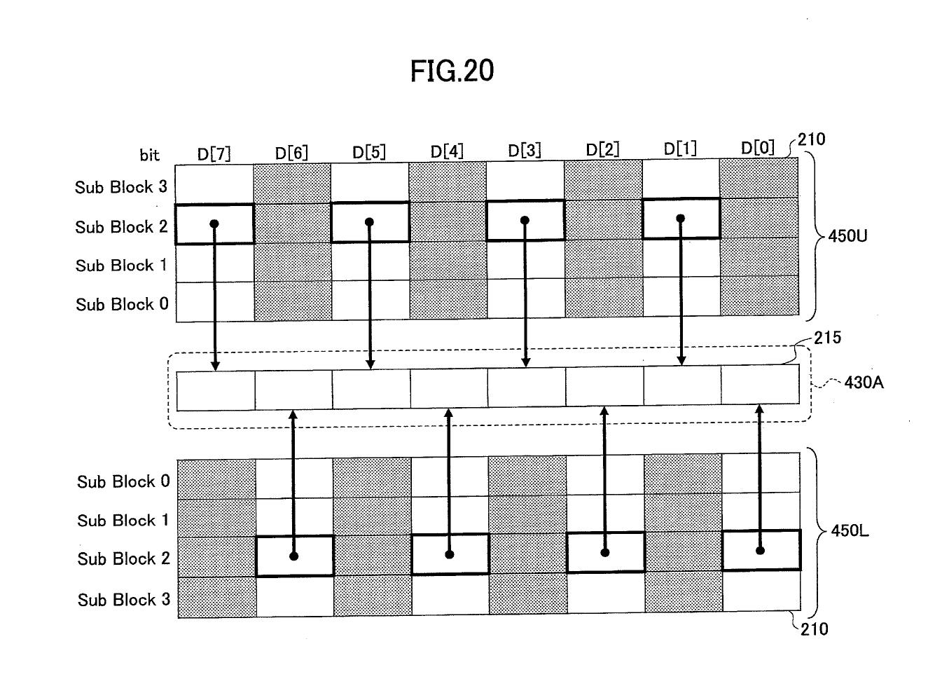

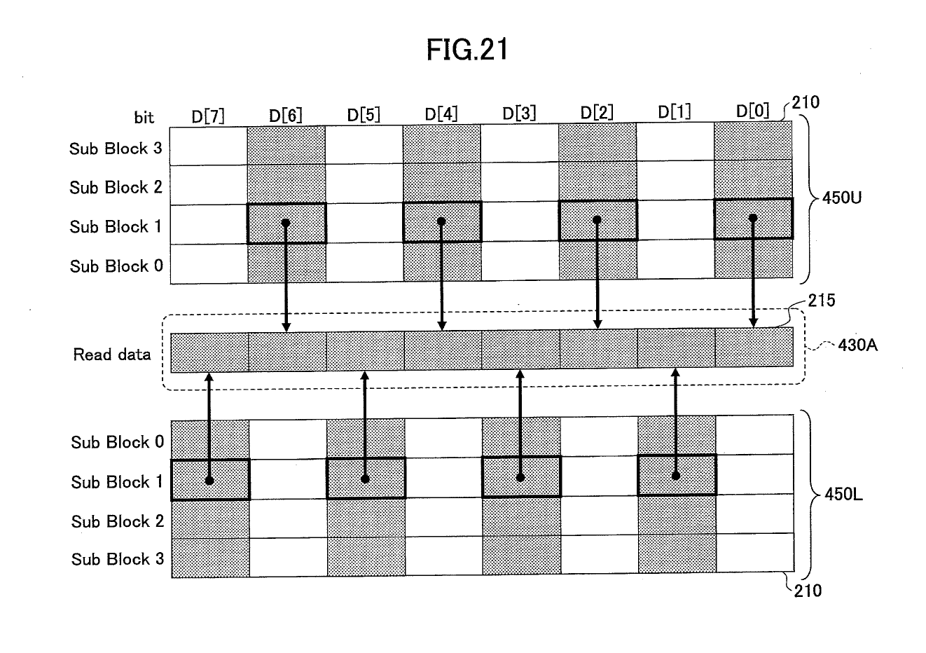

Referring to FIGS. 20 and 21, the arrangement of the bit cells having the same address in the SRAM 400 of the second embodiment is described.

FIGS. 20 and 21 illustrate sub blocks including bit cells having the same address indicated by a shade in the SRAM 400 of the second embodiment.

FIGS. 20 and 21 illustrate the sub blocks 210, whose sub block numbers 0 to 3 for the bits D[0] to D[7] included in the sub banks 450U and 450L by rectangles. Referring to FIGS. 20 and 21, only the sub block at the bit D[0] and the sub block whose sub block number is 3 are referred to as the reference symbol 210. However, each rectangle indicates one sub block (see FIGS. 16 and 18). The sub arrays and the bit cells inside the sub blocks 210 are not illustrated in FIGS. 20 and 21.

An input-output port 430A is illustrated between the sub banks 450U and 450L. The input-output port 430A includes the switch circuit 215.

Referring to FIGS. 20 and 21, the sub blocks indicated by blank (a white color) include the sub arrays 211A and 211B (see FIGS. 16 and 18) where the data is read out or written in under the first pattern.

Among the bit cells included in the sub blocks 210, the bit cells having the same column number and the same row number have the same address.

In the SRAM 400 of the second embodiment illustrated in FIGS. 20 and 21, the bit cells, where the data are read or written under the first pattern, included in the bits, whose bit sequence numbers are odd, are allocated to the sub bank 450U, and the bit cells, where the data are read or written under the first pattern, included in the bits, whose bit sequence numbers are even, are allocated to the sub bank 450L.

Referring to FIGS. 20 and 21, the sub blocks indicated by shading (a gray color) include the sub arrays 211A and 211B (see FIGS. 16 and 18) where the data is readout or written in under the second pattern.

Among the bit cells included in the sub blocks 210, the bit cells having the same column number and the same row number have the same address.

In the SRAM 400 of the second embodiment illustrated in FIGS. 20 and 21, the bit cells, where the data are read or written under the second pattern, included in the bits, whose bit sequence numbers are even, are allocated to the sub bank 450U, and the bit cells, where the data are read or written under the second pattern, included in the bits, whose bit sequence numbers are odd, are allocated to the sub bank 450L.

FIG. 20 indicates flows of the data by arrows when the sub array selection data SAS[4] or SAS[5] becomes “1”, and the data are readout of the sub block, whose sub block number is 2, under the first pattern.

FIG. 21 indicates flows of the data by arrows when the sub array selection data SAS[2] or SAS[3] becomes “1”, and the data are readout of the sub block, whose sub block number is 1, under the second pattern.

The adjacent bits adjacent in the lateral direction including bit cells having the same address in the SRAM 400 of the second embodiment are dispersed into (allocated to) the sub blocks 210 in the mutually different sub banks 450U and 450L so as to be in the zigzag-like formation.

Therefore, even when each bit includes 4 columns in a manner similar to the SRAM 30 (see FIG. 4) of the comparative example, durability similar to that of the SRAM 30A, in which each bit includes 8 columns (see FIG. 5), of the other comparative example can be performed even if data destruction occurs by incidence of an alpha ray or a neuron ray.

On the other hand, unlike the SRAM 30A (see FIG. 5) of the other comparative example, the number of columns may be limited to 4. Therefore, reduction of a working speed caused by a change in the aspect ratio of laterally elongating bits and a laterally extended word line can be restricted.

As described, within the second embodiment, the semiconductor memory device on which the data destruction along a plurality of bits is restricted while restricting the change in the aspect ratio and the reduction of the working speed and a method of controlling the semiconductor memory device can be provided.

### [c] Third Embodiment

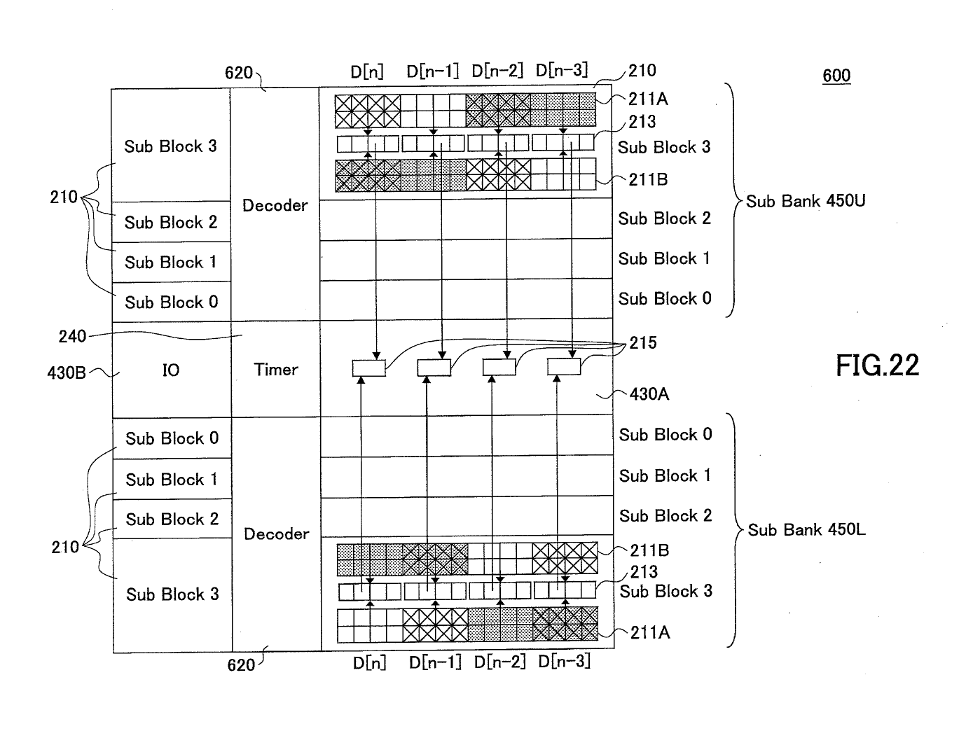

FIG. 22 illustrates an SRAM 600 of a third embodiment.

An SRAM 600 of the third embodiment includes the dispersed bits including the plurality of bit cells having the same address in the SRAM 200 of the first embodiment and the dispersed bits including the plurality of bit cells having the same address in the SRAM 400 of the second embodiment.

Hereinafter, the same reference symbols are attached to elements the same as those of the first and second embodiments, and explanation thereof is omitted.

The SRAM 600 illustrated in FIG. 22 includes a sub block 210, a decoder 620, the input-output ports 430A and 430B, and a timer 240.

FIG. 22 illustrates 4 bits D[n], D[n−1], D[n−2], and D[n−3] inside the sub blocks 210 in the SRAM 600. The bit sequence number of the bit D[n] is odd.

Each bit inside each sub array 211A or 211B includes 16 bit cells arranged in 4 rows×4 columns. For convenience of explanation, the bit cells including 2 rows×4 columns are illustrated by rectangles for the bits inside the sub arrays 211A and 211B.

Referring to FIG. 22, the bit cells in the bits D[n−3] to D[n] are indicated by using blank (a white color) or shading (a gray color) and existence or nonexistence of a mark of X. As to bit cells inside bits which are not illustrated in FIG. 22, the bit cells are grouped into every 4 bit using blank (the white color) or shading (the gray color) and existence or nonexistence of the mark of x. These 4 groups are described later.

Positional relationships of the sub blocks 210, the sub arrays 211A and 211B, and so on are schematically illustrated as a hierarchical structure of the sub blocks 210, the sub arrays 211A and 211B, and so on. The expressions such as “above” and “below” in the description do not represent physical and positional relationships.

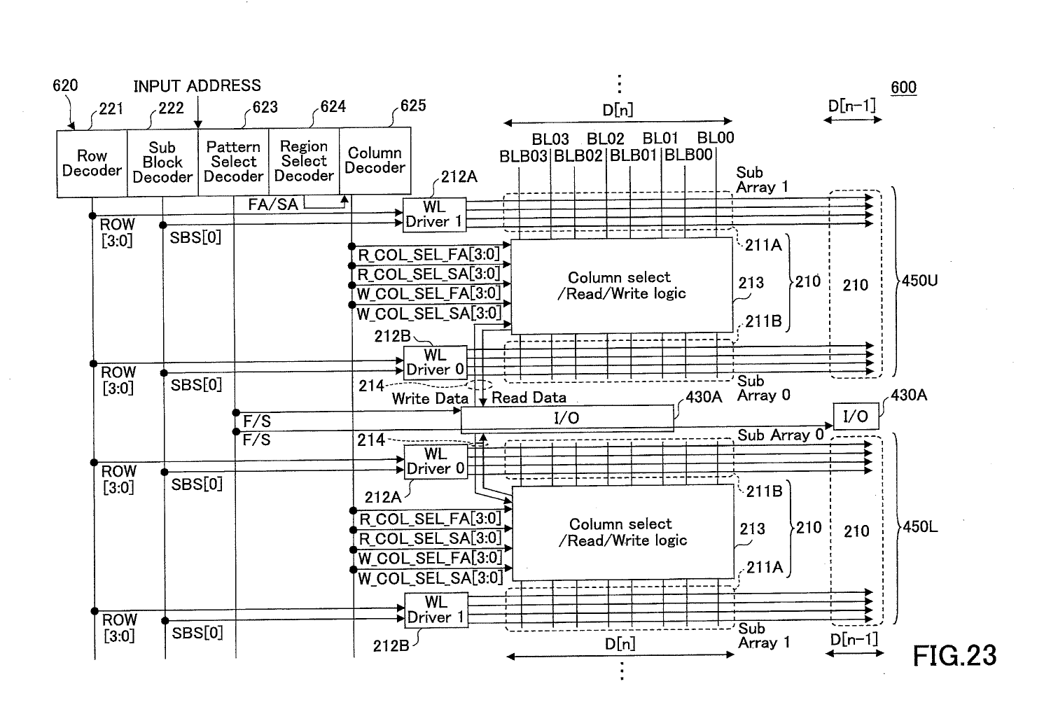

FIG. 23 illustrates a part of the SRAM 600 of the third embodiment.

Referring to FIG. 23, an input-output port (I/O) 430A, the bits D[n] and D[n−1] of the sub blocks 210 whose sub block number is 0 among the two sub blocks positioned above and below the input-output port (I/O) 430A, 2 column selection and read-write circuits 213, global bit lines 214, a decoder 620, and two pairs of word line drivers 212A and 212B.

Here, the bit sequence number of the bit D[n] is odd, and the bit sequence number of the bit D[n−1] is even.

Hereinafter, “n” of the bit D[n] is called a “bit sequence number”.

The data are read out and written into the SRAM 600 in conformity with a read instruction and a write instruction, which are input from the processor core 111 (see FIG. 6).

For convenience of explanation, the bit cells 10 are not illustrated in FIG. 23. However, a plurality of bit cells 10 arranged like an array is included in every sub array 211A and 211B.

Each sub block 210 includes the sub arrays 211A and 211B, the word line drivers 212A and 212B, and the column selection and read-write circuit 213.

The arrangement of the sub arrays 211A and 211B and the sub array numbers are similar to those in the SRAM 400 of the second embodiment.

The word line drivers 212A and 212B correspond to the sub arrays 211A and 211B, respectively. The word line drivers 212A and 212B are connected with the word lines included in the sub arrays 211A and 211B, respectively. Each of the word line drivers 212A and 212B selects the row (the word line) based on row selection data (a row selection signal) output by the decoder 620 after decoding the row address.

The column selection and read-write circuit 213 corresponds to each of the sub blocks 210. The column selection and read-write circuit 213 is connected with bit lines of the sub arrays 211A and 211B inside each of the sub blocks 210. The column selection and read-write circuit 213 selects a column (a bit line) based on column selection data (a column selection signal) output by the decoder 620 after decoding the column address.

The decoder 620 includes a row decoder 221, a sub block decoder 222, a pattern select decoder 623, a region select decoder 624, and a column decoder 625. An input address is input into the decoder 620. A write enable signal W/E is input into the column decoder 625.

Said differently, the decoder 620 includes the pattern select decoder instead of the top and bottom select decoder 223 of the decoder 220 of the first embodiment, includes the region select decoder 624 instead of the pattern select decoder 224 of the decoder 220 of the first embodiment, and a column decoder 625 instead of the column decoder 225 of the decoder 220 of the first embodiment.

The row decoder 221 and the sub block decoder 222 are similar to the row decoder 221 and the sub block decoder 222 of the first embodiment.

The pattern select decoder 623 is provided to select the first or second pattern, and is similar to the pattern select decoder 224 of the first embodiment. Signal lines for outputting first pattern selection data F (First) and second pattern selection data S (Second) are connected with the input-output ports (I/O) 430A and 430B.

The pattern select decoder 623 decodes the pattern selection address included in the input address of the read or write instruction, and outputs the first and second pattern selection data F and S.

The first pattern selection data F and the second pattern selection data S are data for selecting the first pattern or the second pattern.

The first pattern selection data F is input into the input-output port (I/O) 430A for the bit D[n], whose bit sequence number is odd. The first pattern selection data F is input into the input-output port (I/O) 430B for the bit D[n−1], whose bit sequence number is even.

In a case where the first pattern selection data F is “1” and the second pattern selection data S is “0”, the first pattern is selected. On the contrary, in a case where the first pattern selection data F is “0” and the second pattern selection data S is “1”, the second pattern is selected.

Under the first pattern, the data are read out of or written in the bits, whose bit sequence numbers are odd, in the sub bank 450U, and the data are read out of or written in the bits, whose bit sequence numbers are even, in the sub bank 450L.

Under the second pattern, the data are read out of or written in the bits, whose bit sequence numbers are even, in the sub bank 450U, and the data are read out of or written in the bits, whose bit sequence numbers are odd, in the sub bank 450L.

The region select decoder 624 selects the bits from the upper sub array 211A and the lower sub array 211B, which are included in one sub block 210.

The region select decoder 624 selects the bits, whose bit sequence numbers are odd, in the sub array 211A and the bits, whose bit sequence numbers are even, adjacent to the bits, whose bit sequence numbers are odd, as a first region. In the bits included in the first region, the even bit sequence numbers are smaller than the odd bit sequence numbers.

The region select decoder 624 selects the bits, whose bit sequence numbers are odd, in the sub array 211B and the bits, whose bit sequence numbers are even, adjacent to the bits, whose bit sequence numbers are odd, as a second region. In the bits included in the second region, the even bit sequence numbers are smaller than the odd bit sequence numbers.

The bit sequence numbers included in the first region are different from the bit sequence numbers included in the second region.

The bit sequence numbers included in the first region jumps every 2 numbers so as to be arranged like 0, 1, 4, 5, 8, 9, 12, 13, . . . .

The bit sequence numbers included in the second region jumps every 2 numbers so as to be arranged like 2, 3, 6, 7, 10, 11, 14, 15, . . . .

Referring to FIG. 22, the first region includes the bits indicated by blank (the white color), and the second region includes the bits indicated by shading (the gray color).

Said differently, the region select decoder 624 selects every two bit in the sub arrays 211A and 211B inside the sub block 210 in the zigzag-like formation. Consequently, the first region indicated by blank (the white color) and the second region indicated by shading (the gray color) are formed as illustrated in FIG. 22, for example.

The region select decoder 624 deodes a region selection address included in the input address and outputs first region selection data FA (First Area) or second region selection data SA (Second Area) in order to select the first or second regions.

The column decoder 625 is connected with the column selection and read-write circuit 213 through the signal lines. The column decoder 625 is connected with the column selection and read-write circuit 213 inside all the sub blocks 210 illustrated in FIG. 23.

The first region selection data FA, the second region selection data SA, and the write enable signal W/E are input in addition to the column address included in the input address of the read instruction or the write instruction into the column decoder 625.

The column decoder 625 decodes the column address and outputs the column selection data in response to the data value of the first region selection data FA, the data value of the second region selection data SA, and the signal level of the write enable signal W/E.

The column selection data output from the column decoder 625 is provided for selecting the column inside the bits in the sub arrays 211A and 211B to substantialize reading or writing of the data in the first or second regions.

The column selection data is input in the column selection and read-write circuit 213.

In a case where the signal level of the write enable signal W/E is the L level and the first region selection data FA is “1”, and the second region selection data SA is “0”, the column decoder 625 outputs the column selection data R_COL_SEL_FA[3:0].

The column selection data R_COL_SEL_FA[3:0] is provided to select a column in the bits inside the sub arrays 211A and 211B in order to substantialize reading of the data in the first region.

Any pair of bit lines BL and BLB in the first region in the sub arrays 211A and 211B is selected to read the data by the column selection data R_COL_SEL_FA[3:0].

In a case where the signal level of the write enable signal W/E is the L level and the first region selection data FA is “0”, and the second region selection data SA is “1”, the column decoder 625 outputs the column selection data R_COL_SEL_SA[3:0].

The column selection data R_COL_SEL_SA[3:0] is provided to select a column in the bits inside the sub arrays 211A and 211B in order to substantialize reading of the data in the second region.

Any pair of bit lines BL and BLB in the second region in the sub arrays 211A and 211B is selected to read the data by the column selection data R_COL_SEL_SA[3:0].

In a case where the signal level of the write enable signal W/E is the H level and the first region selection data FA is “1”, and the second region selection data SA is “0”, the column decoder 625 outputs the column selection data W_COL_SEL_FA[3:0].

The column selection data W_COL_SEL_FA[3:0] is provided to select a column in the bits inside the sub arrays 211A and 211B in order to substantialize writing of the data into the first region.

Any pair of bit lines BL and BLB in the first region in the sub arrays 211A and 211B is selected to read the data by the column selection data W_COL_SEL_FA[3:0].

In a case where the signal level of the write enable signal W/E is the H level and the first region selection data FA is “1”, and the second region selection data SA is “1”, the column decoder 625 outputs the column selection data W_COL_SEL_SA[3:0].

The column selection data W_COL_SEL_SA[3:0] is provided to select a column in the bits inside the sub arrays 211A and 211B in order to substantialize writing of the data into the second region.

Any pair of bit lines BL and BLB in the second region in the sub arrays 211A and 211B is selected to read the data by the column selection data W_COL_SEL_SA[3:0].

Each of the column selection data R_COL_SEL_FA[3:0], R_COL_SEL_SA[3:0], W_COL_SEL_FA[3:0], and W_COL_SEL_SA[3:0] indicate all column selection data of 4 bits.

For example, the column selection data R_COL_SEL_FA[3:0] includes column selection data R_COL_SEL_FA[3], R_COL_SEL_FA[2], R_COL_SEL_FA[1], and R_COL_SEL_FA[0]. This is the same as the column selection data R_COL_SEL_SA[3:0], W_COL_SEL_FA[3:0], and W_COL_SEL_SA[3:0].

As described, in the SRAM 600 of the third embodiment, the pattern select decoder 623 selects the first or second pattern, and the region select decoder 624 selects the first or second region.

Therefore, when the memory cells having the same address are identified, any one of the first or second pattern is selected for the adjacent bits. Thus, the bits inside the sub bank 450U above the input-output port (I/O) 430A or the bits inside the sub bank 450L below the input-output port (I/O) 430A are identified in the zigzag-like formation. This state is indicated by the existence or nonexistence of the mark of x in FIG. 22.

Further, by selecting any one of the first and second regions in addition to this, the 2 bits including the bit cells are selected from each of the sub arrays 211A and 211B inside the sub block in the zigzag-like formation. This state is indicated by blank (the white color) or shading (the gray color) in FIG. 22.

With this, in the SRAM 600 of the third embodiment, the bit cells having the same address are classified into any one of 4 groups of the bits, i.e., blank bits with the mark x, blank bits without mark, shaded bits with the mark x, and shaded bits without mark.

Among the bit cells included in the 4 groups, the bit cells having the same column number and the same row number have the same address.

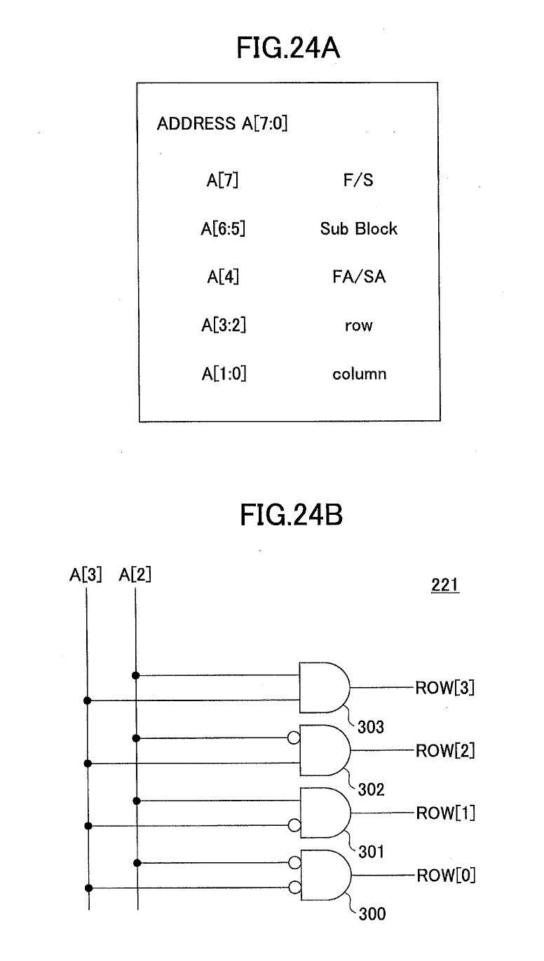

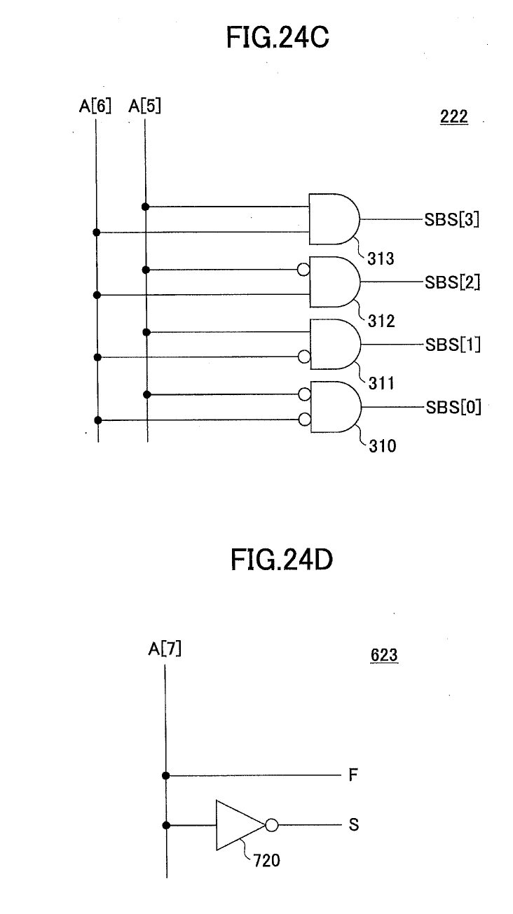

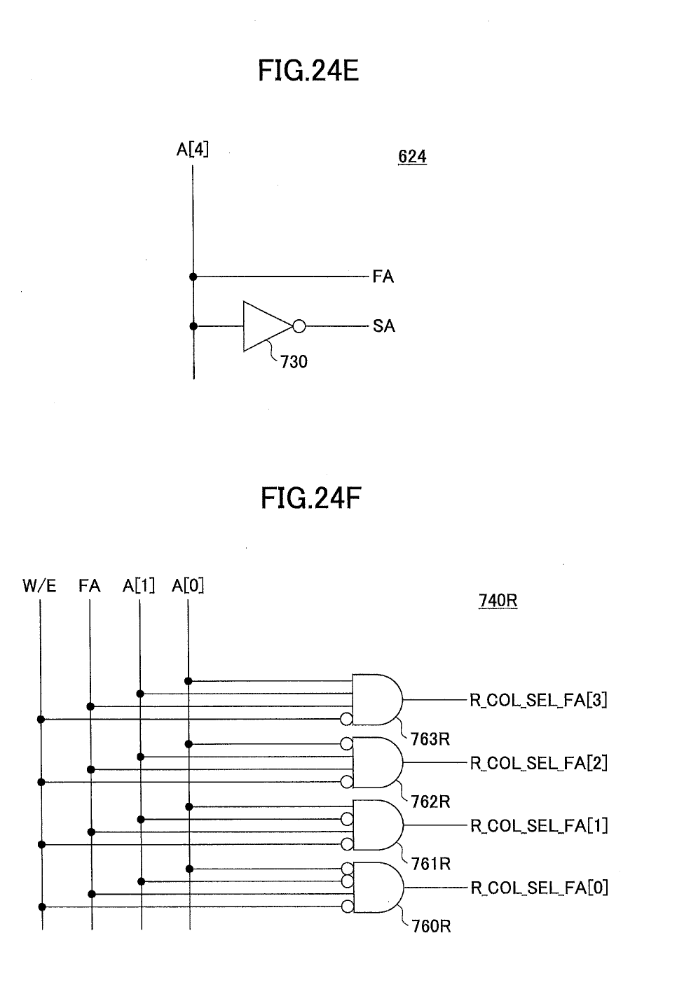

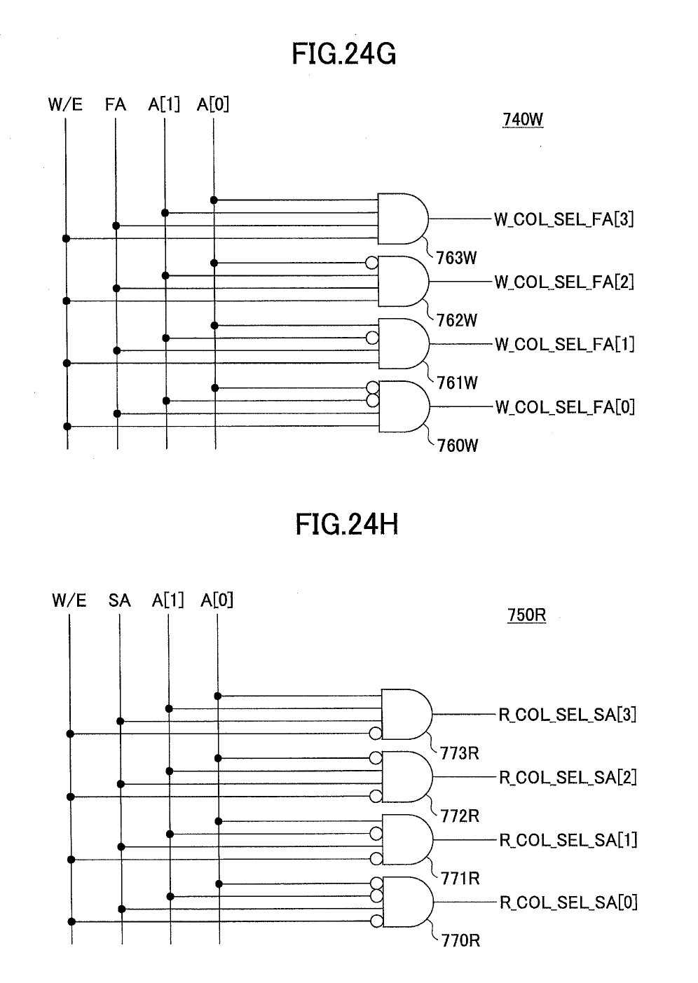

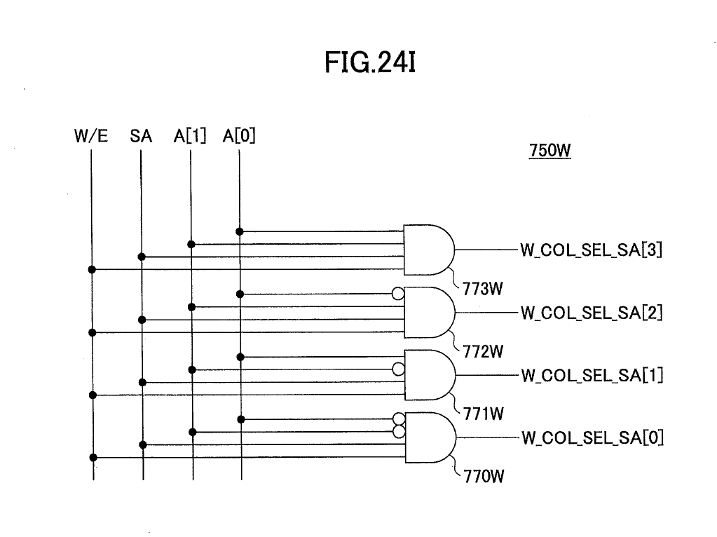

Next, referring to FIG. 24, the data structure of the input address and the circuit structure of the decoder 620 are explained.

FIG. 24A illustrates the data structure of the input address of the SRAM 600 of the third embodiment. The input address A[7:0] is data of 8 bits and includes a column address (column), a row address (row), a region selection address (FA/SA), a sub block address (Sub Block), and a pattern selection address (F/S) from a lower bit to an upper bit.

A[1:0] of 2 bits is allocated to the column address (column). A[3:2] of 2 bits is allocated to the row address (row). A[4] of 1 bit is allocated to the region selection address (FA/SA). A[6:5] of 2 bits is allocated to the sub block address (Sub Block). A[7] of 1 bit is allocated to the pattern selection address (F/S).

FIG. 24B illustrates a circuit of the row decoder 221 of the SRAM 600 of the third embodiment.

The row decoder 221 includes a logical AND circuits 300, 301, 302, and 303 of a two-input type. Two signal lines are connected with each of the AND circuits 300 to 303. The row addresses A[3] and A[2] are input into the two signal lines, respectively.

The logical AND circuits 300, 301, 302, and 303 output row selection data ROW[0], ROW[1], ROW[2], and ROW[3], respectively.

The row decoder 221 is similar to the row decoder 221 of the first embodiment.

Next, referring to FIG. 24C, the circuit of the sub block decoder 222 is described.

FIG. 24C illustrates the circuit of the sub block decoder 222 of the SRAM 600 of the third embodiment.

The sub block decoder 222 is similar to the sub block decoder 222 of the first embodiment and outputs sub block selection data SBS[0], SBS[1], SBS[2], and SBS[3].

Next, referring to FIG. 24D, a circuit of the pattern select decoder 623 is described.

FIG. 24D illustrates the circuit of the pattern select decoder 623 of the SRAM 600 of the third embodiment.

The pattern select decoder 623 includes a circuit of a one-input and two-output type. The pattern select decoder 623 decodes the pattern selection address A[7] and outputs the first pattern selection data F and the second pattern selection data S. The second pattern selection data S is output as an inverted value of data value of the pattern selection address A[7] by an inverter 720, and the first pattern selection data F is output as the data value of the pattern selection address A[7].

In a case where the first pattern selection data F is “1” and the second pattern selection data S is “0”, the first pattern is selected. On the contrary, in a case where the first pattern selection data F is “0” and the second pattern selection data S is “1”, the second pattern is selected.

Referring to FIG. 24E, a circuit of the region select decoder 624 is described.

FIG. 24E illustrates a circuit of the region select decoder 624 of the SRAM 600 of the third embodiment.

The region select decoder 624 includes a circuit of one-input and two-output type, decodes the region selection address A[4], and outputs a first region selection address FA and a second region selection address SA. The second region selection data SA is output as an inverted value of data value of the region selection address A[4] by an inverter 730, and the first region selection data FA is output as the data value of the region selection address A[4].

The first region selection data FA and the second region selection data SA are used for selecting the first or second region and input in the column decoder 225.

In a case where the first region selection data FA is “1” and the second region selection data SA is “0”, the first region is selected. On the contrary, in a case where the first region selection data FA is “0” and the second region selection data SA is “1”, the second region is selected.

Referring to FIG. 24F to FIG. 24I, a circuit of the column decoder 625 is described.

The column decoder 625 decodes the column address and outputs the column selection data in response to the data value of the first region selection data FA, the data value of the second region selection data SA, and the signal level of the write enable signal W/E.

FIGS. 24F to 241 illustrate a circuit for decoding the column address included in the column decoder 625 of the SRAM 600 of the third embodiment.

The column decoder 625 includes a circuit 740R for decoding the column address to read the data in the first region and a circuit 740W for decoding the column address to write the data in the first region.

The column decoder 625 includes a circuit 750R for decoding the column address to read the data in the second region and a circuit 750W for decoding the column address to write the data in the second region.

As illustrated in FIG. 24F, the circuit 740R for decoding the column address to read the data in the first region includes logical AND circuits of the four-input type 760R, 761R, 762R, and 763R. 4 signal lines are connected with each of the logical AND circuits 760R to 763R. The first region selection data FA, the column address A[1], the column address A[0], and the write enable signal W/E are input into the logical AND circuits 760R to 763R.

The logical AND circuits 760R, 761R, 762R, and 763R output the column selection data R_COL_SEL_FA[0], R_COL_SEL_FA[1], R_COL_SEL_FA[2], and R_COL_SEL_FA[3], respectively.

The column selection data R_COL_SEL_FA[0] is provided to select the bit lines BL00 and BLB00 and the bit lines BL10 and BLB10 illustrated in FIG. 23 in order to read the data in the first region.

The column selection data R_COL_SEL_FA[1] is provided to select the bit lines BL01 and BLB01 and the bit lines BL11 and BLB11 illustrated in FIG. 23 in order to read the data in the first region.

The column selection data R_COL_SEL_FA[2] is provided to select the bit lines BL02 and BLB02 and the bit lines BL12 and BLB12 illustrated in FIG. 23 in order to read the data in the first region.

The column selection data R_COL_SEL_FA[3] is provided to select the bit lines BL03 and BLB03 and the bit lines BL13 and BLB13 illustrated in FIG. 23 in order to read the data in the first region.

Into the logical AND circuit 760R, the first region selection data FA, a value of the column address A[1] operated using the NOT operation, a value of the column address A[0] operated using the NOT operation, and a value of the write enable signal W/E operated using the NOT operation are input.

Into the logical AND circuit 761R, the first region selection data FA, the value of the column address A[1] operated using the NOT operation, the column address A[0], and the value of the write enable signal W/E operated using the NOT operation are input.

Into the logical AND circuit 762R, the first region selection data FA, the value of the column address A[1], the column address A[0] operated using the NOT operation, and the value of the write enable signal W/E operated using the NOT operation are input.

Into the logical AND circuit 763R, the first region selection data FA, the value of the column address A[1], the column address A[0], and the value of the write enable signal W/E operated using the NOT operation are input.

In a case where the first region selection data FA is “1”, the column addresses A[1] and A[0] are “0” and “0”, and the write enable signal W/E is in the L level, the column decoder 625 sets the column selection data R_COL_SEL_FA[0] to “1”, and the column selection data R_COL_SEL_FA[1], R_COL_SEL_FA[2], and R_COL_SEL_FA[3] to “0”.

In a case where the first region selection data FA is “1”, the column addresses A[1] and A[0] are “0” and “1”, and the write enable signal W/E is in the L level, the column decoder 625 sets the column selection data R_COL_SEL_FA[1] to “1”, and the column selection data R_COL_SEL_FA[0], R_COL_SEL_FA[2], and R_COL_SEL_FA[3] to “0”.

In a case where the first region selection data FA is “1”, the column addresses A[1] and A[0] are “1” and “0”, and the write enable signal W/E is in the L level, the column decoder 625 sets the column selection data R_COL_SEL_FA[2] to “1”, and the column selection data R_COL_SEL_FA[0], R_COL_SEL_FA[1], and R_COL_SEL_FA[3] to “0”.

In a case where the first region selection data FA is “1”, the column addresses A[1] and A[0] are “1” and “1”, and the write enable signal W/E is in the L level, the column decoder 625 sets the column selection data R_COL_SEL_FA[3] to “1”, and the column selection data R_COL_SEL_FA[0], R_COL_SEL_FA[1], and R_COL_SEL_FA[2] to “0”.

In a case where the first region selection data FA is “0”, the data is not read from the first region. Therefore, all the column selection data R_COL_SEL_FA[0], R_COL_SEL_FA[1], R_COL_SEL_FA[2], and R_COL_SEL_FA[3] are set to “0”.

As illustrated in FIG. 24G, the circuit 740W for decoding the column address to write the data in the first region includes logical AND circuits of the four-input type 760W, 761W, 762W, and 763W. 4 signal lines are connected with each of the logical AND circuits 760W to 763W. The first region selection data FA, the column address A[1], the column address A[0], and the write enable signal W/E are input in the logical AND circuits 760W to 763W.

The logical AND circuits 760W, 761W, 762W, and 763W output the column selection data W_COL_SEL_FA[0], W_COL_SEL_FA[1], W_COL_SEL_FA[2], and W_COL_SEL_FA[3], respectively.

The column selection data W_COL_SEL_FA[0] is provided to select the bit lines BL00 and BLB00 and the bit lines BL10 and BLB10 illustrated in FIG. 23 in order to write the data in the first region.

The column selection data W_COL_SEL_FA[1] is provided to select the bit lines BL01 and BLB01 and the bit lines BL11 and BLB11 illustrated in FIG. 23 in order to write the data in the first region.

The column selection data W_COL_SEL_FA[2] is provided to select the bit lines BL02 and BLB02 and the bit lines BL12 and BLB12 illustrated in FIG. 23 in order to write the data in the first region.

The column selection data W_COL_SEL_FA[3] is provided to select the bit lines BL03 and BLB03 and the bit lines BL13 and BLB13 illustrated in FIG. 23 in order to write the data in the first region.

Into the logical AND circuit 760W, the first region selection data FA, the value of the column address A[1] operated using the NOT operation, the column address A[0] operated using the NOT operation, and the value of the write enable signal W/E are input.

Into the logical AND circuit 761W, the first region selection data FA, the value of the column address A[1] operated using the NOT operation, the column address A[0], and the value of the write enable signal W/E are input.

Into the logical AND circuit 762W, the first region selection data FA, the value of the column address A[1], the column address A[0] operated using the NOT operation, and the value of the write enable signal W/E are input.

Into the logical AND circuit 763W, the first region selection data FA, the value of the column address A[1], the column address A[0], and the value of the write enable signal W/E are input.

In a case where the first region selection data FA is “1”, the column addresses A[1] and A[0] are “0” and “0”, and the write enable signal W/E is in the H level, the column decoder 625 sets the column selection data W_COL_SEL_FA[0] to “1”, and the column selection data W_COL_SEL_FA[1], W_COL_SEL_FA[2], and W_COL_SEL_FA[3] to “0”.

In a case where the first region selection data FA is “1”, the column addresses A[1] and A[0] are “0” and “1”, and the write enable signal W/E is in the H level, the column decoder 625 sets the column selection data W_COL_SEL_FA[1] to “1”, and the column selection data W_COL_SEL_FA[0], W_COL_SEL_FA[2], and W_COL_SEL_FA[3] to “0”.

In a case where the first region selection data FA is “1”, the column addresses A[1] and A[0] are “1” and “0”, and the write enable signal W/E is in the H level, the column decoder 625 sets the column selection data W_COL_SEL_FA[2] to “1”, and the column selection data W_COL_SEL_FA[0], W_COL_SEL_FA[1], and W_COL_SEL_FA[3] to “0”.

In a case where the first region selection data FA is “1”, the column addresses A[1] and A[0] are “1” and “1”, and the write enable signal W/E is in the H level, the column decoder 625 sets the column selection data W_COL_SEL_FA[3] to “1”, and the column selection data W_COL_SEL_FA[0], W_COL_SEL_FA[1], and W_COL_SEL_FA[2] to “0”.

In a case where the first region selection data FA is “0”, the data is not written in the first region. Therefore, all the column selection data W_COL_SEL_FA[0], W_COL_SEL_FA[1], W_COL_SEL_FA[2], and W_COL_SEL_FA[3] are set to “0”.

As illustrated in FIG. 24H, the circuit 750R for decoding the column address to read the data in the second region includes logical AND circuits of the four-input type 770R, 771R, 772R, and 773R. 4 signal lines are connected with each of the logical AND circuits 770R to 773R. The second region selection data SA, the column address A[1], the column address A[0], and the write enable signal W/E are input in the logical AND circuits 770R to 773R.

The logical AND circuits 770R, 771R, 772R, and 773R output the column selection data R_COL_SEL_SA[0], R_COL_SEL_SA[1], R_COL_SEL_SA[2], and R_COL_SEL_SA[3], respectively.

The column selection data R_COL_SEL_SA[0] is provided to select the bit lines BL00 and BLB00 and the bit lines BL10 and BLB10 illustrated in FIG. 23 in order to read the data in the second region.

The column selection data R_COL_SEL_SA[1] is provided to select the bit lines BL01 and BLB01 and the bit lines BL11 and BLB11 illustrated in FIG. 23 in order to read the data in the second region.

The column selection data R_COL_SEL_SA[2] is provided to select the bit lines BL02 and BLB02 and the bit lines BL12 and BLB12 illustrated in FIG. 23 in order to read the data in the second region.

The column selection data R_COL_SEL_SA[3] is provided to select the bit lines BL03 and BLB03 and the bit lines BL13 and BLB13 illustrated in FIG. 23 in order to read the data in the second region.

Into the logical AND circuit 770R, the second region selection data SA, a value of the column address A[1] operated using the NOT operation, a value of the column address A[0] operated using the NOT operation, and a value of the write enable signal W/E operated using the NOT operation are input.

Into the logical AND circuit 771R, the second region selection data SA, the value of the column address A[2] operated using the NOT operation, the column address A[0], and the value of the write enable signal W/E operated using the NOT operation are input.

Into the logical AND circuit 772R, the second region selection data SA, the value of the column address A[1], the column address A[0] operated using the NOT operation, and the value of the write enable signal W/E operated using the NOT operation are input.

Into the logical AND circuit 773R, the second region selection data SA, the value of the column address A[1], the column address A[0], and the value of the write enable signal W/E operated using the NOT operation are input.

In a case where the second region selection data SA is “1”, the column addresses A[1] and A[0] are “0” and “0”, and the write enable signal W/E is in the L level, the column decoder 625 sets the column selection data R_COL_SEL_SA[0] to “1”, and the column selection data R_COL_SEL_SA[1], R_COL_SEL_SA[2], and R_COL_SEL_SA[3] to “0”.

In a case where the second region selection data SA is “1”, the column addresses A[1] and A[0] are “0” and “1”, and the write enable signal W/E is in the L level, the column decoder 625 sets the column selection data R_COL_SEL_SA[1] to “1”, and the column selection data R_COL_SEL_SA[0], R_COL_SEL_SA[2], and R_COL_SEL_SA[3] to “0”.

In a case where the second region selection data SA is “1”, the column addresses A[1] and A[0] are “1” and “0”, and the write enable signal W/E is in the L level, the column decoder 625 sets the column selection data R_COL_SEL_SA[2] to “1”, and the column selection data R_COL_SEL_SA[0], R_COL_SEL_SA[1], and R_COL_SEL_SA[3] to “0”.

In a case where the second region selection data SA is “1”, the column addresses A[1] and A[0] are “1” and “1”, and the write enable signal W/E is in the L level, the column decoder 625 sets the column selection data R_COL_SEL_SA[3] to “1”, and the column selection data R_COL_SEL_SA[0], R_COL_SEL_SA[1], and R_COL_SEL_SA[2] to “0”.

In a case where the second region selection data SA is “0”, the data is not read from the second region. Therefore, all the column selection data R_COL_SEL_SA[0], R_COL_SEL_SA[1], R_COL_SEL_SA[2], and R_COL_SEL_SA[3] are set to “0”.

As illustrated in FIG. 24I, the circuit 750W for decoding the column address to write the data in the second region includes logical AND circuits of the four-input type 770W, 771W, 772W, and 773W. 4 signal lines are connected with each of the logical AND circuits 770W to 773W. The second region selection data SA, the column address A[1], the column address A[0], and the write enable signal W/E are input in the logical AND circuits 770W to 773W.

The logical AND circuits 770W, 771W, 772W, and 773W output the column selection data W_COL_SEL_SA[0], W_COL_SEL_SA[1], W_COL_SEL_SA[2], and W_COL_SEL_SA[3], respectively.

The column selection data W_COL_SEL_SA[0] is provided to select the bit lines BL00 and BLB00 and the bit lines BL10 and BLB10 illustrated in FIG. 23 in order to write the data in the second region.

The column selection data W_COL_SEL_SA[1] is provided to select the bit lines BL01 and BLB01 and the bit lines BL11 and BLB11 illustrated in FIG. 23 in order to write the data in the second region.

The column selection data W_COL_SEL_SA[2] is provided to select the bit lines BL02 and BLB02 and the bit lines BL12 and BLB12 illustrated in FIG. 23 in order to write the data in the second region.

The column selection data W_COL_SEL_SA[3] is provided to select the bit lines BL03 and BLB03 and the bit lines BL13 and BLB13 illustrated in FIG. 23 in order to write the data in the second region.

Into the logical AND circuit 770W, the second region selection data SA, the value of the column address A[1] operated using the NOT operation, the column address A[0] operated using the NOT operation, and the value of the write enable signal W/E are input.

Into the logical AND circuit 771W, the second region selection data SA, the value of the column address A[1] operated using the NOT operation, the column address A[0], and the value of the write enable signal W/E are input.

Into the logical AND circuit 772W, the second region selection data SA, the value of the column address A[1], the column address A[0] operated using the NOT operation, and the value of the write enable signal W/E are input.

Into the logical AND circuit 773W, the second region selection data SA, the value of the column address A[1], the column address A[0], and the value of the write enable signal W/E are input.

In a case where the first region selection data SA is “1”, the column addresses A[1] and A[0] are “0” and “0”, and the write enable signal W/E is in the H level, the column decoder 625 sets the column selection data W_COL_SEL_SA[0] to “1”, and the column selection data W_COL_SEL_SA[1], W_COL_SEL_SA[2], and W_COL_SEL_SA[3] to “0”.

In a case where the second region selection data SA is “1”, the column addresses A[1] and A[0] are “0” and “1”, and the write enable signal W/E is in the H level, the column decoder 625 sets the column selection data W_COL_SEL_SA[1] to “1”, and the column selection data W_COL_SEL_SA[0], W_COL_SEL_SA[2], and W_COL_SEL_SA[3] to “0”.

In a case where the second region selection data SA is “1”, the column addresses A[1] and A[0] are “1” and “0”, and the write enable signal W/E is in the H level, the column decoder 625 sets the column selection data W_COL_SEL_SA[2] to “1”, and the column selection data W_COL_SEL_SA[0], W_COL_SEL_SA[1], and W_COL_SEL_SA[3] to “0”.

In a case where the second region selection data SA is “1”, the column addresses A[1] and A[0] are “1” and “1”, and the write enable signal W/E is in the H level, the column decoder 625 sets the column selection data W_COL_SEL_SA[3] to “1”, and the column selection data W_COL_SEL_SA[0], W_COL_SEL_SA[1], and W_COL_SEL_SA[2] to “0”.

In a case where the second region selection data SA is “0”, the data is not written in the second region. Therefore, all the column selection data W_COL_SEL_SA[0], W_COL_SEL_SA[2], W_COL_SEL_SA[2], and W_COL_SEL_SA[3] are set to “0”.

The input-output ports 430A and 430B are similar to the input-output ports 430A and 430B of the second embodiment. The data read out of the bits or written in the bits are selected through the global bit line 214 by the input-output ports (I/O) 430A and 430B under the first or second pattern based on the first pattern selection data F or the second pattern selection data S.

Both the first pattern selection data F and the second pattern selection data S are input in the input-output ports (I/O) for the bit D[n] whose bit sequence number is odd and for the bit D[n−1] whose bit sequence number is even.

In the SRAM 600 of the third embodiment, in order to read or write the data under the first or second pattern, the bit cells included in the bits whose bit sequence numbers are odd or even are alternately selected from the sub banks 450U or 450L substantially in a zigzag-like formation.

For example, the bits including 4 columns marked with x (see FIG. 22) are selected under the first pattern, or the bits including 4 columns without a mark of X (see FIG. 22) are selected under the second pattern.

Further, in the SRAM 600 of the third embodiment, the data is read or written in the first and second regions. Therefore, it is possible to select the bits indicated by blank (the white color) and the bits indicated by shading (the gray color).

With this, in the SRAM 600 of the third embodiment, the bit cells having the same address are classified into any one of 4 groups of the bits, i.e., blank bits with the mark x, blank bits without the mark, shaded bits with the mark x, and shaded bits without the mark.

Among the bit cells included in the 4 groups, the bit cells having the same column number and the same row number have the same address.

Therefore, in the SRAM 600 of the third embodiment, it is possible to selects the bits in 4 ways, i.e., the blank bits with the mark x, the blank bits without the mark, the shaded bits with the mark x, and the shaded bits without the mark.

For example, as to the blank bits with the mark x, the adjacent bits are in different sub banks and in the sub array 211A or 211B on the side opposite relative to the column selection and read-write circuit 213.

As to the blank bits with the mark x, there is an interval of 3 bits between the bits including the bit cells having the same address inside the same sub arrays 211A or 211B.

This is a structure similar to an SRAM including 16 columns in each bit. The above structure is similar in the blank bits without the mark, the shaded bits with the mark x, and the shaded bits without the mark.

As described, in the SRAM 600 of the third embodiment, adjacent bits including a plurality of bit cells having the same address are allocated to sub banks in the mutually different sub banks 450U and 450L and the sub array on an opposite side relative to the column selection and read-write circuit 213.

Therefore, even when each bit includes 4 columns in a manner similar to the SRAM 30 (see FIG. 4) of the comparative example, durability similar to that of the SRAM 30A, in which each bit includes 16 columns (see FIG. 5), of the other comparative example can be performed even if data destruction occurs by incidence of an alpha ray or a neuron ray.

On the other hand, unlike the SRAM 30A (see FIG. 5) of the other comparative example, the number of columns may be limited to 4. Therefore, reduction of a working speed caused by a change in the aspect ratio of laterally elongating bits and a laterally extended word line can be restricted.

As described, within the third embodiment, the semiconductor memory device on which the data destruction along a plurality of bits is restricted while restricting the change in the aspect ratio and the reduction of the working speed and a method of controlling the semiconductor memory device can be provided.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor memory device comprising:
a plurality of memory blocks, each including a plurality of memory cells for retaining data;
a decoder which identifies, when the memory cells having a same address are identified out of the plurality of memory cells, the memory cells having the same address in adjacent bits from the different memory blocks; and
a read-write controlling unit which reads the data retained by the memory cells identified by the decoder and writes the data into the memory cell identified by the decoder.

2. The semiconductor memory device according to claim 1,
wherein the memory blocks are sub arrays provided on one or another side of the read-write controlling unit, and
the decoder identifies, when the memory cells having the same address are identified from the plurality of memory cells, the memory cells in the adjacent bits having the same address in the sub arrays on said one side of or said another side of the read-write controlling unit.

3. The semiconductor memory device according to claim 2,
wherein the decoder identifies, when the memory cells having the same address are identified from the plurality of memory cells, the memory cells having the same address in the sub arrays on said one side of and said another side of the read-write controlling unit based on pattern selection data for selecting the memory cells in the sub array in an odd bit whose bit sequence number is odd on said one side of the read-write controlling unit and for selecting the memory cells in the sub array in an even bit whose bit sequence number is even on said another side of the read-write controlling unit.

4. The semiconductor memory device according to claim 1,
wherein the memory blocks are sub banks formed by hierarchizing a plurality of sub blocks, each including the memory cells,
the sub banks are provided on one or another side of an input-output unit which inputs or outputs the data between an external circuit of the semiconductor memory device and the read-write controlling unit, and
the decoders identify, when the memory cells having the same address are identified from the plurality of memory cells, the memory cells having the same address in the adjacent bits in the sub banks on said one side of or said another side of the input-output unit.

5. The semiconductor memory device according to claim 4,
wherein the decoder identifies, when the memory cells having the same address are identified from the plurality of memory cells, the memory cells having the same address in the sub banks on said one side of and said another side of the read-write controlling unit based on pattern selection data for selecting the memory cells in an odd bit whose bit sequence number is odd in the sub bank on said one side of the read-write controlling unit and for selecting the memory cells in an even bit whose bit sequence number is even in the sub bank on said another side of the read-write controlling unit.

6. The semiconductor memory device according to claim 1,
wherein the memory blocks are sub banks formed by hierarchizing a plurality of sub blocks, each including the memory cells,
the sub banks are provided on one or another side of an input-output unit which inputs or outputs the data between an external circuit of the semiconductor memory device and the read-write controlling units, and
the decoders identify, when the memory cells having the same address are identified from the plurality of memory cells, the sub block including the adjacent bits in the sub banks on said one side of or said another side of the input-output unit, and
the decoders identify the memory cells in each one bit or each two bit, from the plurality of memory cells, the memory cells having the same address in the sub arrays on said one side of or said another side of the read-write controlling unit in the identified sub block.

7. A method of controlling a semiconductor memory device including a plurality of memory blocks, each including a plurality of memory cells for retaining data, the method comprising:
identifying, by a decoder of the semiconductor memory device, when the memory cells having a same address in adjacent bits are identified from the plurality of memory cells, the memory cells having the same address in the different memory blocks;
reading, by a read-write controlling unit, the data retained by the memory cells identified by the decoder; and
writing, by the read-write controlling unit, the data into the memory cell identified by the decoder.
